(19) United States
(12) Patent Application Publication
(10) Pub. No.: US 2026/0020288 A1
(43) Pub. Date: Jan. 15, 2026

(54) TRANSISTOR AND METHOD FOR FABRICATING TRANSISTOR

(71) Applicant: SEMICONDUCTOR ENERGY LABORATORY CO., LTD., Atsugi-shi, Kanagawa-ken (JP)

(72) Inventors: Junichi KOEZUKA, Tochigi Tochigi (JP); Masami JINTYOU, Shimotsuga, Tochigi (JP)

(21) Appl. No.: 18/881,797

(22) PCT Filed: Jun. 29, 2023
(86) PCT No.: PCT/IB2023/056731

§ 371 Date: Jan. 7, 2025

(30) Foreign Application Priority Data
Jul. 13, 2022 (JP) 2022-112253

(51) Int. Cl. H10D 30/67; H01L 21/02; H01L 21/3105; H10D 30/01

(52) U.S. Cl. CPC H10D 30/6736; H01L 21/02554; H01L 21/0262; H01L 21/02631; H01L 21/3105; H10D 30/0312; H10D 30/0318; H10D 30/6728; H10D 30/6729; H10D 30/6731; H10D 30/6734; H10D 30/6755

(57) ABSTRACT

A transistor having a minute size is provided. The transistor includes a first conductive layer, a second conductive layer, a third conductive layer, a first insulating layer, a second insulating layer, and a semiconductor layer. The first insulating layer is provided over the first conductive layer and includes an opening reaching the first conductive layer and a depressed portion surrounding the opening in a plan view. The second conductive layer is provided to cover the inner wall of the depressed portion and includes a region facing the semiconductor layer with the first insulating layer therebetween. The semiconductor layer is provided to include a region overlapping with the opening and is in contact with the top surface of the first conductive layer, the side surface of the first insulating layer, the side surface of the second conductive layer, and the top surface of the second conductive layer. The second insulating layer is provided in contact with the top surface of the semiconductor layer. The third conductive layer is provided over the second insulating layer to cover the inner wall of the opening and includes a region facing the semiconductor layer with the second insulating layer therebetween.

### TECHNICAL FIELD

One embodiment of the present invention relates to a transistor, a semiconductor device, a display apparatus, a display module, and an electronic device. One embodiment of the present invention relates to a method for fabricating a transistor, a method for fabricating a semiconductor device, and a method for fabricating a display apparatus.

Note that one embodiment of the present invention is not limited to the above technical field. Examples of the technical field of one embodiment of the present invention include a transistor, a semiconductor device, a display apparatus, a light-emitting apparatus, a power storage device, a memory device, a lighting device, an input device (e.g., a touch sensor), an input/output device (e.g., a touch panel), a display module, an electronic device including any of them, a method for driving any of them, and a method for manufacturing any of them.

### BACKGROUND ART

Semiconductor devices including transistors have been widely used in display apparatuses and electronic devices, and the semiconductor devices have been required increasingly to achieve high integration and high-speed operation. In the case where semiconductor devices are used for high-resolution display apparatuses, highly integrated semiconductor devices are required, for example. The development of transistors having minute sizes is ongoing as one way of increasing the degree of integration of transistors.

In recent years, display apparatuses applicable to virtual reality (VR), augmented reality (AR), substitutional reality (SR), or mixed reality (MR) have been needed. VR, AR, SR, and MR are collectively referred to as XR (Extended Reality). Display apparatuses for XR have been desired to have higher resolution and higher color reproducibility so that realistic feeling and the sense of immersion can be enhanced. Examples of devices applicable to such display apparatuses include a liquid crystal display apparatus and a light-emitting apparatus including a light-emitting device (also referred to as a light-emitting element) such as an organic EL (Electro Luminescence) device or a light-emitting diode (LED).

Patent Document 1 discloses a display apparatus using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a transistor having a minute size and a fabrication method thereof. Another object of one embodiment of the present invention is to provide a transistor with a high on-state current and a fabrication method thereof. Another object of one embodiment of the present invention is to provide a transistor having excellent electrical characteristics and a fabrication method thereof. Another object of one embodiment of the present invention is to provide a highly reliable transistor and a fabrication method thereof. Another object of one embodiment of the present invention is to provide a transistor with high productivity and a fabrication method thereof. Another object of one embodiment of the present invention is to provide a novel transistor and a fabrication method thereof.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a transistor including a first conductive layer, a second conductive layer, a third conductive layer, a first insulating layer, a second insulating layer, and a semiconductor layer. The first insulating layer is provided over the first conductive layer and includes an opening reaching the first conductive layer and a depressed portion surrounding the opening in a plan view. The second conductive layer is provided to cover an inner wall of the depressed portion and includes a region facing the semiconductor layer with the first insulating layer therebetween. The semiconductor layer is provided in contact with an inner wall and a bottom surface of the opening. The second insulating layer is provided in contact with atop surface of the semiconductor layer. The third conductive layer is provided over the second insulating layer to cover the inner wall of the opening and includes a region facing the semiconductor layer with the second insulating layer therebetween.

In the above, it is preferable that the semiconductor layer include an oxide semiconductor.

In the above, it is preferable that the first insulating layer have a stacked-layer structure of a third insulating layer, a fourth insulating layer over the third insulating layer, and a fifth insulating layer over the fourth insulating layer, and the third insulating layer and the fifth insulating layer each include a region having a film density higher than that of the fourth insulating layer.

In the above, it is preferable that a width of the opening be wider on the second conductive layer side than on the first conductive layer side in a cross-sectional view, and a width of the depressed portion be wider on the second conductive layer side than on the first conductive layer side in a cross-sectional view.

In the above, it is preferable that a width of the opening be wider on the second conductive layer side than on the first conductive layer side in a cross-sectional view, and a width of the depressed portion be narrower on the second conductive layer side than on the first conductive layer side in a cross-sectional view.

In the above, when a length of a side surface of the first insulating layer in contact with the semiconductor layer in a cross-sectional view is L1 and a length of the region of the second conductive layer that faces the semiconductor layer with the first insulating layer therebetween in a cross-sectional view is L2, it is preferable that L2 be greater than or equal to 0.5 times and less than or equal to 1.0 times L1.

One embodiment of the present invention is a transistor including a first conductive layer, a second conductive layer, a third conductive layer, a first insulating layer, a second insulating layer, and a semiconductor layer. The first insulating layer is provided over the first conductive layer and includes a first opening reaching the first conductive layer and a depressed portion surrounding the opening in a plan view. The semiconductor layer is in contact with an inner wall and a bottom surface of the opening and a top surface of the first insulating layer. The second conductive layer is provided to cover an inner wall of the depressed portion and includes a region in contact with a top surface of the semiconductor layer and a region facing the semiconductor layer with the first insulating layer therebetween. The second insulating layer is provided in contact with the top surface of the semiconductor layer. The third conductive layer is provided over the second insulating layer to cover the inner wall of the opening and includes a region facing the semiconductor layer with the second insulating layer therebetween.

In the above, it is preferable that the semiconductor layer include an oxide semiconductor.

In the above, it is preferable that the first insulating layer have a stacked-layer structure of a third insulating layer, a fourth insulating layer over the third insulating layer, and a fifth insulating layer over the fourth insulating layer, and the third insulating layer and the fifth insulating layer each include a region having a film density higher than that of the fourth insulating layer.

In the above, it is preferable that a width of the opening be wider on the second conductive layer side than on the first conductive layer side in a cross-sectional view, and a width of the depressed portion be wider on the second conductive layer side than on the first conductive layer side in a cross-sectional view.

In the above, it is preferable that a width of the opening be wider on the second conductive layer side than on the first conductive layer side in a cross-sectional view, and a width of the depressed portion be narrower on the second conductive layer side than on the first conductive layer side in a cross-sectional view.

In the above, when a length of a side surface of the first insulating layer in contact with the semiconductor layer in a cross-sectional view is L1 and a length of the region of the second conductive layer that faces the semiconductor layer with the first insulating layer therebetween in a cross-sectional view is L2, it is preferable that L2 be greater than or equal to 0.5 times and less than or equal to 1.0 times L1.

One embodiment of the present invention is a method for fabricating a transistor, including the following steps: forming a first conductive layer; forming a first insulating layer over the first conductive layer; processing the first insulating layer to form a depressed portion in the first insulating layer; forming a second insulating layer to cover a top surface of the first insulating layer; forming a first conductive film over the second insulating layer; processing the first conductive film to form a second conductive layer, and then forming an opening reaching the first conductive layer in a region surrounded by the depressed portion in a plan view; forming a metal oxide film to cover a top surface of the second conductive layer, an inner wall of the opening, and a bottom surface of the opening; processing the metal oxide film to form a semiconductor layer that includes a region overlapping with the inner wall of the opening; forming a third insulating layer to cover the semiconductor layer and the top surface of the second conductive layer; forming a second conductive film over the third insulating layer; and processing the second conductive film to form a third conductive layer that includes a region overlapping with the opening.

In the above, it is preferable that after forming the first insulating layer, treatment for supplying oxygen to the first insulating layer be performed.

In the above, it is preferable that the metal oxide film be formed using a sputtering method.

In the above, it is preferable that the metal oxide film be formed using an ALD method.

### Effect of the Invention

One embodiment of the present invention can provide a transistor having a minute size and a fabrication method thereof. Alternatively, one embodiment of the present invention can provide a transistor with a high on-state current and a fabrication method thereof. Alternatively, one embodiment of the present invention can provide a transistor having excellent electrical characteristics and a fabrication method thereof. Alternatively, one embodiment of the present invention can provide a highly reliable transistor and a fabrication method thereof. Alternatively, one embodiment of the present invention can provide a transistor with high productivity and a fabrication method thereof. Alternatively, one embodiment of the present invention can provide a novel transistor and a fabrication method thereof.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a transistor. FIG. 1B is a cross-sectional view illustrating an example of a transistor.

FIG. 2A and FIG. 2B are cross-sectional views illustrating a structure example of a transistor.

FIG. 3A and FIG. 3B is cross-sectional views each illustrating an example of a transistor.

FIG. 4A and FIG. 4B is cross-sectional views each illustrating an example of a transistor.

FIG. 5A and FIG. 5B is cross-sectional views each illustrating an example of a transistor.

FIG. 6A and FIG. 6B is cross-sectional views each illustrating an example of a transistor.

FIG. 7A and FIG. 7B is cross-sectional views each illustrating an example of a transistor.

FIG. 8A is a plan view illustrating an example of a transistor. FIG. 8B is a cross-sectional view illustrating an example of a transistor.

FIG. 9A to FIG. 9C are cross-sectional views illustrating an example of a method for fabricating a transistor.

FIG. 10A to FIG. 10C are cross-sectional views illustrating an example of a method for fabricating a transistor.

FIG. 11A to FIG. 11C are cross-sectional views illustrating an example of a method for fabricating a transistor.

FIG. 12 is a perspective view illustrating an example of a display apparatus.

FIG. 13 is a cross-sectional view illustrating an example of a display apparatus.

FIG. 14 is a cross-sectional view illustrating an example of a display apparatus.

FIG. 15 is a cross-sectional view illustrating an example of a display apparatus.

FIG. 16 is a cross-sectional view illustrating an example of a display apparatus.

FIG. 17 is a cross-sectional view illustrating an example of a display apparatus.

FIG. 18 is a cross-sectional view illustrating an example of a display apparatus.

FIG. 19 is a cross-sectional view illustrating an example of a display apparatus.

FIG. 20A to FIG. 20F are cross-sectional views illustrating an example of a method for fabricating a display apparatus.

FIG. 21A and FIG. 21B are each a circuit diagram of a pixel circuit.

FIG. 22A and FIG. 22B are each a circuit diagram of a pixel circuit.

FIG. 23 is a circuit diagram of a pixel circuit.

FIG. 24 is a diagram illustrating a structure example of a sequential circuit.

FIG. 25A to FIG. 25D are diagrams illustrating examples of electronic devices.

FIG. 26A to FIG. 26F are diagrams illustrating examples of electronic devices.

FIG. 27A to FIG. 27G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure.

In this specification and the like, a structure in which at least light-emitting layers of light-emitting elements having different emission wavelengths are separately formed may be referred to as an SBS (Side By Side) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In this specification and the like, a tapered shape refers to such a shape that at least part of the side surface of a component is inclined with respect to a substrate surface or a formation surface. For example, a tapered shape preferably includes a region where the angle between the inclined side surface and the substrate surface or the formation surface (such an angle is also referred to as a taper angle) is less than 90°, further preferably includes a region where the angle is greater than or equal to 45° and less than 90°, still further preferably includes a region where the angle is greater than or equal to 50° and less than 90°, yet further preferably includes a region where the angle is greater than or equal to 55° and less than 90°, yet still further preferably includes a region where the angle is greater than or equal to 60° and less than 90°, yet still further preferably includes a region where the angle is greater than or equal to 60° and less than or equal to 85°, yet still further preferably includes a region where the angle is greater than or equal to 65° and less than or equal to 85°, yet still further preferably includes a region where the angle is greater than or equal to 65° and less than or equal to 80°, yet still further preferably includes a region where the angle is greater than or equal to 70° and less than or equal to 80°. Note that the side surface of the component, the substrate surface, and the formation surface are not necessarily completely flat, and may have a substantially planar shape with a slight curvature or a substantially planar shape with slight unevenness.

In this specification and the like, a sacrificial layer (also referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

In this specification and the like, a planar shape refers to a shape in a plan view, i.e., a shape seen from above. In this specification and the like, the expression “substantially the same planar shapes” means that at least outlines of stacked layers partly overlap with each other. For example, the case of processing the upper layer and the lower layer with use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “substantially the same planar shapes”.

In this specification and the like, the expression “substantially level” indicates a structure in which levels from a reference surface (e.g., a flat surface such as a substrate surface) are substantially the same in a cross-sectional view.

### Embodiment 1

In this embodiment, a transistor of one embodiment of the present invention, a fabrication method thereof, and the like will be described.

### <Structure Example of Transistor>

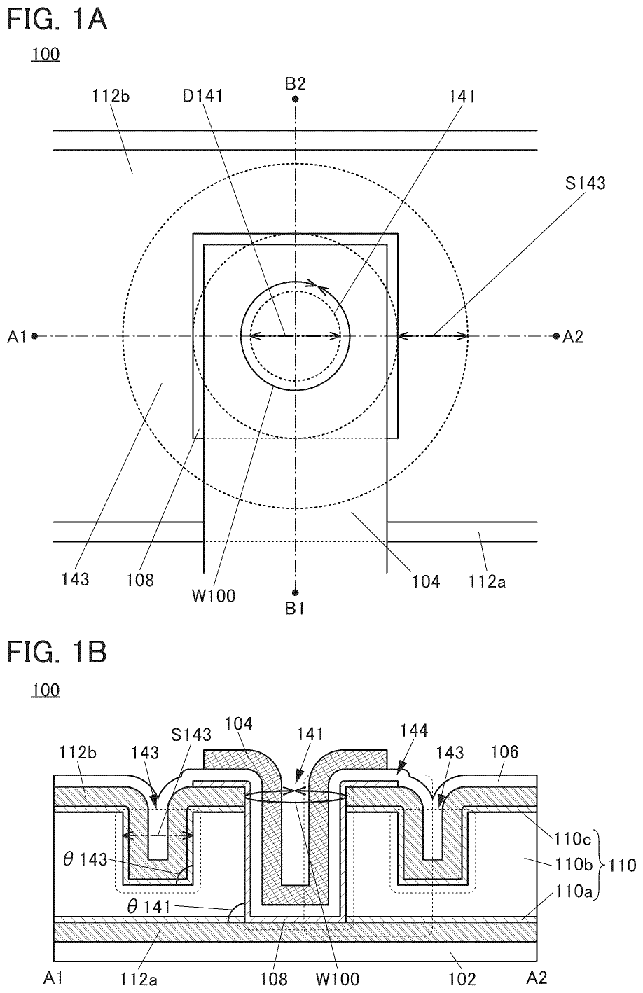

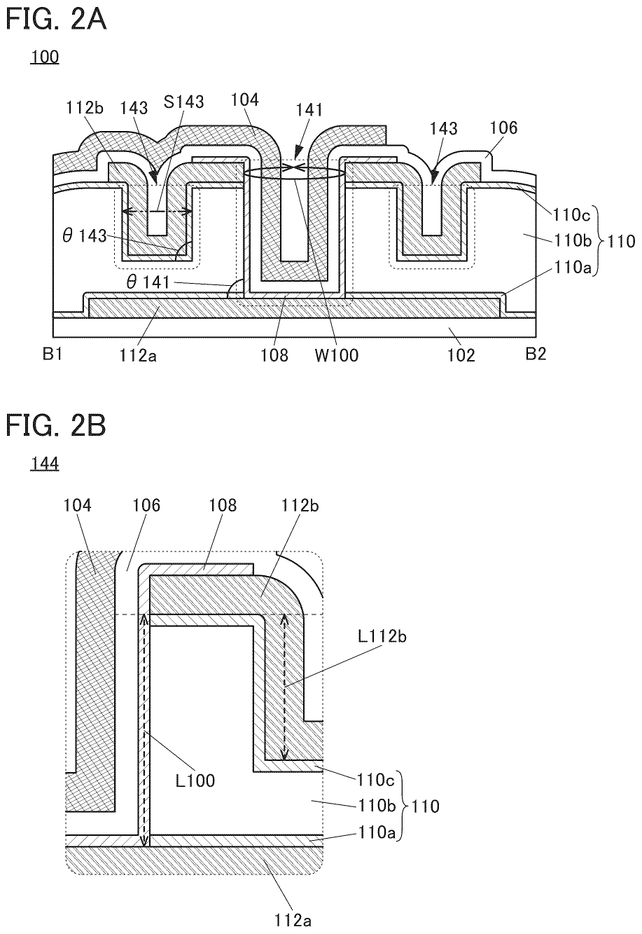

The transistor of one embodiment of the present invention will be described. FIG. 1A is a plan view (also referred to as atop view) of a transistor 100. FIG. 1B is a cross-sectional view taken along the dashed-dotted line A1-A2 in FIG. 1A, and FIG. 2A is a cross-sectional view taken along the dashed-dotted line B1-B2 in FIG. 1A. FIG. 2B is an enlarged view of a region 144 illustrated in FIG. 1B. Note that some components (e.g., an insulating layer) of the transistor 100 are not illustrated in FIG. 1A. Some components are not illustrated in plan views of transistors and the like in the following drawings, as in FIG. 1A.

The transistor 100 is provided over a substrate 102. The transistor 100 includes a conductive layer 104, an insulating layer 106, a semiconductor layer 108, a conductive layer 112a, a conductive layer 112b, an insulating layer 110 (an insulating layer 110a, an insulating layer 110b, and an insulating layer 110c). The conductive layer 104 functions as a first gate electrode. Part of the insulating layer 106 functions as a first gate insulating layer. The conductive layer 112a functions as one of a source electrode and a drain electrode, and the conductive layer 112b functions as the other of the source electrode and the drain electrode. In the semiconductor layer 108, the whole region that is between the source electrode and the drain electrode and overlaps with the first gate electrode with the first gate insulating layer therebetween functions as a channel formation region. In the semiconductor layer 108, a region in contact with the source electrode functions as a source region and a region in contact with the drain electrode functions as a drain region.

The conductive layer 112b functions as a second gate electrode (also referred to as a back gate electrode). Part of the insulating layer 110 functions as a second gate insulating layer. That is, in the transistor of one embodiment of the present invention, the conductive layer 112b can have both a function of the second gate electrode and a function of the other of the source electrode and the drain electrode. Thus, the saturation in the I_{d}-V_{d} characteristics of the transistor can be improved. In this specification and the like, the state where the change in current is small (the slope is small) in the saturation region in the I_{d}-V_{d} characteristics of a transistor is sometimes described using the expression “favorable saturation”. In addition, the reliability of the transistor can be increased. Furthermore, the number of wirings in the circuit including the transistor can be smaller than that in the case where the second gate electrode and the other of the source electrode and the drain electrode are provided separately. Thus, the whole circuit can be simplified. Furthermore, the number of manufacturing steps is reduced and the productivity can be improved.

As illustrated in FIG. 1B and FIG. 2A, the conductive layer 112a is provided over the substrate 102. The insulating layer 110 (the insulating layer 110a, the insulating layer 110b, and the insulating layer 110c) is provided over the conductive layer 112a. The conductive layer 112b is provided over the insulating layer 110. The semiconductor layer 108 is provided in contact with part of the top surface of the conductive layer 112a, the side surface of the insulating layer 110, the side surface of the conductive layer 112b, and part of the top surface of the conductive layer 112b. The insulating layer 106 is provided in contact with the top surface and the side surface of the semiconductor layer 108 and the top surface of the conductive layer 112b. The conductive layer 104 is provided on the top surface of the insulating layer 106 to include a region overlapping with the top surface of the semiconductor layer 108 and the side surface of the insulating layer 110.

An opening 141 reaching the conductive layer 112a is provided in the insulating layer 110 and the conductive layer 112b. The opening 141 has a substantially circular shape in a plan view (see FIG. 1A). In FIG. 1A, the opening 141 is illustrated as a substantially circular shape having a center at the intersection of the dashed-dotted line A1-A2 and the dashed-dotted line B1-B2 and having a diameter of a width D141.

A depressed portion 143 is provided in the insulating layer 110b. The depressed portion 143 has a ring-like shape that has a width S143 and encloses the opening 141 in the plan view (see FIG. 1A). In other words, the depressed portion 143 is provided to surround the opening 141. The bottom surface of the depressed portion 143 is positioned above the top surface of the conductive layer 112a in cross-sectional views (see FIG. 1B and FIG. 2A). That is, in the insulating layer 110b, the depressed portion 143 is formed to be shallower than the opening 141 is. Note that in FIG. 1B and FIG. 2A, an angle between the side surface and the top surface of the insulating layer 110b in the region where the depressed portion 143 is formed is indicated by an angle θ143.

The insulating layer 110a is provided below the insulating layer 110b. That is, the insulating layer 110a and the insulating layer 110b are stacked in this order over the conductive layer 112a. The insulating layer 110c is provided in contact with the side surface of the insulating layer 110b in a region overlapping with the depressed portion 143 in the insulating layer 110b (also referred to as the inner wall of the depressed portion 143), the top surface of the insulating layer 110b in a region overlapping with the depressed portion 143 (also referred to as the bottom surface of the depressed portion 143), and the top surface of the insulating layer 110b in a region not overlapping with the depressed portion 143.

The conductive layer 112b is provided over the insulating layer 110c. The conductive layer 112b is provided to cover the inner wall and the bottom surface of the depressed portion 143. A region in the depressed portion 143 of the conductive layer 112b is preferably provided to include a region overlapping with (facing) the semiconductor layer 108 with the insulating layer 110 therebetween.

The semiconductor layer 108 is provided in contact with the top surface of the conductive layer 112a (also referred to as the bottom surface of the opening 141), the side surfaces of the insulating layer 110 and the conductive layer 112b (also referred to as the inner wall of the opening 141), and the top surface of the conductive layer 112b to include a region overlapping with the opening 141. The insulating layer 106 is provided in contact with the top surface and the side surface of the semiconductor layer 108 and the top surface of the conductive layer 112b. Over the insulating layer 106, the conductive layer 104 is provided to include a region overlapping with the opening 141. The conductive layer 104 is provided to cover the inner wall and the bottom surface of the opening 141. The conductive layer 104 is preferably provided to include a region overlapping with (facing) the semiconductor layer 108 with the insulating layer 106 therebetween in the opening 141.

When the transistor of one embodiment of the present invention has the above structure, the conductive layer 112a can function as one of a source electrode and a drain electrode. The conductive layer 112b can function as the other of the source electrode and the drain electrode. The conductive layer 104 can function as the first gate electrode. Part of the insulating layer 106 (a region positioned at a level between the conductive layer 112a and the conductive layer 112b and overlapping with the conductive layer 104) can function as the first gate insulating layer. Part of the semiconductor layer 108 overlapping with the first gate insulating layer can function as a channel formation region.

The conductive layer 112b can function as the second gate electrode. In addition, part of the insulating layer 110 (which is a region interposed between the conductive layer 112b and the semiconductor layer 108 in the insulating layer 110b and the insulating layer 110c and is also referred to as a region interposed between the opening 141 and the depressed portion 143 in the plan view) can function as the second gate insulating layer.

That is, in the transistor 100, the conductive layer 112b can function as both the second gate electrode and the other of the source electrode and the drain electrode.

Part of the conductive layer 112b overlapping with (facing) the semiconductor layer 108 with the insulating layer 110 therebetween functions as the second gate electrode. In FIG. 2B, a length L112b of the part of the conductive layer 112b functioning as the second gate electrode is indicated by a dashed double-headed arrow.

When the conductive layer 112b has a function of the second gate electrode, a potential of a region of the semiconductor layer 108 on the side facing the conductive layer 112b (also referred to as a back channel region) is fixed and the saturation in the I_{d}-V_{d} characteristics of the transistor 100 can be improved.

In the case where the transistor of one embodiment of the present invention includes the second gate electrode, the controllability of the threshold voltage is improved and normally-off characteristics can be achieved more surely as compared to the case where the second gate electrode is not provided.

When the transistor of one embodiment of the present invention includes the second gate electrode, variations in characteristics between a plurality of transistors can be reduced in some cases. For example, variations in threshold values between a plurality of transistors can be reduced in some cases.

The potential on the lower potential side of the source potential and the drain potential is preferably supplied to the conductive layer 112b functioning as the second gate electrode. In that case, it is preferable that the conductive layer 112b function as a source electrode and the conductive layer 112a function as a drain electrode when the transistor of one embodiment of the present invention is an n-channel transistor. When the transistor of one embodiment of the present invention is an n-channel transistor, making one conductive layer (conductive layer 112b) serve as both the source electrode and the second gate electrode results in inhibition of the influence and the like of electron trapping to the back channel region and an improvement of the reliability of the transistor.

Alternatively, when the transistor of one embodiment of the present invention is an n-channel transistor, the conductive layer 112a may function as the source electrode and the conductive layer 112b may function as the drain electrode. In that case, the conductive layer 104 functioning as the first gate electrode and the conductive layer 112b are electrically connected to each other, for example, whereby the transistor of one embodiment of the present invention can function as a diode.

When the transistor of one embodiment of the present invention is a p-channel transistor, it is preferable that the conductive layer 112b function as a drain electrode and the conductive layer 112a function as a source electrode. When the transistor of one embodiment of the present invention is a p-channel transistor, making one conductive layer (conductive layer 112b) serve as both the drain electrode and the second gate electrode results in an increase in the reliability of the transistor in some cases.

Alternatively, when the transistor of one embodiment of the present invention is a p-channel transistor, the conductive layer 112b may function as the drain electrode and the conductive layer 112a may function as the source electrode. In that case, the conductive layer 104 functioning as the first gate electrode and the conductive layer 112a are electrically connected to each other, for example, whereby the transistor of one embodiment of the present invention can function as a diode.

When the conductive layer 112b is extended, the conductive layer 112b can also function as a wiring. That is, when the conductive layer 112b is extended, the conductive layer 112b can have three functions of the wiring, the second gate electrode, and the other of the source electrode and the drain electrode of the transistor 100. Thus, the number of wirings in the circuit including the transistor can be reduced, so that the whole circuit can be simplified. Furthermore, the number of manufacturing steps is reduced and the productivity can be improved.

In the transistor of one embodiment of the present invention, the source electrode and the drain electrode are positioned at different heights from the substrate surface as illustrated in FIG. 1B or the like, so that a drain current flows in the height direction (the vertical direction). Accordingly, the transistor of one embodiment of the present invention can be referred to as a vertical transistor, a vertical-channel transistor, a vertical channel-type transistor, a vertical field-effect transistor (VFET), or the like.

In the transistor 100, the top surface of the conductive layer 112a functioning as one of the source electrode and the drain electrode and the top surface of the conductive layer 112b functioning as the other of the source electrode and the drain electrode are both in contact with the bottom surface (the surface on the substrate 102 side) of the semiconductor layer 108. Thus, the transistor 100 can also be referred to as a bottom-contact transistor.

The channel length and the channel width of the transistor 100 will be described.

The channel length of the transistor 100 is a distance between the source region and the drain region. In FIG. 2B, a channel length L100 of the transistor 100 is indicated by a dashed double-headed arrow. The channel length L100 can also be regarded as the length of the side surface of the insulating layer 110 (the insulating layer 110a, the insulating layer 110b, and the insulating layer 110c) in contact with the semiconductor layer 108 between the source electrode and the drain electrode.

Here, the channel length L100 of the transistor 100 is determined by the thickness of the insulating layer 110 (the insulating layer 110a, the insulating layer 110b, and the insulating layer 110c), an angle θ141 between the side surface of the insulating layer 110 and the formation surface of the insulating layer 110a (the top surface of the conductive layer 112a), and the like, and is not affected by the performance of a light-exposure apparatus used to fabricate the transistor. Thus, the channel length L100 can be a value smaller than that of the resolution limit of the light-exposure apparatus, which enables the transistor to have a minute size.

As described above, part of the conductive layer 112b in the transistor 100 functions as the second gate electrode. Thus, an electric field supplied from the conductive layer 112b to the semiconductor layer 108 side is preferably applied to half or more of the back channel region. For example, the length L112b of the part of the conductive layer 112b functioning as the second gate electrode is preferably half or more of the channel length L100 of the transistor 100. That is, L112b is preferably greater than or equal to 0.5 times L100, further preferably 0.5 to 1.0 times L100. Accordingly, the effect of the conductive layer 112b functioning as the second gate electrode can be further enhanced.

The channel length L100 is preferably less than or equal to 2 m, less than or equal to 1 μm, less than or equal to 750 nm, less than or equal to 500 nm, less than or equal to 400 nm, less than or equal to 300 nm, less than or equal to 200 nm, less than or equal to 100 nm, less than or equal to 75 nm, less than or equal to 60 nm, less than or equal to 50 nm, less than or equal to 40 nm, less than or equal to 30 nm, less than or equal to 20 nm, less than or equal to 15 nm, less than or equal to 12 nm, or less than or equal to 10 nm, and greater than or equal to 2 nm, greater than or equal to 3 nm, greater than or equal to 5 nm, or greater than or equal to 8 nm, for example.

A reduction in the channel length L100 can increase the on-state current of the transistor 100. With the use of the transistor 100 with a high on-state current, a circuit capable of high-speed operation can be fabricated. Furthermore, the area occupied by the circuit can be reduced. Thus, when the transistor of one embodiment of the present invention is used in a semiconductor device, the device can be downsized.

For example, when the transistor of one embodiment of the present invention is used in a display apparatus, the bezel of the display apparatus can be narrowed. For another example, when the transistor of one embodiment of the present invention is used in a large display apparatus or a high-resolution display apparatus, signal delay in wirings can be reduced so that display unevenness can be inhibited even if the number of wirings is increased.

In general, a transistor with a short channel length tends to have poor saturation in the Ia-V_{d} characteristics. However, the transistor of one embodiment of the present invention can have favorable saturation because of including the second gate electrode.

In the transistor of one embodiment of the present invention, the semiconductor layer 108 is provided along the inner wall and the bottom surface of the opening 141. Accordingly, in this specification and the like, the channel width of the transistor 100 is described as the width (length) of the region where the semiconductor layer 108 is in contact with the conductive layer 112b in the direction orthogonal to the channel length direction. In FIG. 1A, FIG. 1B, and FIG. 2A, a channel width W100 of the transistor 100 is indicated by a solid double-headed arrow. The channel width W100 corresponds to the length of the outer periphery of the opening 141 in the plan view (see FIG. 1A).

The channel width W100 is determined by the planar shape of the opening 141. In FIG. 1A, the width D141 corresponding to the diameter of the opening 141 having a substantially circular shape is indicated by a dashed double-dotted double-headed arrow. In the case where the planar shape of the opening 141 is substantially circular as in the transistor 100, the channel width W100 can be roughly calculated to be “D141×π”. For example, the width D141 is greater than or equal to 0.20 m and less than 5.0 m.

As described above, the channel length of the transistor of one embodiment of the present invention can be set to an extremely small value by controlling the thickness of the insulating layer 110, for example. In addition, the channel width of the transistor can be set to a large value by controlling the diameter of the opening 141, without considerably increasing the area occupied by the transistor in the substrate surface. Thus, appropriate setting of the channel length and the channel width can further increase the on-state current of the transistor 100.

Materials that can be used for the transistor of one embodiment of the present invention are described below.

### [Semiconductor Layer 108]

A semiconductor material that can be used for the semiconductor layer 108 is not particularly limited. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. These semiconductor materials may contain an impurity as a dopant.

There is no particular limitation on the crystallinity of a semiconductor material used for the semiconductor layer 108, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case degradation of transistor characteristics can be inhibited.

Silicon can be used for the semiconductor layer 108. Examples of silicon include single crystal silicon, polycrystalline silicon, microcrystalline silicon, and amorphous silicon. An example of the polycrystalline silicon is low-temperature polysilicon (LTPS).

The transistor using amorphous silicon for the semiconductor layer 108 can be formed over a large glass substrate, and can be fabricated at low cost. The transistor using polycrystalline silicon for the semiconductor layer 108 has high field-effect mobility and enables high-speed operation. The transistor using microcrystalline silicon for the semiconductor layer 108 has higher field-effect mobility and enables higher speed operation than the transistor using amorphous silicon.

The semiconductor layer 108 preferably contains a metal oxide. Examples of the metal oxide that can be used for the semiconductor layer 108 include indium oxide, gallium oxide, and zinc oxide. The metal oxide preferably contains at least indium or zinc. The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, the semiconductor layer 108 can be formed using indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide), indium aluminum zinc oxide (In—Al—Zn oxide, also referred to as IAZO), indium tin zinc oxide (In—Sn—Zn oxide, also referred to as ITZO (registered trademark)), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO, IGZAO, or IAGZO). Alternatively, indium tin oxide containing silicon, gallium tin oxide (Ga—Sn oxide), aluminum tin oxide (Al—Sn oxide), or the like can be used.

A sputtering method or an atomic layer deposition (ALD) method can be suitably used to form the metal oxide. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Specific examples of ALD methods used to form the semiconductor layer 108 include film formation methods such as a thermal ALD method and a plasma enhanced ALD (PEALD) method. The thermal ALD method is preferable because of its capability of forming a film with extremely high step coverage. The PEALD method is preferable because of its capability of forming a film at low temperatures, in addition to its capability of forming a film with high step coverage.

The composition of the metal oxide included in the semiconductor layer 108 greatly affects the electrical characteristics and reliability of the transistor 100.

For example, a metal oxide with a higher indium content percentage enables the transistor to have a higher on-state current.

In the case of using In—Zn oxide for the semiconductor layer 108, a metal oxide in which the atomic proportion of indium is higher than or equal to the atomic proportion of zinc is preferably used. For example, it is possible to use, for the semiconductor layer 108, a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the neighborhood thereof.

In the case of using In—Sn oxide for the semiconductor layer 108, a metal oxide in which the atomic proportion of indium is higher than or equal to the atomic proportion of tin is preferably used. For example, it is possible to use, for the semiconductor layer 108, a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case of using In—Sn—Zn oxide for the semiconductor layer 108, it is possible to use a metal oxide in which the atomic proportion of indium is higher than the atomic proportion of tin. It is further preferable to use a metal oxide in which the atomic proportion of zinc is higher than the atomic proportion of tin. For example, it is possible to use, for the semiconductor layer 108, a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case of using In—Al—Zn oxide for the semiconductor layer 108, it is possible to use a metal oxide in which the atomic proportion of indium is higher than the atomic proportion of aluminum. It is further preferable to use a metal oxide in which the atomic proportion of zinc is higher than the atomic proportion of aluminum. For example, it is possible to use, for the semiconductor layer 108, a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case of using In—Ga—Zn oxide for the semiconductor layer 108, it is possible to use a metal oxide in which the atomic proportion of indium to the metal elements is higher than the atomic proportion of gallium. It is further preferable to use a metal oxide in which the atomic proportion of zinc is higher than the atomic proportion of gallium. For example, it is possible to use, for the semiconductor layer 108, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, or In:Ga:Zn=40:1:10, or in the neighborhood thereof.

In the case of using In-M-Zn oxide for the semiconductor layer 108, it is possible to use a metal oxide in which the atomic proportion of indium to the metal elements is higher than the atomic proportion of the element M. It is further preferable to use a metal oxide in which the atomic proportion of zinc is higher than the atomic proportion of the element M. For example, it is possible to use, for the semiconductor layer 108, a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, or In:M:Zn=40:1:10, or in the neighborhood thereof.

In the case where a plurality of metal elements are contained as the element M, the sum of the proportions of the numbers of atoms of the metal elements can be the proportion of the number of element M atoms. In the case of In—Ga—Al—Zn oxide in which gallium and aluminum are contained as the element M, for example, the sum of the proportion of the number of gallium atoms and the proportion of the number of aluminum atoms can be the proportion of the number of element M atoms. The atomic ratio between indium, the element M, and zinc is preferably within the ranges described above. In the case of In—Ga—Sn—Zn oxide in which gallium and tin are contained as the element M, for example, the sum of the proportion of the number of gallium atoms and the proportion of the number of tin atoms can be the proportion of the number of element M atoms. The atomic ratio between indium, the element M, and zinc is preferably within the ranges described above.

It is preferable to use a metal oxide in which the proportion of the number of indium atoms to the number of atoms of the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, still further preferably higher than or equal to 35 atomic % and lower than or equal to 90 atomic %, yet further preferably higher than or equal to 40 atomic % and lower than or equal to 90 atomic %, yet still further preferably higher than or equal to 45 atomic % and lower than or equal to 90 atomic %, yet still further preferably higher than or equal to 50 atomic % and lower than or equal to 80 atomic %, yet still further preferably higher than or equal to 60 atomic % and lower than or equal to 80 atomic %, yet still further preferably higher than or equal to 70 atomic % and lower than or equal to 80 atomic %. For example, in the case of using In—Ga—Zn oxide for the semiconductor layer 108, the proportion of the number of indium atoms in the sum of the numbers of atoms of indium, the element M, and zinc is preferably within the ranges described above.

In this specification and the like, the proportion of the number of indium atoms to the number of atoms of the metal elements contained is sometimes referred to as indium content percentage. The same applies to other metal elements.

A metal oxide with a higher indium content percentage enables a transistor to have a higher on-state current. By using such a transistor as a transistor required to have a high on-state current, a semiconductor device having excellent electrical characteristics can be provided.

As an analysis method of the composition of a metal oxide, for example, energy dispersive X-ray spectroscopy (EDX), X-ray photoelectron spectroscopy (XPS), inductively coupled plasma-mass spectrometry (ICP-MS), or inductively coupled plasma-atomic emission spectroscopy (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

A composition in the neighborhood in this specification and the like includes the range of +30% of an intended atomic ratio. For example, when the atomic ratio is described as In:M:Zn=4:2:3 or a composition in the neighborhood thereof, the case is included where the atomic proportion of M is higher than or equal to 1 and lower than or equal to 3 and the atomic proportion of zinc is higher than or equal to 2 and lower than or equal to 4 with the atomic proportion of indium being 4. When the atomic ratio is described as In:M:Zn=5:1:6 or a composition in the neighborhood thereof, the case is included where the atomic proportion of M is higher than 0.1 and lower than or equal to 2 and the atomic proportion of zinc is higher than or equal to 5 and lower than or equal to 7 with the atomic proportion of indium being 5. When the atomic ratio is described as In:M:Zn=1:1:1 or a composition in the neighborhood thereof, the case is included where the atomic proportion of M is higher than 0.1 and lower than or equal to 2 and the atomic proportion of zinc is higher than 0.1 and lower than or equal to 2 with the atomic proportion of indium being 1.

Here, the reliability of a transistor is described. One of indicators of evaluating the reliability of a transistor is a GBT (Gate Bias Temperature) stress test in which a state of applying an electric field to a gate is maintained at high temperatures. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation with light is performed are respectively referred to as a PBTIS (Positive Bias Temperature Illumination Stress) test and an NBTIS (Negative Bias Temperature Illumination Stress) test.

In an n-type transistor, a positive potential is supplied to a gate in putting the transistor in an on state (a state where current flows); thus, the amount of change in threshold voltage in the PBTS test is one important item to be focused on as an indicator of the reliability of the transistor.

With the use of a metal oxide that does not contain gallium or has a low gallium content percentage in the semiconductor layer 108, the transistor can be highly reliable against positive bias application. In other words, the amount of change in the threshold voltage of the transistor in the PBTS test can be small. In the case of using a metal oxide that contains gallium, the gallium content percentage is preferably lower than the indium content percentage. Thus, a highly reliable transistor can be achieved.

One of the factors in change in the threshold voltage in the PBTS test is carrier (here, electron) trapping by a defect state at the interface between a semiconductor layer and a gate insulating layer or in the vicinity of the interface. As the density of defect states increases, the number of carriers that are trapped at the above-described interface increases; thus, degradation in the PBTS test becomes more significant. Generation of the defect states can be inhibited and thus change in the threshold voltage in the PBTS test can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, trap sites of carriers (here, electrons) are probably generated easily. This might cause the change in the threshold voltage when a positive potential is supplied to a gate and carriers are trapped at the interface between the semiconductor layer and the gate insulating layer.

Specifically, in the case of using In—Ga—Zn oxide for the semiconductor layer 108, a metal oxide in which the atomic proportion of indium is higher than the atomic proportion of gallium can be used for the semiconductor layer 108. It is further preferable to use a metal oxide in which the atomic proportion of zinc is higher than the atomic proportion of gallium. In other words, a metal oxide in which the atomic proportions of metal elements satisfy In >Ga and Zn>Ga is preferably used for the semiconductor layer 108.

It is preferable to use, for the semiconductor layer 108, a metal oxide in which the proportion of the number of gallium atoms to the number of atoms of the metal elements contained is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, still further preferably higher than or equal to 0.1 atomic % and lower than or equal to 30 atomic %, yet further preferably higher than or equal to 0.1 atomic % and lower than or equal to 25 atomic %, yet still further preferably higher than or equal to 0.1 atomic % and lower than or equal to 20 atomic %, yet still further preferably higher than or equal to 0.1 atomic % and lower than or equal to 15 atomic %, yet still further preferably higher than or equal to 0.1 atomic % and lower than or equal to 10 atomic %. The reduction in the gallium content percentage in the semiconductor layer enables the transistor to be highly resistant to the PBTS test. Note that an oxygen vacancy (V_{O}) is less likely to be generated in the metal oxide when the metal oxide contains gallium.

A metal oxide not containing gallium may be used for the semiconductor layer 108. For example, In—Zn oxide can be used for the semiconductor layer 108. In that case, when the atomic ratio of indium to the metal elements contained in the metal oxide is increased, the field-effect mobility of the transistor can be increased. By contrast, when the atomic ratio of zinc to the metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, may be used for the semiconductor layer 108. The use of a metal oxide not containing gallium can make a change in the threshold voltage particularly in the PBTS test extremely small.

For example, an oxide containing indium and zinc can be used for the semiconductor layer 108. In that case, for example, a metal oxide in which the atomic ratio of metal elements is In:Zn=2:3 or in the neighborhood thereof can be used.

Although the case of using gallium is described as a typical example, the same applies to the case where the element M is used instead of gallium. A metal oxide in which the atomic proportion of indium is higher than the atomic proportion of the element M is preferably used for the semiconductor layer 108. Furthermore, a metal oxide in which the atomic proportion of zinc is higher than the atomic proportion of the element M is preferably used.

The use of a metal oxide having a low element M content percentage for the semiconductor layer 108 enables the transistor to be highly reliable against positive bias application. With the use of the transistor as a transistor that is required to have high reliability against positive bias application, a highly reliable semiconductor device can be provided.

Next, the reliability of a transistor against light is described.

Light incidence on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in an NBTIS test, for example.

The high content percentage of the element M in the metal oxide enables the transistor to be highly reliable against light. In other words, the amount of change in the threshold voltage of the transistor in the NBTIS test can be small. Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide included in the semiconductor layer 108 is preferably greater than or equal to 2.0 eV, further preferably greater than or equal to 2.5 eV, still further preferably greater than or equal to 3.0 eV, yet further preferably greater than or equal to 3.2 eV, yet still further preferably greater than or equal to 3.3 eV, yet still further preferably greater than or equal to 3.4 eV, yet still further preferably greater than or equal to 3.5 eV.

For example, it is possible to use, for the semiconductor layer 108, a metal oxide in which the atomic ratio of the metal elements is In:M:Zn=1:1:1, In:M:Zn=1:1:1.2, In:M:Zn=1:3:2, In:M:Zn=1:3:3, or In:M:Zn=1:3:4, or in the neighborhood thereof.

In particular, a metal oxide in which the proportion of the number of element M atoms to the number of atoms of the metal elements contained is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet still further preferably higher than or equal to 50 atomic % and lower than or equal to 60 atomic % can be suitably used for the semiconductor layer 108.

In the case of using In—Ga—Zn oxide for the semiconductor layer 108, a metal oxide in which the atomic ratio of indium to the metal elements is lower than or equal to the atomic ratio of gallium can be used. For example, it is possible to use a metal oxide in which the atomic ratio of the metal elements is In:Ga:Zn=1:1:1, In:Ga:Zn=1:1:1.2, In:Ga:Zn=1:3:2, In:Ga:Zn=1:3:3, or In:Ga:Zn=1:3:4, or in the neighborhood thereof.

In particular, a metal oxide in which the proportion of the number of gallium atoms to the number of atoms of the metal elements contained is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, still further preferably higher than or equal to 40 atomic % and lower than or equal to 60 atomic %, yet still further preferably higher than or equal to 50 atomic % and lower than or equal to 60 atomic % can be suitably used for the semiconductor layer 108.

The use of a metal oxide having a high element M content percentage for the semiconductor layer 108 enables the transistor to be highly reliable against light. With the use of the transistor as a transistor that is required to have high reliability against light, a highly reliable semiconductor device can be provided.

As described above, the electrical characteristics and reliability of a transistor depend on the composition of the metal oxide used for the semiconductor layer 108. Therefore, by determining the composition of the metal oxide in accordance with the electrical characteristics and reliability required for the transistor, the semiconductor device can have both excellent electrical characteristics and high reliability.

The semiconductor layer 108 may have a stacked-layer structure including two or more metal oxide layers. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target, for example. The two or more metal oxide layers included in the semiconductor layer 108 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

It is preferable to use a metal oxide layer having crystallinity as the semiconductor layer 108. For example, a metal oxide layer having a CAAC (C-Axis Aligned Crystal) structure, a polycrystalline structure, a nano-crystal (nc) structure, or the like can be used. With the use of a metal oxide layer having crystallinity as the semiconductor layer 108, the density of defect states in the semiconductor layer 108 can be reduced, which enables the transistor to have high reliability.

The higher the crystallinity of the metal oxide layer used as the semiconductor layer 108 is, the lower the density of defect states in the semiconductor layer 108 can be. By contrast, the use of a metal oxide layer having low crystallinity enables a transistor to flow a large amount of current.

The semiconductor layer 108 may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 108 may have the same composition or substantially the same compositions. Employing a stacked-layer structure of metal oxide layers having the same composition can reduce the manufacturing cost because the metal oxide layers can be formed using the same sputtering target. For example, with the use of the same sputtering target and different oxygen flow rate ratios or different oxygen partial pressures, a stacked-layer structure of two or more metal oxide layers having different crystallinities can be formed. The two or more metal oxide layers included in the semiconductor layer 108 may have different compositions.

The thickness of the semiconductor layer 108 is preferably larger than or equal to 3 nm and smaller than or equal to 100 nm, further preferably larger than or equal to 5 nm and smaller than or equal to 100 nm, still further preferably larger than or equal to 10 nm and smaller than or equal to 100 nm, yet further preferably larger than or equal to 10 nm and smaller than or equal to 70 nm, yet still further preferably larger than or equal to 15 nm and smaller than or equal to 70 nm, yet still further preferably larger than or equal to 15 nm and smaller than or equal to 50 nm, yet still further preferably larger than or equal to 20 nm and smaller than or equal to 50 nm, yet still further preferably larger than or equal to 20 nm and smaller than or equal to 40 nm, yet still further preferably larger than or equal to 25 nm and smaller than or equal to 40 nm.

Here, oxygen vacancies that might be formed in the semiconductor layer 108 will be described.

In the case where an oxide semiconductor is used for the semiconductor layer 108, hydrogen contained in the oxide semiconductor reacts with oxygen bonded to a metal atom to be water, and thus sometimes forms an oxygen vacancy (V_{O}) in the oxide semiconductor. In some cases, a defect where hydrogen enters an oxygen vacancy (hereinafter, referred to as V_{O}H) functions as a donor and generates an electron serving as a carrier. In other cases, bonding of part of hydrogen to oxygen bonded to a metal atom generates an electron serving as a carrier. Thus, a transistor using an oxide semiconductor that contains a large amount of hydrogen is likely to have normally-on characteristics. Moreover, hydrogen in an oxide semiconductor is easily transferred by a stress such as heat or an electric field; thus, a large amount of hydrogen contained in an oxide semiconductor might reduce the reliability of a transistor.

V_{O}H can function as a donor of the oxide semiconductor. However, it is difficult to evaluate the defect quantitatively. Thus, the oxide semiconductor is sometimes evaluated not by its donor concentration but by its carrier concentration. Therefore, in this specification and the like, the carrier concentration assuming the state where an electric field is not applied is sometimes used as the parameter of the oxide semiconductor, instead of the donor concentration. That is, “carrier concentration” described in this specification and the like can be replaced with “donor concentration” in some cases.

Accordingly, in the case where an oxide semiconductor is used for the semiconductor layer 108, the amount of V_{O}H in the semiconductor layer 108 is preferably reduced as much as possible so that the semiconductor layer 108 becomes a highly purified intrinsic or substantially highly purified intrinsic semiconductor layer. In order to obtain such an oxide semiconductor with sufficiently reduced V_{O}H, it is important to remove impurities such as water and hydrogen in the oxide semiconductor (this treatment is sometimes referred to as dehydration or dehydrogenation treatment) and supply oxygen to the oxide semiconductor to fill an oxygen vacancy (V_{O}). When an oxide semiconductor with sufficiently reduced impurities such as V_{O}H is used for a channel formation region of a transistor, the transistor can have stable electrical characteristics. Supplying oxygen to an oxide semiconductor to fill an oxygen vacancy (V_{O}) is sometimes referred to as oxygen adding treatment.

When an oxide semiconductor is used for the semiconductor layer 108, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

A transistor using an oxide semiconductor (hereinafter, referred to as an OS transistor) has much higher field-effect mobility than a transistor using amorphous silicon. In addition, the OS transistor has an extremely low leakage current between a source and a drain in an off state (hereinafter, also referred to as off-state current), and charge accumulated in a capacitor that is connected in series with the transistor can be held for a long period. With the use of the OS transistor in a semiconductor device, the power consumption of the semiconductor device can be reduced.

The OS transistor can be used for a display apparatus. To increase the emission luminance of a light-emitting element included in a pixel circuit in the display apparatus, it is necessary to increase the amount of current flowing through the light-emitting element. To increase the amount of current, the source-drain voltage of a driving transistor included in the pixel circuit needs to be increased. Since the OS transistor has a higher breakdown voltage between a source and a drain than a transistor using silicon (hereinafter, referred to as a Si transistor), a high voltage can be applied between the source and the drain of the OS transistor. Accordingly, when the OS transistor is used as the driving transistor in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be finely set by a change in gate-source voltage; thus, the amount of current flowing through the light-emitting element can be controlled finely. Therefore, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through the OS transistor than through a Si transistor. Thus, with the use of an OS transistor as a driving transistor, current can be made flow stably to the light-emitting element, for example, even when a variation in current-voltage characteristics of the light-emitting element occurs. In other words, when the OS transistor operates in the saturation region, the source-drain current hardly changes even with an increase in the source-drain voltage; thus, the emission luminance of the light-emitting element can be stable.

As described above, with the use of an OS transistor as the driving transistor included in the pixel circuit, it is possible to achieve “inhibition of black floating”, “increase in emission luminance”, “increase in the number of gray levels”, “inhibition of variation in light-emitting elements”, and the like.

A change in electrical characteristics of an OS transistor due to irradiation with radiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, proton beams, and neutron beams).

### [Insulating Layer 110 and Insulating Layer 106]

In the transistor of one embodiment of the present invention and a semiconductor device, a display apparatus, and the like each using the transistor of one embodiment of the present invention, the insulating layers (the insulating layer 110 and the insulating layer 106) can be formed using an inorganic insulating material or an organic insulating material. The insulating layers (the insulating layer 110 and the insulating layer 106) may each have a stacked-layer structure of an inorganic insulating material and an organic insulating material.

As the inorganic insulating material, one or more of an oxide, an oxynitride, a nitride oxide, and a nitride can be used.

Note that in this specification and the like, an oxynitride refers to a material that contains more oxygen than nitrogen in its composition. A nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

The contents of oxygen and nitrogen can be analyzed by secondary ion mass spectrometry (SIMS) or X-ray photoelectron spectroscopy (XPS), for example. When the content percentage of a target element is high (e.g., higher than or equal to 0.5 atomic %, or higher than or equal to 1 atomic %), XPS is suitable. By contrast, when the content percentage of a target element is low (e.g., lower than 0.5 atomic %, or lower than 1 atomic %), SIMS is suitable. To compare the contents of elements, analysis with a combination of SIMS and XPS is further preferably used.

The film density of an insulating layer or the like can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Note that when insulating layers formed using the same material have different film densities, it is sometimes possible to identify the boundary between the insulating layers by a difference in contrast in a TEM image of a cross section.

The nitrogen content of an insulating layer can be confirmed by EDX, for example. In the case where silicon nitride, silicon oxynitride, or the like is used for the insulating layer, for example, the nitrogen content can be evaluated with the ratio of the peak height of nitrogen to the peak height of silicon. Note that in EDX, the peak of a certain element refers to a point at which the number of counts of the element reaches a local maximum value in a spectrum where the horizontal axis represents the energy of characteristic X-rays and the vertical axis represents the number of counts (the detected value) of characteristic X-rays. Alternatively, the number of counts at an energy of a characteristic X-ray unique to the element may be used to confirm a difference in nitrogen content with the ratio of the number of counts of nitrogen to the number of counts of silicon. For example, the number of counts at 1.739 keV (Si—Kα) can be used for silicon, and the number of counts at 0.392 keV (N—Kα) can be used for nitrogen.

The hydrogen concentration in an insulating layer can be evaluated by SIMS, for example.

When an insulating layer that releases oxygen is used as an insulating layer in contact with the semiconductor layer 108 or an insulating layer positioned around the semiconductor layer 108, oxygen can be supplied from the insulating layer to the semiconductor layer 108. Supplying oxygen to the channel formation region in the semiconductor layer 108 allows the amount of oxygen vacancy (V_{O}) and V_{O}H to be reduced in the semiconductor layer 108, so that the transistor can have excellent electrical characteristics and high reliability. Examples of treatment for supplying oxygen to the semiconductor layer 108 include heat treatment in an oxygen-containing atmosphere and plasma treatment in an oxygen-containing atmosphere.

Hydrogen diffusing into the semiconductor layer 108 reacts with an oxygen atom contained in an oxide semiconductor to be water, and thus sometimes forms an oxygen vacancy (V_{O}). Furthermore, V_{O}H is formed and the carrier concentration is increased in some cases. When a blocking film that inhibits hydrogen diffusion is used as the insulating layer in contact with the semiconductor layer 108 or the insulating layer positioned around the semiconductor layer 108, the amount of oxygen vacancy (V_{O}) and V_{O}H can be reduced in the semiconductor layer 108, so that the transistor can have excellent electrical characteristics and high reliability.

It is preferable that the amount of oxygen vacancy (V_{O}) and V_{O}H be small in the channel formation region of the transistor 100. Particularly in the case where the channel length L100 is short, an oxygen vacancy (V_{O}) and V_{O}H in the channel formation region greatly affect the electrical characteristics and the reliability. For example, diffusion of V_{O}H from the source region or the drain region into the channel formation region increases the carrier concentration in the channel formation region, which might cause a change in the threshold voltage or a reduction in the reliability of the transistor 100. As the channel length L100 of the transistor 100 is shorter, the influence of such diffusion of V_{O}H on the electrical characteristics and the reliability becomes greater. Reducing the amount of oxygen vacancy (V_{O}) and V_{O}H in the semiconductor layer 108, particularly in the channel formation region in the semiconductor layer 108, enables the transistor with a short channel length to have excellent electrical characteristics and high reliability.

The amount of impurities (e.g., water and hydrogen) released from the insulating layer in contact with the semiconductor layer 108 or the insulating layer positioned around the semiconductor layer 108 is preferably small. When the released amount of impurities is small, diffusion of impurities into the semiconductor layer 108 is inhibited, and the transistor can have excellent electrical characteristics and high reliability.

Due to heat applied in a step after the formation of the semiconductor layer 108, oxygen might be released from the semiconductor layer 108. However, supply of oxygen to the semiconductor layer 108 from the insulating layer in contact with the semiconductor layer 108 or the insulating layer positioned around the semiconductor layer 108 can inhibit an increase in the amount of oxygen vacancy (V_{O}) and V_{O}H. Furthermore, in a step after the formation of the semiconductor layer 108, the flexibility of the treatment temperature can be increased. Specifically, also in a step after the formation of the semiconductor layer 108, the treatment temperature can be high. Consequently, the transistor 100 can have excellent electrical characteristics and high reliability.

For the insulating layer 110, an inorganic insulating material or an organic insulating material can be used. The insulating layer 110b may have a stacked-layer structure of an inorganic insulating material and an organic insulating material.

For the insulating layer 110, an inorganic insulating material can be suitably used. As the inorganic insulating material, one or more of an oxide, an oxynitride, a nitride oxide, and a nitride can be used. For the insulating layer 110, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

The insulating layer 110 may have a stacked-layer structure of two or more layers. FIG. 1B and the like illustrate a structure in which the insulating layer 110 has a stacked structure of three layers of the insulating layer 110a, the insulating layer 110b over the insulating layer 110a, and the insulating layer 110c over the insulating layer 110b. For each of the insulating layer 110a, the insulating layer 110b, and the insulating layer 110c, the above-described material can be used. For the insulating layer 110a, the insulating layer 110b, and the insulating layer 110c, the same material or different materials may be used.

The amount of impurities (e.g., water and hydrogen) released from the insulating layer 110a, the insulating layer 110b, and the insulating layer 110c is preferably small.

The thickness of the insulating layer 110b can be larger than the thickness of the insulating layer 110a. The thickness of the insulating layer 110b can be larger than the thickness of the insulating layer 110c. The film formation speed of the insulating layer 110b is preferably high. By increasing the film formation speed of the film having a large thickness, the productivity can be increased.

The insulating layer 110a and the insulating layer 110c respectively function as blocking films that inhibit release of gas from the insulating layer 110b. For each of the insulating layer 110a and the insulating layer 110c, a material that does not easily allow diffusion of gas is preferably used. The insulating layer 110a preferably includes a region having a film density higher than that of the insulating layer 110b. The insulating layer 110c preferably includes a region having a film density higher than that of the insulating layer 110b. An insulating layer having a higher film density can have a higher property of blocking impurities (e.g., water and hydrogen). An insulating layer formed at a lower film formation speed can have a higher film density and a higher property of blocking impurities.

It is preferable to use an oxide or an oxynitride for the insulating layer 110b. A film from which oxygen is released by heating is preferably used as the insulating layer 110b. For example, silicon oxide or silicon oxynitride can be suitably used for the insulating layer 110b.

When oxygen is released from the insulating layer 110b, oxygen can be supplied to the semiconductor layer 108 from the insulating layer 110b. The insulating layer 110b preferably has a high oxygen diffusion coefficient. With a high oxygen diffusion coefficient, oxygen easily diffuses in the insulating layer 110b, so that oxygen can be efficiently supplied to the semiconductor layer 108.

The insulating layer 110a, the insulating layer 110b, and the insulating layer 110c are preferably formed by a film formation method such as a sputtering method, an ALD method, or a plasma CVD method.

In particular, a film is formed by a sputtering method as a film formation method that does not use a hydrogen gas for a film formation gas, so that a film with an extremely low hydrogen content can be formed. Thus, supply of hydrogen to the semiconductor layer 108 can be inhibited and the electrical characteristics of the transistor 100 can be stabilized. In the case where silicon oxide is formed by a sputtering method, the silicon oxide can be formed using a silicon target in an atmosphere containing an oxygen gas, for example. In the case where silicon nitride is formed by a sputtering method, the silicon nitride can be formed using a silicon target in an atmosphere containing a nitrogen gas, for example. In the case where aluminum oxide is formed by a sputtering method, the aluminum oxide can be formed using an aluminum target in an atmosphere containing an oxygen gas, for example.

Silicon oxide and silicon nitride can be formed by a PEALD method, for example. Aluminum oxide and hafnium oxide can be formed by a thermal ALD method, for example. An insulating layer formed by a PEALD method or a thermal ALD method can be dense and thus can have a high blocking property against oxygen and hydrogen.

The insulating layer 110a can be formed using a material having a higher nitrogen content than a material for the insulating layer 110b. The insulating layer 110c can be formed using a material having a higher nitrogen content than a material for the insulating layer 110b. An insulating layer having a higher nitrogen content can have a higher property of blocking impurities (e.g., water and hydrogen).

The insulating layer 110a and the insulating layer 110c are preferably less likely to transmit oxygen. The insulating layer 110a and the insulating layer 110c function as blocking films that inhibit release of oxygen from the insulating layer 110b. Moreover, the insulating layer 110a and the insulating layer 110c are preferably less likely to transmit hydrogen. The insulating layer 110a and the insulating layer 110c function as blocking films that inhibit diffusion of hydrogen into the semiconductor layer 108 from the outside of the transistor through the insulating layer 110a and the insulating layer 110c. The insulating layer 110a and the insulating layer 110c preferably have high film densities. The blocking property against oxygen and hydrogen can be enhanced by increasing the film density. In the case where silicon oxide or silicon oxynitride is used for the insulating layer 110b, silicon nitride or silicon nitride oxide can be used for each of the insulating layer 110a and the insulating layer 110c. In addition, hafnium oxide or aluminum oxide can be suitably used for each of the insulating layer 110a and the insulating layer 110c.

The insulating layer 110a and the insulating layer 110c can each have a structure in which two or more selected from silicon nitride, silicon nitride oxide, hafnium oxide, and aluminum oxide are stacked.

When oxygen contained in the insulating layer 110b diffuses upward from a region of the insulating layer 110b that is not in contact with the semiconductor layer 108 (e.g., the top surface of the insulating layer 110b), the amount of oxygen supplied from the insulating layer 110b to the semiconductor layer 108 might be reduced. Provision of the insulating layer 110c over the insulating layer 110b can inhibit upward diffusion of oxygen contained in the insulating layer 110b from the region of the insulating layer 110b that is not in contact with the semiconductor layer 108. Similarly, provision of the insulating layer 110a under the insulating layer 110b can inhibit downward diffusion of oxygen contained in the insulating layer 110b from the region of the insulating layer 110b that is not in contact with the semiconductor layer 108. Accordingly, the amount of oxygen supplied from the insulating layer 110b to the semiconductor layer 108 is increased, whereby the amount of oxygen vacancy (V_{O}) and V_{O}H in the semiconductor layer 108 can be reduced.

The conductive layer 112a and the conductive layer 112b are oxidized by oxygen contained in the insulating layer 110b and have high resistance in some cases. Moreover, when the conductive layer 112a and the conductive layer 112b are oxidized, the amount of oxygen supplied from the insulating layer 110b to the semiconductor layer 108 might be reduced. Provision of the insulating layer 110a between the insulating layer 110b and the conductive layer 112a can inhibit the conductive layer 112a from being oxidized and having high resistance. Similarly, provision of the insulating layer 110c between the insulating layer 110b and the conductive layer 112b can inhibit the conductive layer 112b from being oxidized and having high resistance. In addition, the amount of oxygen supplied from the insulating layer 110b to the semiconductor layer 108 is increased and the amount of oxygen vacancy (V_{O}) and V_{O}H in the semiconductor layer 108 can be reduced.

Provision the insulating layer 110a and the insulating layer 110c can inhibit diffusion of hydrogen into the semiconductor layer 108 and reduce the amount of oxygen vacancy (V_{O}) and V_{O}H in the semiconductor layer 108.

Each of the insulating layer 110a and the insulating layer 110c preferably has a thickness with which the insulating layer functions as a blocking film against oxygen and hydrogen. When the thickness is small, the function of a blocking film deteriorates in some cases. Meanwhile, when the thickness is large, a region of the semiconductor layer 108 that is in contact with the insulating layer 110b are narrowed and the amount of oxygen supplied to the semiconductor layer 108 is sometimes reduced. The thickness of each of the insulating layer 110a and the insulating layer 110c is preferably larger than or equal to 1 nm or larger than or equal to 2 nm, and smaller than or equal to 200 nm, smaller than or equal to 100 nm, smaller than or equal to 60 nm, smaller than or equal to 50 nm, smaller than or equal to 40 nm, smaller than or equal to 30 nm, smaller than or equal to 20 nm, smaller than or equal to 10 nm, or smaller than or equal to 5 nm.

The insulating layer 106 functioning as a gate insulating layer preferably have a low defect density. With the insulating layer 106 having a low defect density, the transistor can have excellent electrical characteristics. In addition, the insulating layer 106 preferably has a high breakdown voltage. With the insulating layer 106 having a high breakdown voltage, the transistor can have high reliability.

For the insulating layer 106, one or more of an insulating oxide, an insulating oxynitride, an insulating nitride oxide, and an insulating nitride can be used, for example. For the insulating layer 106, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga—Zn oxide can be used. The insulating layer 106 may be a single layer or stacked layers. The insulating layer 106 may have a stacked-layer structure of an oxide and a nitride, for example.

A transistor having a minute size and including a thin gate insulating layer may have a high leakage current. When a high dielectric constant material (also referred to as a high-k material) is used for the gate insulating layer, voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 106 is preferably small. With the insulating layer 106 from which a small amount of impurities is released, diffusion of impurities into the semiconductor layer 108 is inhibited, and the transistor can have excellent electrical characteristics and high reliability.

The insulating layer 106 is formed over the semiconductor layer 108, and thus are each preferably a film that can be formed under conditions where damage to the semiconductor layer 108 is small. For example, the insulating layers is preferably formed under conditions where the film formation speed (also referred to as film formation rate) is sufficiently low. For example, when the insulating layer 106 is formed by a plasma CVD method under a low-power condition, damage to the semiconductor layer 108 can be small.

Here, the insulating layer 106 will be specifically described using a structure in which a metal oxide is used for the semiconductor layer 108 as an example.

In order to improve the properties of the interface with the semiconductor layer 108, an oxide or an oxynitride is preferably used at least for the side of the insulating layer 106 that is in contact with the semiconductor layer 108. For example, one or more of silicon oxide and silicon oxynitride can be suitably used for the insulating layer 106. A film from which oxygen is released by heating is further preferably used for the insulating layer 106.

Note that the insulating layer 106 may have a stacked-layer structure. The insulating layer 106 can have a stacked-layer structure of an oxide film on the side in contact with the semiconductor layer 108 and a nitride film on the side in contact with the conductive layer 104. For example, one or more of silicon oxide and silicon oxynitride can be suitably used for the oxide film. For example, silicon nitride can be suitably used for the nitride film.

The thickness of the insulating layer 106 is preferably larger than or equal to 0.5 nm and smaller than or equal to 20 nm, further preferably larger than or equal to 0.5 nm and smaller than or equal to 15 nm, still further preferably larger than or equal to 0.5 nm and smaller than or equal to 10 nm. At least part of the insulating layer 106 includes a region having the above-described thickness.

The insulating layer 106 preferably has a function of supplying oxygen to the semiconductor layer 108.

### [Conductive Layer 112a, Conductive Layer 112b, and Conductive Layer 104]

The conductive layer 112a functioning as one of a source electrode and a drain electrode and the conductive layer 112b functioning as the second gate electrode and the other of the source electrode and the drain electrode can each be formed using one or more of chromium, copper, aluminum, gold, silver, zinc, tantalum, titanium, tungsten, manganese, nickel, iron, cobalt, molybdenum, niobium, and ruthenium; or an alloy including one or more of these metals as its components. For each of the conductive layer 112a and the conductive layer 112b, a low-resistance conductive material that contains one or more of copper, silver, gold, and aluminum can be suitably used. Copper or aluminum is particularly preferable because of its high mass-productivity.

As each of the conductive layer 112a and the conductive layer 112b, a conductive metal oxide (also referred to as an oxide conductor) can be used. Examples of the oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when an oxygen vacancy (V_{O}) is formed in a metal oxide having semiconductor characteristics and hydrogen is added to the oxygen vacancy, a donor level is formed in the vicinity of the conduction band. As a result, the conductivity of the metal oxide is increased, so that the metal oxide becomes a conductor. The metal oxide having become a conductor can be referred to as an oxide conductor.

Each of the conductive layer 112a and the conductive layer 112b may have a stacked-layer structure of a conductive film containing the oxide conductor (the metal oxide) and a conductive film containing a metal or an alloy. The use of the conductive film containing a metal or an alloy can reduce the resistance.

A Cu—X alloy film (X is Mn, Ni, Cr, Fe, Co, Mo, Ta, or Ti) may be used for each of the conductive layer 112a and the conductive layer 112b. The use of a Cu—X alloy film enables the manufacturing cost to be reduced because a wet etching process can be used in the processing.

Note that the conductive layer 112a and the conductive layer 112b may be formed using the same material or different materials.

Here, the conductive layer 112a and the conductive layer 112b will be specifically described using a structure in which a metal oxide is used for the semiconductor layer 108 as an example.

When an oxide semiconductor is used for the semiconductor layer 108, the conductive layer 112a and the conductive layer 112b are oxidized by oxygen contained in the semiconductor layer 108 and have high resistance in some cases. Moreover, when the conductive layer 112a and the conductive layer 112b are oxidized by oxygen contained in the semiconductor layer 108, the amount of oxygen vacancy (V_{O}) in the semiconductor layer 108 is increased in some cases.

Each of the conductive layer 112a and the conductive layer 112b is preferably formed using a conductive material that is less likely to be oxidized, a conductive material that maintains low electric resistance even when oxidized, or an oxide conductor. For example, titanium, In—Sn oxide (ITO), or In—Sn—Si oxide (ITSO) can be suitably used. For each of the conductive layer 112a and the conductive layer 112b, a nitride conductor may be used. Examples of the nitride conductor include tantalum nitride and titanium nitride. The conductive layer 112a and the conductive layer 112b may each have a stacked-layer structure of the above-described materials.

The conductive layer 112a and the conductive layer 112b formed using a material that is less likely to be oxidized can be inhibited from being oxidized by oxygen contained in the semiconductor layer 108 and having a high resistance. In addition, the amount of oxygen vacancies (V_{O}) can be inhibited from increasing in the semiconductor layer 108.

As described above, a material that is less likely to be oxidized is preferably used for each of the conductive layer 112a and the conductive layer 112b in contact with the semiconductor layer 108. However, the use of a material that is less likely to be oxidized might increase the resistance of the conductive layer 112a and the conductive layer 112b. For example, in the case where the conductive layer 112a and the conductive layer 112b are extended to function as wirings, the conductive layer 112a and the conductive layer 112b preferably have low resistance. In view of this, when the conductive layer 112a and the conductive layer 112b each have a stacked-layer structure, a material that is less likely to be oxidized is used for a conductive layer including a region in contact with the semiconductor layer 108 and a material with low resistance is used for a conductive layer not including a region in contact with the semiconductor layer 108, whereby the total resistance of the conductive layer 112a and the conductive layer 112b can be reduced. Furthermore, the amount of oxygen vacancy (V_{O}) and V_{O}H in the semiconductor layer 108 can be reduced.

Particularly in the case where the channel length L100 is short, an oxygen vacancy (V_{O}) and V_{O}H in the channel formation region greatly affect the electrical characteristics and the reliability, as described above. When a material that is less likely to be oxidized is used for each of the conductive layer 112a and the conductive layer 112b, an increase in the amount of oxygen vacancy (V_{O}) and V_{O}H in the semiconductor layer 108 can be inhibited. Thus, the transistor with a short channel length can have excellent electrical characteristics and high reliability.

In the case where the conductive layer 112a and the conductive layer 112b each have a stacked-layer structure, one or more of an oxide conductor and a nitride conductor can be suitably used for a conductive layer including a region in contact with the semiconductor layer 108. By contrast, a material having a lower resistance than the above-described material is preferably used for a conductive layer not including a region in contact with the semiconductor layer 108. One or more of copper, aluminum, titanium, tungsten, and molybdenum or an alloy including one or more of these metals as its components can be suitably used, for example. For example, In—Sn—Si oxide (ITSO) can be suitably used for a conductive layer including a region in contact with the semiconductor layer 108, and tungsten can be suitably used for a conductive layer not including a region in contact with the semiconductor layer 108.

Note that the structure of the conductive layer 112a is determined in accordance with wiring resistance required for the conductive layer 112a. For example, when the wiring (the conductive layer 112a) is short and requires relatively high wiring resistance, the conductive layer 112a may have a single-layer structure using a material that is less likely to be oxidized. Meanwhile, when the wiring (the conductive layer 112a) is long and requires relatively low wiring resistance, the conductive layer 112a preferably has a stacked-layer structure using a material that is less likely to be oxidized and a material with low electrical resistivity.

The conductive layer 104 functioning as the first gate electrode can be formed using one or more of chromium, copper, aluminum, gold, silver, zinc, tantalum, titanium, tungsten, manganese, nickel, iron, cobalt, molybdenum, and niobium; or an alloy containing one or more of these metals as its components, for example. A nitride and an oxide that can be used for the conductive layer 112a and the conductive layer 112b may be used for the conductive layer 104. Note that the conductive layer 104 may have a two-layer stacked structure. For example, a nitride or an oxide can be used for the lower conductive layer, and one or more of chromium, copper, aluminum, gold, silver, zinc, molybdenum, tantalum, titanium, tungsten, manganese, nickel, iron, cobalt, and niobium or an alloy containing one or more of these metals as its components can be used for the upper conductive layer.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI (Silicon On Insulator) substrate, a glass substrate, a quartz substrate, a sapphire substrate, a ceramic substrate, or an organic resin substrate may be used as the substrate 102. Alternatively, any of these substrates over which a semiconductor element is provided may be used as the substrate 102. Note that the shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. The separation layer can be used when part or the whole of a semiconductor device completed thereover is separated from the substrate 102 and transferred onto another substrate. In such a case, the transistor 100 and the like can be transferred to a substrate having low heat resistance or a flexible substrate as well.

Modification examples of the transistor will be described below. Note that in some cases, the above description is referred to for the portions already described and the description thereof is omitted.

### <Modification Example 1 of Transistor>

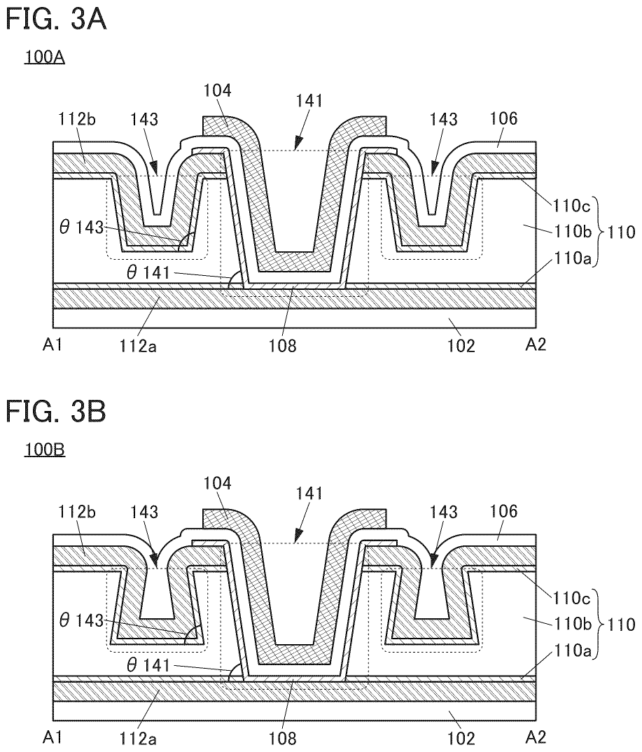

A transistor 100A illustrated in FIG. 3A is different from the transistor 100 illustrated in FIG. 1B mainly in the cross-sectional shapes of the opening 141 and the depressed portion 143.

Specifically, in the transistor 100, the inner wall of the opening 141 (the side surfaces of the insulating layer 110a, the insulating layer 110b, the insulating layer 110c, and the conductive layer 112b) and the inner wall of the depressed portion 143 (the side surface of the insulating layer 110b) are formed substantially perpendicular to the substrate surface, whereas in the transistor 100A, a tapered shape is provided.

The opening 141 has a shape with a width (the diameter of the opening 141 in the plan view) narrower toward the bottom surface. That is, in the opening 141, the width on the conductive layer 112a side is narrower than the width on the conductive layer 112b side. In this specification and the like, an opening having such a shape with a width narrower toward the bottom surface in the cross-sectional view is referred to as an opening having a “forward tapered shape” in some cases. In the case where the opening 141 has a forward tapered shape, the angle θ141 is greater than 0° and less than 90°.

Similarly, the depressed portion 143 also has a forward tapered shape. That is, in the depressed portion 143, the width on the conductive layer 112a side (the diameter of the depressed portion 143 in the plan view) is narrower than the width on the conductive layer 112b side. In this case, the angle θ143 is greater than 90° and less than 180°.

When the opening 141 and the depressed portion 143 each have a forward tapered shape, the coverage with a film formed in the opening 141 and the depressed portion 143 can be improved. In addition, the range of choices of the deposition apparatus can be widened.

### <Modification Example 2 of Transistor>

A transistor 100B illustrated in FIG. 3B is different from the transistor 100 illustrated in FIG. 1B and the transistor 100A illustrated in FIG. 3A mainly in the cross-sectional shapes of the opening 141 and the depressed portion 143.

Specifically, in the transistor 100, the inner wall of the opening 141 and the inner wall of the depressed portion 143 are formed substantially perpendicular to the substrate surface, whereas in the transistor 100B, a tapered shape is provided. In addition, in the transistor 100A, the opening 141 and the depressed portion 143 each have a forward tapered shape, whereas in the transistor 100B, the opening 141 and the depressed portion 143 have different tapered shapes.

As in the transistor 100A, the opening 141 has a forward tapered shape. That is, the angle θ141 is greater than 0° and less than 90°.

By contrast, the depressed portion 143 has a shape with a width (the diameter of the depressed portion 143 in the plan view) broader toward the bottom surface. That is, in the depressed portion 143, the width on the conductive layer 112a side is broader than the width on the conductive layer 112b side. In this specification and the like, an depressed portion having such a shape with a width broader toward the bottom surface in the cross-sectional view is referred to as an depressed portion having an “inverse tapered shape” in some cases. In the case where the depressed portion 143 has an inverse tapered shape, the angle θ143 is greater than 0° and less than 90°.

That is, in the transistor 100B, the opening 141 has a forward tapered shape and the depressed portion 143 has an inverse tapered shape. In FIG. 3B, the angle θ141 and the angle θ143 in the transistor 100B are substantially the same. In other words, the inner wall of the opening 141 and the inner wall of the depressed portion 143 that faces the inner wall of the opening 141 are substantially parallel to each other.

When the inner wall of the opening 141 and the inner wall of the depressed portion 143 are substantially parallel to each other, the second gate insulating layer (which is a region interposed between the conductive layer 112b and the semiconductor layer 108 in the insulating layer 110b and the insulating layer 110c and is also referred to as a region interposed between the opening 141 and the depressed portion 143 in the plan view) of the transistor 100B can have a substantially uniform thickness. Thus, the electric field from the conductive layer 112b functioning as the second gate electrode can be substantially uniformly applied to the back channel region of the semiconductor layer 108 that faces the conductive layer 112b. As a result, the transistor can have stable electrical characteristics and reliability.

### <Modification Example 3 of Transistor>

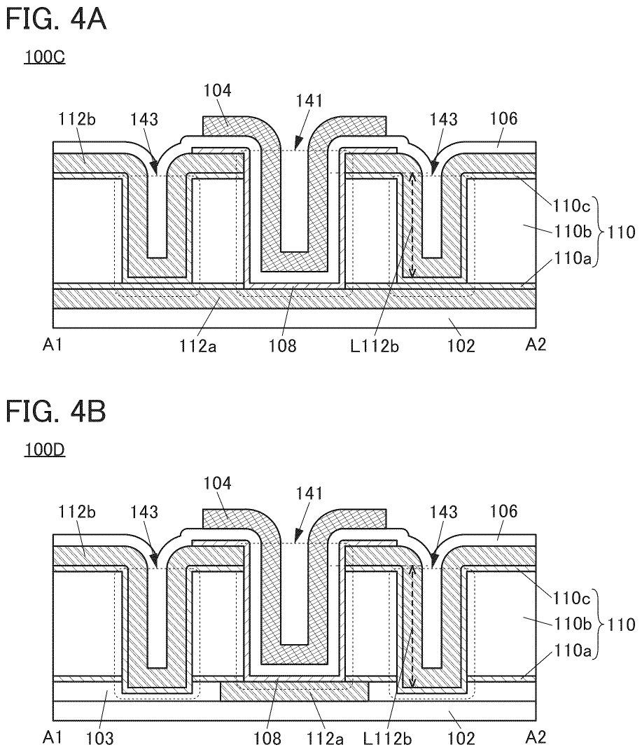

A transistor 100C illustrated in FIG. 4A is different from the transistor 100 illustrated in FIG. 1B mainly in the depth of the depressed portion 143.

Specifically, in the transistor 100, the bottom surface of the depressed portion 143 is positioned in the film of the insulating layer 110b, whereas in the transistor 100C, the bottom surface of the depressed portion 143 is positioned on the top surface of the insulating layer 110a. That is, it can be regarded that the depth of the depressed portion 143 in the transistor 100C is deeper than that in the transistor 100.

In the transistor 100C, the length L112b of the conductive layer 112b functioning as the second gate electrode is larger than the length L112b in the transistor 100. Accordingly, an electric field from the conductive layer 112b can be applied to substantially the entire back channel region of the semiconductor layer 108. As a result, the transistor can have stable electrical characteristics and reliability.

### <Modification Example 4 of Transistor>

A transistor 100D illustrated in FIG. 4B is different from the transistor 100 illustrated in FIG. 1B and the transistor 100C illustrated in FIG. 4A mainly in the shape of the conductive layer 112a and the depth of the depressed portion 143.

Specifically, in the transistor 100 and the transistor 100C, the conductive layer 112a is provided over the entire substrate 102 in the dashed-dotted line A1-A2, and the opening 141 and the depressed portion 143 are provided over the conductive layer 112a. By contrast, in the transistor 100D, the conductive layer 112a is provided over only part of the substrate 102 in the dashed-dotted line A1-A2, and the insulating layer 103 is provided to fill the conductive layer 112a. The opening 141 is provided over the conductive layer 112a, and the depressed portion 143 is provided in a region not including the conductive layer 112a. Furthermore, the bottom surface of the depressed portion 143 is positioned in the film of the insulating layer 103 below the insulating layer 110a, and the insulating layer 110c and the conductive layer 112b are provided to fill the depressed portion 143. For the insulating layer 103, any of the above-described materials that can be used for the insulating layer 110 and the insulating layer 106 can be used.

That is, it can be regarded that the depth of the depressed portion 143 in the transistor 100D is deeper than those in the transistor 100 and the transistor 100C. Thus, in the transistor 100D, the length L112b of the conductive layer 112b functioning as the second gate electrode is larger than the length L112b in the transistor 100 and the length L112b in the transistor 100C. Accordingly, an electric field from the conductive layer 112b can be surely applied to the entire back channel region of the semiconductor layer 108. As a result, the transistor can have stable electrical characteristics and reliability.

### <Modification Example 5 of Transistor>

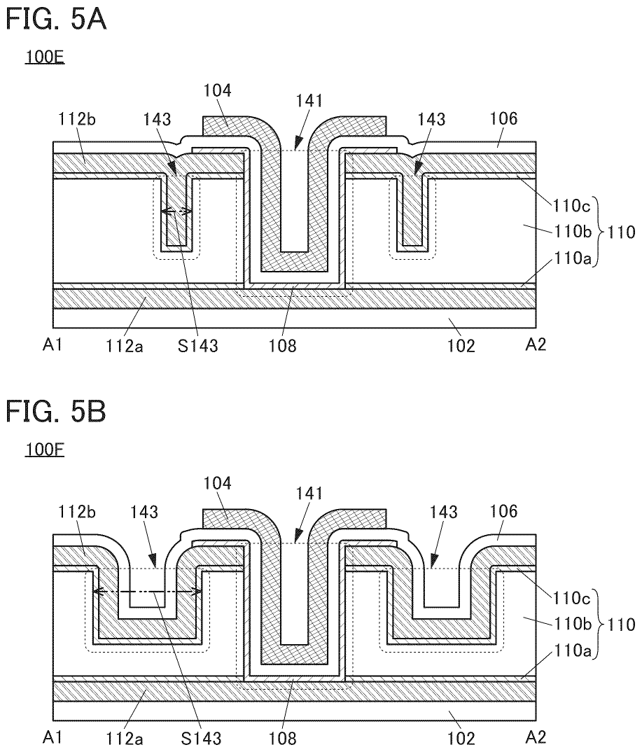

A transistor 100E illustrated in FIG. 5A is different from the transistor 100 illustrated in FIG. 1B mainly in the width of the depressed portion 143 (the diameter of the depressed portion 143 in the plan view).

Specifically, the width S143 of the depressed portion 143 in the transistor 100E is narrower than that in the transistor 100.

For example, by narrowing the width S143 of the depressed portion 143 so that the diameter of the depressed portion 143 in the plan view (see FIG. 1A) becomes smaller (i.e., by reducing the diameter on the outer periphery side of the depressed portion 143), the area occupied by the transistor in the substrate surface can be reduced. Accordingly, miniaturization of the transistor can be achieved, and high integration of the semiconductor device including the transistor can be achieved.

Furthermore, by narrowing the width S143 of the depressed portion 143 so that the diameter on the inner periphery side of the depressed portion 143 in the plan view (see FIG. 1A) becomes larger, for example, the influence of misalignment that might occur when the opening 141 is formed later can be reduced. A fabricating method of the transistor of one embodiment of the present invention will be described below.

### <Modification Example 6 of Transistor>

A transistor 100F illustrated in FIG. 5B is different from the transistor 100 illustrated in FIG. 1B and the transistor 100E illustrated in FIG. 5A mainly in the width of the depressed portion 143 (the diameter of the depressed portion 143 in the plan view).

Specifically, the width S143 of the depressed portion 143 in the transistor 100F is narrower than those in the transistor 100 and the transistor 100E.

By widening the width S143 of the depressed portion 143, the insulating layer 110c, the conductive layer 112b, and the insulating layer 106 can be surely formed to reach the bottom surface of the depressed portion 143, and thus generation of a space such as a void between these layers and the bottom surface of the depressed portion 143 can be reduced.

### <Modification Example 7 of Transistor>

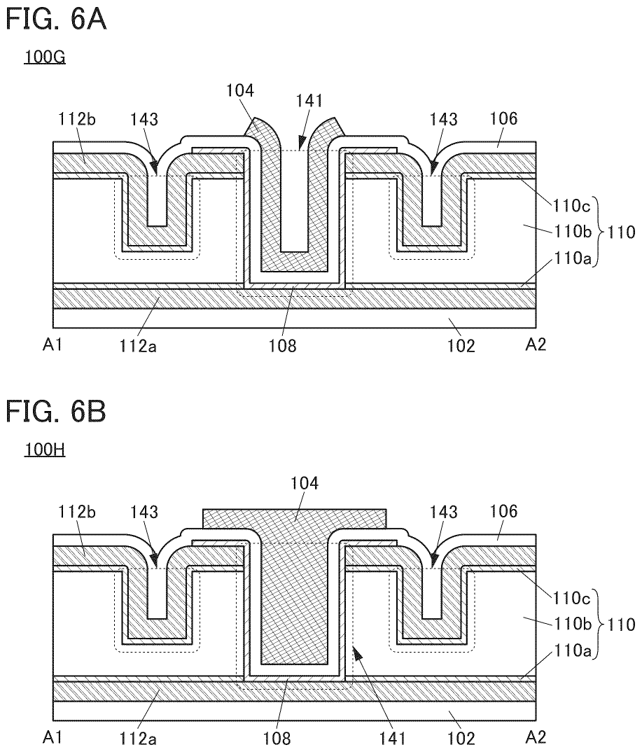

A transistor 100G illustrated in FIG. 6A is different from the transistor 100 illustrated in FIG. 1B mainly in the shape of the conductive layer 104 functioning as the first gate electrode. Specifically, in the transistor 100, the end portion of the conductive layer 104 extends to the outside of the opening 141 and is positioned on the substantially flat top surface of the insulating layer 106 (over the region where the insulating layer 110, the conductive layer 112b, and the semiconductor layer 108 overlap with each other). By contrast, the end portion of the conductive layer 104 in the transistor 100G is positioned inward (the opening 141 side) from that in the transistor 100.

In the transistor 100, the region where the conductive layer 104 and the conductive layer 112b overlap with each other can function as parasitic capacitance. Thus, by reducing the region of the conductive layer 104 extending to the outside of the opening 141 as much as possible as in the transistor 10G, the parasitic capacitance generated between the conductive layer 104 and the conductive layer 112b can be reduced. Thus, adverse effects of the parasitic capacitance on the electrical characteristics of the transistor can be inhibited.

### <Modification Example 8 of Transistor>

A transistor 100H illustrated in FIG. 6B is different from the transistor 100 illustrated in FIG. 1B and the transistor 100G illustrated in FIG. 6A mainly in the shape of the conductive layer 104 functioning as the first gate electrode.

Specifically, in the transistor 100 and the transistor 100G, the conductive layer 104 has a shape along the inner wall and the bottom surface of the opening 141, and the top surface of the conductive layer 104 has a depressed portion inside the opening 141. By contrast, in the transistor 100H, the conductive layer 104 is provided to completely fill the opening 141, and the top surface of the conductive layer 104 has a substantially flat shape.

When the conductive layer 104 has the above-described shape, unevenness of the top surface of the transistor can be reduced. Thus, the coverage with a layer formed over the transistor can be improved.

### <Modification Example 9 of Transistor>

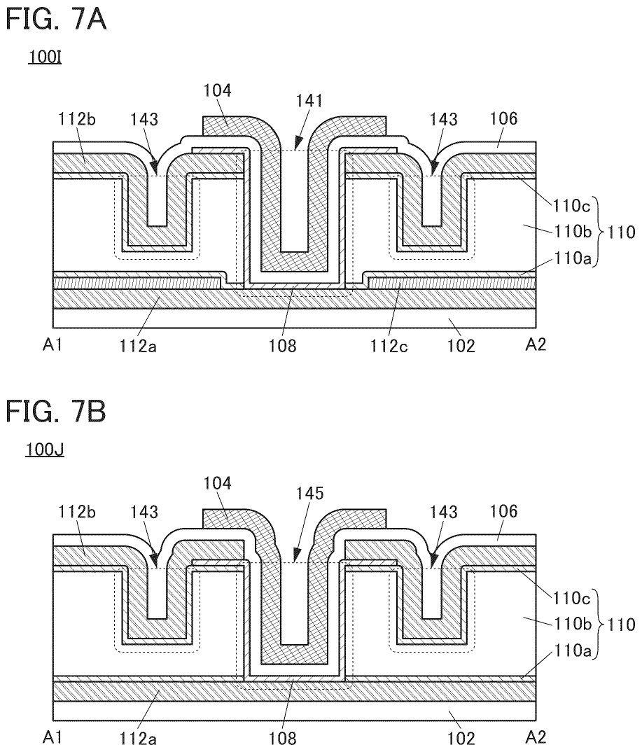

A transistor 100I illustrated in FIG. 7A is different from the transistor 100 illustrated in FIG. 1B mainly in the structure of a conductive layer functioning as one of a source electrode and a drain electrode.

Specifically, in the transistor 100, a conductive layer functioning as one of the source electrode and the drain electrode has a single-layer structure of the conductive layer 112a alone. By contrast, in the transistor 100I, part of a conductive layer functioning as one of the source electrode and the drain electrode has a stacked-layer structure of the conductive layer 112a and a conductive layer 112c.

The conductive layer 112c is provided to interpose the opening 141 over the conductive layer 112a. The insulating layer 110a is provided in contact with the bottom surface (the surface on the back channel region side) of the semiconductor layer 108, part of the top surface of the conductive layer 112a, and the conductive layer 112c whose parts face each other with the opening 141 therebetween.

In the transistor 100I, the stack of the conductive layer 112a and the conductive layer 112c functions as one of the source electrode and the drain electrode.

The conductive layer 112a includes a region in contact with the semiconductor layer 108. Accordingly, a material that is less likely to be oxidized is preferably used for the conductive layer 112a. By contrast, the conductive layer 112c that does not include a region in contact with the semiconductor layer 108 can be formed using a material that has a lower resistance than the conductive layer 112a. Note that the above description can be referred to for details of the material that is less likely to be oxidized and can be used for the conductive layer 112a and the material that has a low resistance and can be used for the conductive layer 112c. When a stack of a conductive layer that is less likely to be oxidized (the conductive layer 112a) and a conductive layer that has a low resistance (the conductive layer 112c) is used as one of the source electrode and the drain electrode as in the transistor 100I, the stack can be used also as a wiring.

### <Modification Example 10 of Transistor>

A transistor 100J illustrated in FIG. 7B is different from the transistor 100 illustrated in FIG. 1B mainly in the positional relationship between the semiconductor layer 108 and the conductive layer 112b.

Specifically, in the transistor 100J, an opening 145 reaching the conductive layer 112a is provided in the insulating layer 110, and the semiconductor layer 108 is provided in contact with the top surface of the conductive layer 112a (also referred to as the bottom surface of the opening 145), the side surface of the insulating layer 110 (also referred to as the inner wall of the opening 145), and the top surface of the insulating layer 110 to include a region overlapping with the opening 145. The conductive layer 112b is provided in contact with the top surface and the side surface of the semiconductor layer 108 and the top surface of the insulating layer 110. The conductive layer 112b is provided to fill the depressed portion 143 and includes a region overlapping with (facing) the semiconductor layer 108 with the insulating layer 110 therebetween in the depressed portion 143.

That is, the transistor 100 is a bottom-contact transistor in which the bottom surface (the surface on the substrate 102 side) of the semiconductor layer 108 is in contact with the top surface of the conductive layer 112b functioning as the other of the source electrode and the drain electrode, whereas the transistor 100J is atop-contact transistor in which the top surface of the semiconductor layer 108 is in contact with the bottom surface (the surface on the substrate 102 side) of the conductive layer 112b functioning as the other of the source electrode and the drain electrode.

As described above, the transistor of one embodiment of the present invention may be a bottom-contact transistor or a top-contact transistor depending on the application, the fabricating method, or the like.

### <Modification Example 11 of Transistor>

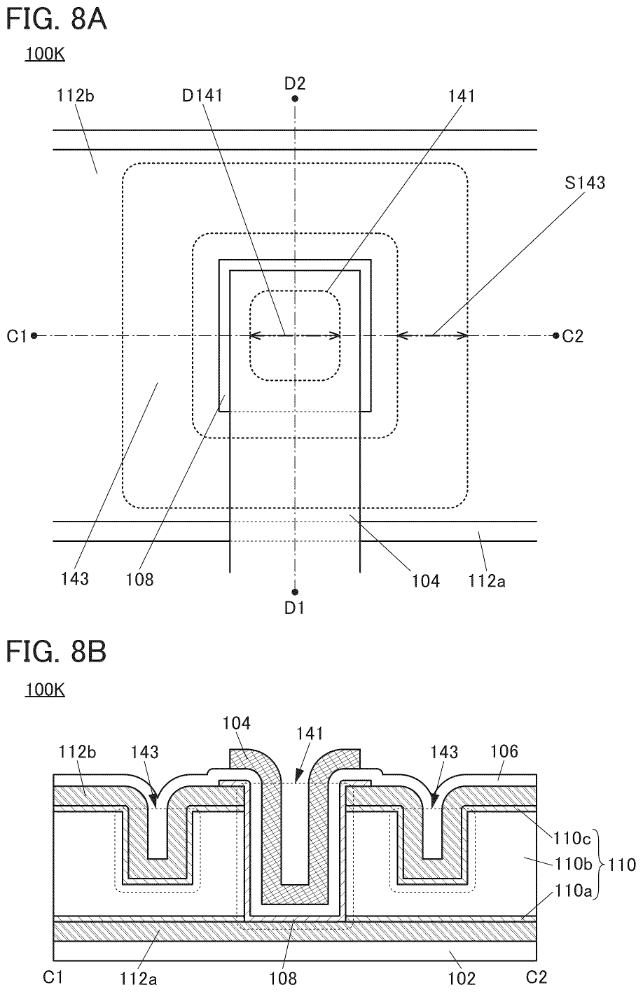

FIG. 8A is a plan view of a transistor 100K. FIG. 8B is a cross-sectional view of the transistor 100K taken along the dashed-dotted line C1-C2 in FIG. 8A. The transistor 100K is different from the transistor 100 illustrated in FIG. 1A mainly in the planar shapes of the opening 141 and the depressed portion 143.

Specifically, in the transistor 100, the planar shapes of the opening 141 and the depressed portion 143 are each substantially circular (see FIG. 1A). By contrast, in the transistor 100K, the planar shapes of the opening 141 and the depressed portion 143 are each substantially quadrangular (see FIG. 8A). On the other hand, there is almost no difference in the cross-sectional shape between the transistor 100 and the transistor 100K (see FIG. 1B and FIG. 8B).

As described above, in the transistor of one embodiment of the present invention, the planar shapes of the opening 141 and the depressed portion 143 may be non-circular. Although FIG. 8A illustrates an example in which the planar shapes of the opening 141 and the depressed portion 143 are substantially quadrangular, one embodiment of the present invention is not limited thereto. Examples of the planar shape of each of the opening 141 and the depressed portion 143 include a circle, an ellipse, polygons such as a triangle, a quadrangle (including a rectangle, a rhombus, and a square), and a pentagon, and polygons with rounded corners.

Note that the planar shape of the opening 141 and the planar shape of the depressed portion 143 are preferably the same shape. For example, in the case where the planar shape of the opening 141 is circular, the planar shape of the depressed portion 143 is also preferably circular, and in the case where the planar shape of the opening 141 is quadrangular, the planar shape of the depressed portion 143 is also preferably quadrangular. In plan views (see FIG. 1A and FIG. 8A), the center of the opening 141 and the center of the depressed portion 143 preferably coincide with each other to the extent possible. This enables the second gate insulating layer in the transistor of one embodiment of the present invention to have a substantially uniform thickness in any region. Thus, the electric field from the conductive layer 112b functioning as the second gate electrode can be substantially uniformly applied to the back channel region of the semiconductor layer 108 that faces the conductive layer 112b. As a result, the transistor can have stable electrical characteristics and reliability.

As described above, since the transistor of one embodiment of the present invention has the second gate electrode, the saturation in the I_{d}-V_{d} characteristics of the transistor can be increased. In that case, for example, in the case where the transistor is used in a semiconductor device including a display portion, the number of gray levels expressed by the display portion can be increased. The emission luminance of the display portion can be stable.

Furthermore, the transistor of one embodiment of the present invention has high reliability. This can improve the reliability of a semiconductor device including the transistor. Specifically, degradation of transistor characteristics in a state where a voltage is applied to the first gate electrode can be inhibited. For example, in an n-channel transistor, degradation of characteristics in a state where a positive potential with respect to a source potential is applied to the first gate electrode can be inhibited.

In the transistor of one embodiment of the present invention, the threshold voltage is suitably controlled and normally-off characteristics can be easily obtained. A structure in which the second gate electrode is electrically connected to the source electrode (a combined-use structure) can suitably prevent an n-channel transistor from having a negative threshold voltage value, for example.

Since the channel length of the transistor of one embodiment of the present invention can be set to an extremely small value, a transistor with a high on-state current can be achieved. Thus, the frequency characteristics of the transistor can be improved, for example. Accordingly, for example, the operation speed of the semiconductor device using the transistor can be increased.

As described above, in the transistor of one embodiment of the present invention, one conductive layer (the conductive layer 112b) has both a function of the second gate electrode and a function of the other of the source electrode and the drain electrode. Thus, the number of wirings in the circuit including the transistor of one embodiment of the present invention can be smaller than that in the case where the second gate electrode and the other of the source electrode and the drain electrode are provided separately. Thus, the whole circuit can be simplified. Furthermore, the number of manufacturing steps is reduced and the productivity can be improved.

### <Fabricating Method Example of Transistor>

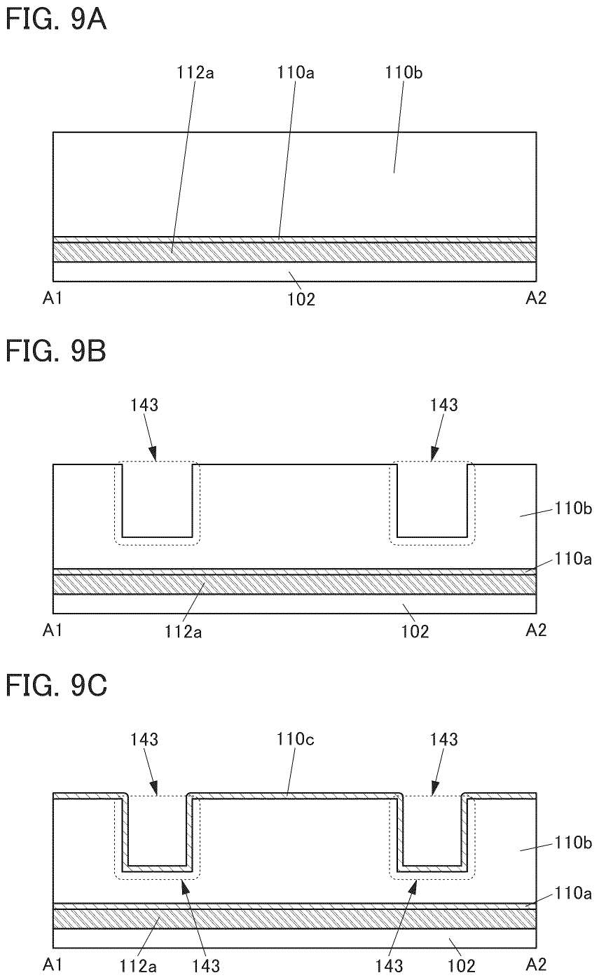

A method for fabricating the transistor of one embodiment of the present invention will be described below with reference to drawings (FIG. 9A to FIG. 11C). Here, an example of fabricating the transistor 100 illustrated in FIG. 1B is described.

Note that thin films that form the transistor 100 (insulating films, semiconductor films, conductive films, and the like) can be formed by a sputtering method, a chemical vapor deposition (CVD) method, a vacuum evaporation method, a pulsed laser deposition (PLD) method, an ALD method, or the like.

Examples of the sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is formed by a reactive sputtering method.

The CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. The thermal CVD method is a film formation method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during film formation, so that a film with few defects can be obtained.

As the ALD method, a thermal ALD method, in which a precursor and a reactant react with each other only by a thermal energy, a PEALD method, in which a reactant excited by plasma is used, or the like can be used.

The CVD method and the ALD method are different from the sputtering method in which particles ejected from a target or the like are deposited. Thus, the CVD method and the ALD method are film formation methods that enable good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low film formation speed, and thus is preferably used in combination with another film formation method with a high film formation speed, such as the CVD method, in some cases.

By the CVD method, a film with a certain composition can be formed depending on the flow rate ratio of the source gases. For example, by the CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By the ALD method, a film with a certain composition can be formed by concurrently introducing different kinds of precursors. In the case where different kinds of precursors are introduced, a film with a certain composition can be formed by controlling the number of cycles for each of the precursors.

The thin films that form the transistor 100 (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

When the thin films that form the transistor 100 are processed, a photolithography method or the like can be used. Alternatively, a nanoimprinting method, a sandblasting method, a lift-off method, or the like may be used for the processing of the thin films. Island-shaped thin films may be directly formed by a film formation method using a blocking mask such as a metal mask.

There are the following two typical examples of a photolithography method. In one of the methods, a resist mask is formed over a thin film that is to be processed, the thin film is processed by etching or the like, and the resist mask is removed. In the other method, a photosensitive thin film is formed and then the thin film is processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. In addition, light exposure may be performed by liquid immersion exposure technique. As the light used for light exposure, extreme ultraviolet (EUV) light or X-rays may be used. Instead of the light used for light exposure, an electron beam can be used. It is preferable to use extreme ultraviolet light, X-rays, or an electron beam because extremely fine processing can be performed. Note that in the case of performing light exposure by scanning of a beam such as an electron beam, a photomask is not needed.

For etching of the thin film, a dry etching method, a wet etching method, or a sandblasting method can be used, for example. These etching methods may be employed in combination.

An example of a fabricating method of the transistor 100 is described below.

First, the conductive layer 112a is formed over the substrate 102, and the insulating layer 110a and the insulating layer 110b are formed in this order over the conductive layer 112a (see FIG. 9A).

For the substrate 102, any of the above-described materials can be used, for example.

The conductive layer 112a can be formed with the above-described material by a sputtering method, for example.

The insulating layer 110a and the insulating layer 110b can be formed with the above-described material by a PECVD method, for example. The insulating layer 110a and the insulating layer 110b are preferably formed successively in a vacuum without exposure to the air. Such formation can inhibit attachment of atmospherically derived impurities to the surface of the insulating layer 110a. Examples of the impurities include water and organic substances.

The substrate temperature at the time of forming the insulating layer 110a and the insulating layer 110b is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. With the substrate temperature at the time of forming the insulating layer (film) in the above range, impurities (e.g., water and hydrogen) released from the insulating layer itself can be decreased, which inhibits the diffusion of the impurities to the semiconductor layer 108 to be formed later. Consequently, a transistor with excellent electrical characteristics and high reliability can be provided.

Since the formation of the insulating layer 110a and the insulating layer 110b precedes the formation of the semiconductor layer 108, heat applied in the formation of the insulating layers (films) is unlikely to cause the release of oxygen from the semiconductor layer 108.

After the insulating layer 110b is formed, heat treatment may be performed. By performing the heat treatment, water and hydrogen can be released from the surface and inside of the insulating layer 110b.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a rare gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating layer 110 can be prevented as much as possible. An oven, a rapid thermal annealing (RTA) apparatus, or the like can be used for the heat treatment. The use of the RTA apparatus can shorten the heat treatment time.

After the formation of the insulating layer 110b, treatment for supplying oxygen to the insulating layer 110b may be performed.

In one embodiment of the present invention, a metal oxide layer is formed over the insulating layer 110b after the formation of the insulating layer 110b to supply oxygen to the insulating layer 110b. After the formation of the metal oxide layer, heat treatment may be performed. By the heat treatment performed after the formation of the metal oxide layer, oxygen can be effectively supplied from the metal oxide layer to the insulating layer 110b, and oxygen can be contained in the insulating layer 110b. Oxygen supplied to the insulating layer 110b is supplied to the semiconductor layer 108 in a later step, whereby oxygen vacancies (V_{O}) and V_{O}H in the semiconductor layer 108 can be reduced.

After the formation of the metal oxide layer or after the above-described heat treatment, oxygen may be further supplied to the insulating layer 110b through the metal oxide layer. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include a plasma etching apparatus and a plasma ashing apparatus.

The metal oxide layer may be an insulating layer or a conductive layer. For the metal oxide layer, aluminum oxide, hafnium oxide, hafnium aluminate, indium oxide, indium tin oxide (ITO), or indium tin oxide containing silicon (ITSO) can be used, for example.

An oxide material containing one or more elements that are the same as those in the semiconductor layer 108 is preferably used for the metal oxide layer. It is particularly preferable to use an oxide semiconductor material that can be used for the semiconductor layer 108.

The metal oxide layer is preferably formed in, for example, an oxygen-containing atmosphere. It is particularly preferable that the metal oxide layer be formed by a sputtering method in an oxygen-containing atmosphere. In that case, oxygen can be suitably supplied to the insulating layer 110b at the time of forming the metal oxide layer.

Then, the metal oxide layer is removed. For the removal of the metal oxide layer, a wet etching method can be suitably used, for example.

The treatment for supplying oxygen to the insulating layer 110b is not necessarily performed by the above-described method. An oxygen radical, an oxygen atom, an oxygen atomic ion, an oxygen molecular ion, or the like may be supplied to the insulating layer 110b by an ion doping method, an ion implantation method, plasma treatment, or the like, for example. Alternatively, a film that inhibits oxygen release may be formed over the insulating layer 110b and then oxygen may be supplied to the insulating layer 110b through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

Next, a resist mask is formed over the insulating layer 110b by a photolithography process (not illustrated), and then the insulating layer 110b is processed, whereby the depressed portion 143 is formed in the insulating layer 110b (see FIG. 9B). For the formation of the depressed portion 143, a dry etching method can be suitably used, for example.

Next, the insulating layer 110c is formed to cover the top surface of the insulating layer 110b (including the inner wall and the bottom surface of the depressed portion 143) (see FIG. 9C). The insulating layer 110c can be formed with the above-described material by a PECVD method, for example. The insulating layer 110c is preferably formed using the same material as the insulating layer 110a.

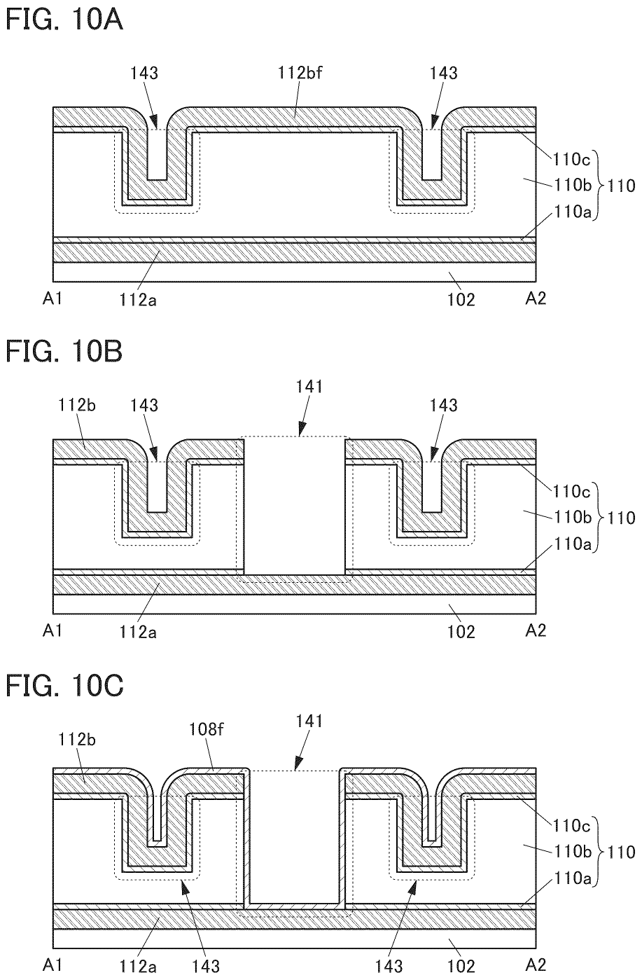

Then, a conductive film 112bf to be the conductive layer 112b later is formed over the insulating layer 110c (see FIG. 10A). The conductive film 112bf can be formed with the above-described material by a sputtering method, for example.

Next, a resist mask is formed over the conductive film 112bf by a photolithography process (not illustrated). The resist mask is formed in a position excluding a region surrounded by the depressed portion 143 (a position as close as possible to the center of the region) in the plan view (see FIG. 1A). After that, the conductive film 112bf, the insulating layer 110c, the insulating layer 110b, and the insulating layer 110a are processed to form the opening 141 reaching the conductive layer 112a in the conductive film 112bf, the insulating layer 110c, the insulating layer 110b, and the insulating layer 110a (see FIG. 10B). Note that the conductive layer 112b is formed from the conductive film 112bf by the processing.

As described above, in one embodiment of the present invention, the depressed portion 143 is formed in the insulating layer 110b in advance, and then the conductive film 112bf in the region surrounded by the depressed portion 143 is processed, whereby the opening 141 and the conductive layer 112b are formed. The conductive layer 112b is a conductive layer that functions as the second gate electrode and the other of the source electrode and the drain electrode of the transistor 100 later. Thus, the number of steps can be smaller than that in the case where the second gate electrode and the other of the source electrode and the drain electrode are formed separately.

Next, a metal oxide film 108f to be the semiconductor layer 108 later is formed to cover the top surface of the conductive layer 112b, the top surface of the conductive layer 112a (i.e., the bottom surface of the opening 141), and the side surfaces of the conductive layer 112b, the insulating layer 110c, the insulating layer 110b, and the insulating layer 110a (i.e., the inner wall of the opening 141) (see FIG. 10C). The metal oxide film 108f is preferably formed by a sputtering method using a metal oxide target.

The metal oxide film 108f is preferably a dense film with as few defects as possible. The metal oxide film 108f is preferably a highly purified film in which impurities containing hydrogen elements are reduced as much as possible. It is particularly preferable to use a metal oxide film having crystallinity as the metal oxide film 108f.

In forming the metal oxide film 108f, an oxygen gas and an inert gas (such as a helium gas, an argon gas, or a xenon gas) may be mixed. The higher the proportion of the oxygen gas in the whole film formation gas (oxygen flow rate ratio) is in forming the metal oxide film 108f, the higher the crystallinity of the metal oxide film 108f can be in some cases. Thus, the transistor 100 can have high reliability in some cases. By contrast, the lower the oxygen flow rate ratio is, the lower the crystallinity of the metal oxide film 108f is in some cases. Thus, the transistor 100 can have high on-state current in some cases.

In forming the metal oxide film 108f, as the substrate temperature becomes higher, the denser metal oxide film having higher crystallinity can be formed in some cases. On the other hand, as the substrate temperature becomes lower, the metal oxide film 108f having lower crystallinity and higher electric conductivity can be formed in some cases.

The substrate temperature at the time of forming the metal oxide film 108f is higher than or equal to room temperature and lower than or equal to 250° C., preferably higher than or equal to room temperature and lower than or equal to 200° C., further preferably higher than or equal to room temperature and lower than or equal to 140° C. For example, the substrate temperature is preferably higher than or equal to room temperature and lower than or equal to 140° C., in which case productivity is increased.

In the case where the semiconductor layer 108 has a stacked-layer structure, an upper metal oxide film is preferably formed successively after the formation of a lower metal oxide film without exposure of the surface of the lower metal oxide film to the air.

For example, in the case where a metal oxide is used for the semiconductor layer 108, the semiconductor layer can be formed by an ALD method using an oxidizer and a precursor containing a constituent metal element.

For example, in the case where In—Ga—Zn oxide is formed, three precursors of a precursor containing indium, a precursor containing gallium, and a precursor containing zinc can be used. Alternatively, two precursors of a precursor containing indium and a precursor containing gallium and zinc may be used.

As the precursor containing indium, triethylindium, tris(2,2,6,6-tetramethyl-3,5-heptanedionato)indium, cyclopentadienylindium, indium(III) chloride, (3-(dimethylamino)propyl)dimethylindium, or the like can be used.

As the precursor containing gallium, trimethylgallium, triethylgallium, tris(dimethylamido)gallium(III), gallium(III) acetylacetonate, tris(2,2,6,6-tetramethyl-3,5-heptanedionato)gallium, dimethylchlorogallium, diethylchlorogallium, gallium(III) chloride, or the like can be used.

As the precursor containing zinc, dimethylzinc, diethylzinc, bis(2,2,6,6-tetramethyl-3,5-heptanedionato)zinc, zinc chloride, or the like can be used.

Ozone, oxygen, water, or the like can be used as the oxidizer, for example.

As an example of a method for controlling the composition of a film to be obtained, adjusting the flow rate ratio of the source gases, the flowing time of the source gases, the flowing order of the source gases, or the like is given. By adjusting such conditions, a film whose composition is continuously changed can be formed. Furthermore, films having different compositions can be formed successively.

Heat treatment may be performed after the formation of the metal oxide film 108f. By the heat treatment, water or hydrogen can be released from the surface and inside of the metal oxide film 108f. By the heat treatment, oxygen can be supplied from the insulating layer 110b to the metal oxide film 108f. Furthermore, the film quality of the metal oxide film 108f is improved (e.g., the number of defects is reduced or crystallinity is increased) by the heat treatment in some cases. As the conditions for the heat treatment, the conditions for the above heat treatment that can be used after the formation of the insulating layer 110a and the insulating layer 110b can be used.

Note that the heat treatment is not necessarily performed. The heat treatment is not necessarily performed in this step, and heat treatment performed in a later step may also serve as the heat treatment in this step. In some cases, treatment at a high temperature (e.g., film formation step) or the like in a later step can serve as the heat treatment in this step.

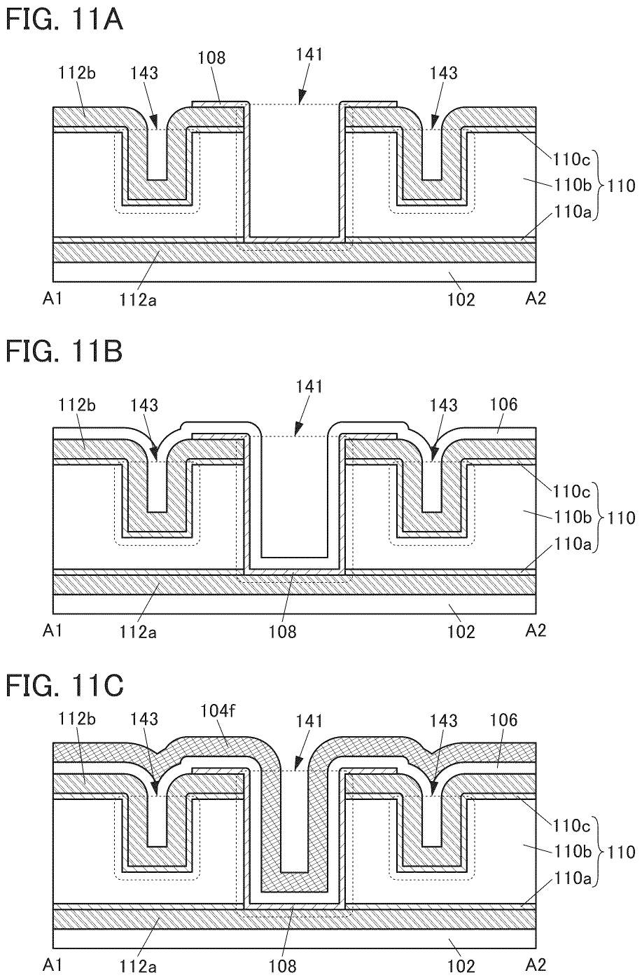

Next, the metal oxide film 108f is processed into an island shape to include a region overlapping with the inner wall of the opening 141, whereby the semiconductor layer 108 is formed (see FIG. 11A).

For the formation of the semiconductor layer 108, either one or both of a wet etching method and a dry etching method can be used. For example, a wet etching method can be suitably used to form the semiconductor layer 108.

Next, the insulating layer 106 is formed to cover the semiconductor layer 108 and the top surface of the conductive layer 112b (see FIG. 11B). The insulating layer 106 can be formed with the above-described material by a PECVD method, for example.

When an oxide semiconductor is used for the semiconductor layer 108, an insulating material in which oxygen is contained and hydrogen is reduced is preferably used for the insulating layer 106. Thus, the semiconductor layer 108 including a region in contact with the insulating layer 106 is less likely to have n-type conductivity. In addition, oxygen can be supplied from the insulating layer 106 to the semiconductor layer 108 efficiently, and accordingly, oxygen vacancies (V_{O}) in the semiconductor layer 108 can be reduced. The semiconductor layer 108 functions as the semiconductor layer where the channel of the transistor 100 is formed later. Thus, the insulating layer 106 using the material described above allows the transistor 100 to have excellent electrical characteristics and high reliability.

When the temperature at the time of forming the insulating layer 106 functioning as the gate insulating layer of the transistor 100 is increased, an insulating layer with few defects can be obtained. However, the high temperature at the time of forming the insulating layer 106 sometimes allows release of oxygen from the semiconductor layer 108, which increases the oxygen vacancies (V_{O}) and V_{O}H, which is generated when hydrogen enters an oxygen vacancy, in the semiconductor layer 108. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, the transistor 100 can have excellent electrical characteristics and high reliability.

Before the formation of the insulating layer 106, a surface of the semiconductor layer 108 may be subjected to plasma treatment. By the plasma treatment, impurities such as water adsorbed on the surface of the semiconductor layer 108 can be reduced. Accordingly, impurities at the interface between the semiconductor layer 108 and the insulating layer 106 can be reduced, enabling the transistor 100 to have high reliability. The plasma treatment is particularly preferable in the case where the surface of the semiconductor layer 108 is exposed to the air in the process from formation of the semiconductor layer 108 to formation of the insulating layer 106. The plasma treatment can be performed in an atmosphere of oxygen, ozone, nitrogen, dinitrogen monoxide, argon, or the like. The plasma treatment and the formation of the insulating layer 106 are preferably performed successively without exposure to the air.

Then, a conductive film 104f to be the conductive layer 104 later is formed over the insulating layer 106 (see FIG. 11C). The conductive film 104f can be formed with the above-described material by a sputtering method, for example.

Next, a resist mask is formed over the conductive film 104f by a photolithography process (not illustrated). Note that the resist mask is provided to include at least a region overlapping with the opening 141. After that, the conductive film 104f is processed through the resist mask, whereby the conductive layer 104 including a region overlapping with the opening 141 is formed. The conductive layer 104 is a conductive layer to be the gate electrode of the transistor 100. For the formation of the conductive layer 104, either one or both of a wet etching method and a dry etching method can be used. For example, a wet etching method can be suitably used to form the conductive layer 104.

Through the above, the transistor 100 can be fabricated (see FIG. 1B).

Since the transistor of one embodiment of the present invention is a kind of vertical transistor as described above, a source electrode, a semiconductor layer, and a drain electrode can be provided to overlap with each other over a substrate. Thus, the area occupied by the transistor in the substrate surface can be significantly small as compared with a planar transistor or the like, for example. The transistor of one embodiment of the present invention can have an extremely small channel length and has the second gate electrode; thus, the transistor can have a high on-state current and high saturation in the I_{d}-V_{d} characteristics. In addition, higher reliability can be achieved. Furthermore, in the transistor of one embodiment of the present invention, one conductive layer has both a function of the second gate electrode and a function of the other of the source electrode and the drain electrode. Thus, the number of wirings in the circuit including the transistor can be smaller than that in the case where the second gate electrode and the other of the source electrode and the drain electrode are provided separately, so that the whole circuit can be simplified. Furthermore, the number of manufacturing steps is reduced and the productivity can be improved.

This embodiment can be combined with the other embodiments as appropriate. In this specification, in the case where a plurality of structure examples are shown in one embodiment, the structure examples can be combined as appropriate.

### Embodiment 2

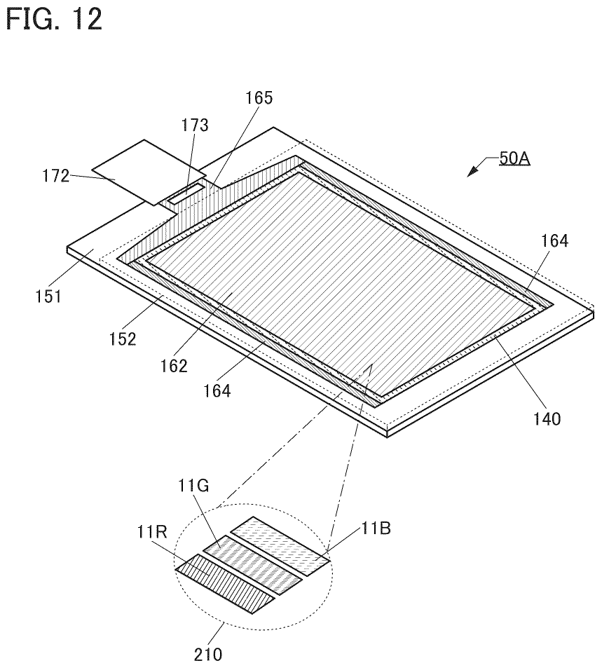

In this embodiment, a display apparatus including the transistor of one embodiment of the present invention will be described with reference to FIG. 12 to FIG. 20F.

The display apparatus of this embodiment can be a high-definition display apparatus or large-sized display apparatus. Accordingly, the display apparatus of this embodiment can be used for display portions of a digital camera, a digital video camera, a digital photo frame, a mobile phone, a portable game machine, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine, for example.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display apparatus or a module including the display apparatus. Examples of the module including the display apparatus include a module in which a connector such as a flexible printed circuit board (hereinafter, referred to as an FPC) or a TCP (Tape Carrier Package) is attached to the display apparatus and a module that is mounted with an integrated circuit (IC) by a COG (Chip On Glass) method, a COF (Chip On Film) method, or the like.

### [Display Apparatus 50A]

FIG. 12 is a perspective view of a display apparatus 50A.

The display apparatus 50A has a structure in which a substrate 152 and a substrate 151 are bonded to each other. In FIG. 12, the substrate 152 is indicated by a dashed line.

The display apparatus 50A includes a display portion 162, a connection portion 140, a circuit portion 164, a wiring 165, and the like. FIG. 12 illustrates an example in which an IC 173 and an FPC 172 are mounted on the display apparatus 50A. Thus, the structure illustrated in FIG. 12 can be regarded as a display module including the display apparatus 50A, the IC, and the FPC.

The connection portion 140 is provided outside the display portion 162. The connection portion 140 can be provided along one or more sides of the display portion 162. The number of connection portions 140 may be one or more. FIG. 12 illustrates an example in which the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The wiring 165 has a function of supplying a signal and power to the display portion 162 and the circuit portion 164. The signal and power are input to the wiring 165 from the outside through the FPC 172 or input to the wiring 165 from the IC 173.

FIG. 12 illustrates an example in which the IC 173 is provided on the substrate 151 by a COG method, a COF method, or the like. An IC including one or both of a scan line driver circuit and a signal line driver circuit can be used as the IC 173, for example. Note that the display apparatus 50A and the display module are not necessarily provided with an IC. The IC may be mounted on the FPC by a COF method or the like.

The transistor of one embodiment of the present invention can be used for one or both of the display portion 162 and the circuit portion 164 of the display apparatus 50A, for example.

In the case where the transistor of one embodiment of the present invention is used for a pixel circuit of the display apparatus, the area occupied by the pixel circuit can be reduced and the display apparatus can have a high resolution, for example. In the case where the transistor of one embodiment of the present invention is used for a driver circuit (e.g., one or both of a gate line driver circuit and a source line driver circuit) of the display apparatus, the area occupied by the driver circuit can be reduced and the display apparatus can have a narrow bezel, for example. Since the transistor of one embodiment of the present invention has excellent electrical characteristics, a display apparatus can have increased reliability by using the transistor.

The display portion 162 of the display apparatus 50A is a region where an image is to be displayed, and includes a plurality of pixels 210 that are periodically arranged. FIG. 12 shows an enlarged view of one pixel 210.

There is no particular limitation on the arrangement of the pixels in the display apparatus of this embodiment, and any of a variety of methods can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 12 includes a subpixel 11R that emits red light, a subpixel 11G that emits green light, and a subpixel 11B that emits blue light.

The subpixel 11R, the subpixel 11G, and the subpixel 11B each include a display element and a circuit for controlling the driving of the display element.

Any of a variety of elements can be used as the display element, and a liquid crystal element or a light-emitting element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

Examples of the liquid crystal element include a transmissive liquid crystal element, a reflective liquid crystal element, and a transflective liquid crystal element.

Examples of the light-emitting element include self-luminous light-emitting elements such as an LED, an OLED (Organic LED), and a semiconductor laser. As the LED, a mini LED, a micro LED, or the like can be used, for example.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a Thermally Activated Delayed Fluorescence (TADF) material), and an inorganic compound (e.g., a quantum dot material).

The emission color of the light-emitting element can be infrared, red, green, blue, cyan, magenta, yellow, white, or the like. When the light-emitting element has a microcavity structure, the color purity can be increased.

One of a pair of electrodes included in the light-emitting element functions as an anode, and the other electrode functions as a cathode.

In this embodiment, the case where a light-emitting element is used as the display element is mainly described as an example.

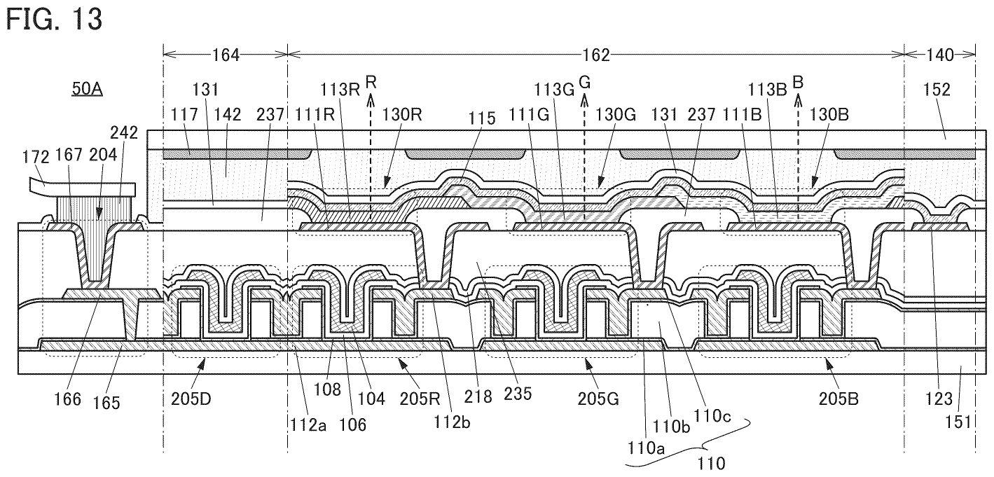

The display apparatus of one embodiment of the present invention can have any of a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces. FIG. 13 illustrates an example of cross sections of part of a region including the FPC 172, part of the circuit portion 164, part of the display portion 162, part of the connection portion 140, and part of a region including the end portion of the display apparatus 50A.

The display apparatus 50A illustrated in FIG. 13 includes a transistor 205D, a transistor 205R, a transistor 205G, and a transistor 205B, a light-emitting element 130R, a light-emitting element 130G, a light-emitting element 130B, and the like between the substrate 151 and the substrate 152. The light-emitting element 130R is a display element included in the subpixel 11R that emits red light, the light-emitting element 130G is a display element included in the subpixel 11G that emits green light, and the light-emitting element 130B is a display element included in the subpixel 11B that emits blue light.

The display apparatus 50A employs an SBS structure. The SBS structure can optimize materials and structures of light-emitting elements and thus can extend freedom of choice of materials and structures, whereby the luminance and the reliability can be easily improved.

The display apparatus 50A has atop-emission structure. The aperture ratio of pixels in a top-emission structure can be higher than that of pixels in a bottom-emission structure because a transistor and the like can be provided to overlap with a light-emitting region of a light-emitting element in the top-emission structure.

All of the transistor 205D, the transistor 205R, the transistor 205G, and the transistor 205B are formed over the substrate 151. These transistors can be fabricated using the same material through the same process.

This embodiment describes an example in which OS transistors are used as the transistor 205D, the transistor 205R, the transistor 205G, and the transistor 205B. The transistor of one embodiment of the present invention can be used as each of the transistor 205D, the transistor 205R, the transistor 205G, and the transistor 205B. In other words, the display apparatus 50A includes the transistor of one embodiment of the present invention in both the display portion 162 and the circuit portion 164. When the display portion 162 includes the transistor of one embodiment of the present invention, the pixel size can be reduced and a high resolution can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

Specifically, the transistor 205D, the transistor 205R, the transistor 205G, and the transistor 205B each include the conductive layer 104 functioning as the first gate electrode, the insulating layer 106 functioning as the first gate insulating layer, the conductive layer 112a functioning as one of a source electrode and a drain electrode, the conductive layer 112b functioning as the second gate electrode and the other of the source electrode and the drain electrode, the semiconductor layer 108 including a metal oxide, and the insulating layer 110 (the insulating layer 110a, the insulating layer 110b, and the insulating layer 110c) functioning as the second gate insulating layer. Here, a plurality of layers obtained by processing the same conductive film are shown with the same hatching pattern. The insulating layer 110 is positioned between the conductive layer 112b and the semiconductor layer 108. The insulating layer 106 is positioned between the conductive layer 104 and the semiconductor layer 108.

Note that the transistor included in the display apparatus of this embodiment is not limited to the transistor of one embodiment of the present invention. For example, the display apparatus may include the transistor of one embodiment of the present invention and a transistor having another structure in combination.

The display apparatus of this embodiment may include one or more of a planar transistor, a staggered transistor, and an inverted staggered transistor. A transistor included in the display apparatus of this embodiment may have either a top-gate structure or a bottom-gate structure. Gate electrodes may be provided above and below a semiconductor layer where a channel is formed.

The display apparatus of this embodiment may include a transistor using silicon in its channel formation region (a Si transistor).

Examples of silicon include single crystal silicon, polycrystalline silicon, and amorphous silicon. In particular, a transistor including LTPS in a semiconductor layer (hereinafter, also referred to as an LTPS transistor) can be used. The LTPS transistor has high field-effect mobility and excellent frequency characteristics.

To increase the emission luminance of the light-emitting element included in the pixel circuit, it is necessary to increase the amount of current flowing through the light-emitting element. To increase the amount of current, it is necessary to increase the source-drain voltage of a driving transistor included in the pixel circuit. Since an OS transistor has a higher breakdown voltage between the source and the drain than a Si transistor, a high voltage can be applied between the source and the drain of the OS transistor. Thus, with the use of an OS transistor as a driving transistor included in the pixel circuit, the amount of current flowing through the light-emitting element can be increased, resulting in an increase in emission luminance of the light-emitting element.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be finely set by a change in gate-source voltage; thus, the amount of current flowing through the light-emitting element can be controlled. Therefore, the number of gray levels in the pixel circuit can be increased.

Regarding saturation characteristics of current flowing when a transistor operates in a saturation region, current (saturation current) can flow more stably in an OS transistor than in a Si transistor even when the source-drain voltage gradually increases. Thus, with the use of an OS transistor as a driving transistor, current can be made to flow stably through the light-emitting element, for example, even when a variation in current-voltage characteristics of an EL element occurs. In other words, when the OS transistor operates in the saturation region, the source-drain current hardly changes with a change in the source-drain voltage; thus, the emission luminance of the light-emitting element can be stable.

The transistor included in the circuit portion 164 and the transistor included in the display portion 162 may have the same structure or different structures. The same structure or two or more kinds of structures may be employed for a plurality of transistors included in the circuit portion 164. Similarly, the same structure or two or more kinds of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. Note that a structure in which an LTPS transistor and an OS transistor are used in combination is referred to as LTPO in some cases. As a favorable example, a structure is given in which an OS transistor is used as a transistor or the like functioning as a switch for controlling electrical continuity and discontinuity between wirings and an LTPS transistor is used as a transistor or the like for controlling a current.

For example, one of the transistors included in the display portion 162 functions as a transistor for controlling current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or lower); thus, power consumption can be reduced by stopping the driver in displaying a still image.

An insulating layer 218 is provided to cover the transistor 205D, the transistor 205R, the transistor 205G, and the transistor 205B and an insulating layer 235 is provided over the insulating layer 218.

The insulating layer 218 preferably functions as a protective layer of the transistors. A material that does not easily allow diffusion of impurities such as water and hydrogen is preferably used for the insulating layer 218. Thus, the insulating layer 218 can function as a barrier layer. Such a structure can effectively inhibit diffusion of impurities into the transistors from the outside and increase the reliability of the display apparatus.

The insulating layer 218 preferably includes one or more inorganic insulating films. Examples of the inorganic insulating film include an oxide insulating film, a nitride insulating film, an oxynitride insulating film, and a nitride oxide insulating film. Specific examples of these inorganic insulating films are as described above.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably has a function of an etching protective layer. In that case, the formation of a depressed portion in the insulating layer 235 can be inhibited in processing a pixel electrode 111R, a pixel electrode 111G, and a pixel electrode 111B, for example. Alternatively, a depressed portion may be formed in the insulating layer 235 in processing the pixel electrode 111R, the pixel electrode 111G, and the pixel electrode 111B, for example.

The light-emitting element 130R, the light-emitting element 130G, and the light-emitting element 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 13 emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 13 emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 13 emits blue light (B). The EL layer 113B includes a light-emitting layer that emits blue light.

Although FIG. 13 illustrates the EL layer 113R, the EL layer 113G, and the EL layer 113B that have the same thickness, the present invention is not limited thereto. The EL layer 113R, the EL layer 113G, and the EL layer 113B may have different thicknesses. For example, the thicknesses of the EL layer 113R, the EL layer 113G, and the EL layer 113B are preferably set to match an optical path length that intensifies light emitted from each EL layer. In that case, a microcavity structure is obtained, and the color purity of light emitted from each light-emitting element can be improved.

The pixel electrode 111R is electrically connected to the conductive layer 112b included in the transistor 205R through an opening provided in the insulating layer 106, the insulating layer 218, and the insulating layer 235. Similarly, the pixel electrode 111G is electrically connected to the conductive layer 112b included in the transistor 205G, and the pixel electrode 111B is electrically connected to the conductive layer 112b included in the transistor 205B.

End portions of the pixel electrode 111R, the pixel electrode 111G, and the pixel electrode 111B are covered with an insulating layer 237. The insulating layer 237 functions as a partition (also referred to as a bank or a spacer). The insulating layer 237 can have a single-layer structure or a stacked-layer structure using one or both of an inorganic insulating material and an organic insulating material. A material that can be used for the insulating layer 218 and a material that can be used for the insulating layer 235 can be used for the insulating layer 237, for example. The insulating layer 237 can electrically isolate the pixel electrode and the common electrode. Furthermore, the insulating layer 237 can electrically isolate light-emitting elements adjacent to each other.

The common electrode 115 is one continuous film shared by the light-emitting element 130R, the light-emitting element 130G, and the light-emitting element 130B. The common electrode 115 shared by the plurality of light-emitting elements is electrically connected to a conductive layer 123 provided in the connection portion 140. A conductive layer formed using the same material through the same process as the pixel electrode 111R, the pixel electrode 111G, and the pixel electrode 111B is preferably used as the conductive layer 123.

In the display apparatus of one embodiment of the present invention, a conductive film that transmits visible light is used for the electrode through which light is extracted, which is either the pixel electrode or the common electrode. A conductive film that reflects visible light is preferably used for the electrode through which light is not extracted.

A conductive film that transmits visible light may be used also for the electrode through which light is not extracted. In that case, this electrode is preferably provided between a reflective layer and the EL layer. In other words, light emitted from the EL layer may be reflected by the reflective layer to be extracted from the display apparatus.

As a material that forms the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element preferably includes an electrode having properties of transmitting and reflecting visible light (a transflective electrode), and the other preferably includes an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layer 113R, the EL layer 113G, and the EL layer 113B are each provided to have an island shape. In FIG. 13, the end portion of the EL layer 113R and the end portion of the EL layer 113G that are adjacent to each other overlap with each other, the end portion of the EL layer 113G and the end portion of the EL layer 113B that are adjacent to each other overlap with each other. Although not illustrated, the end portion of the EL layer 113R and the end portion of the EL layer 113B that are adjacent to each other overlap with each other. When island-shaped EL layers are formed using a fine metal mask, end portions of the EL layers adjacent to each other may overlap with each other as illustrated in FIG. 13; however, the present invention is not limited thereto. That is, it is also possible that the EL layers adjacent to each other do not overlap with each other and are apart from each other. It is also possible that the display apparatus includes both a portion where the EL layers adjacent to each other overlap with each other and a portion where the EL layers adjacent to each other do not overlap with each other and are apart from each other.

Each of the EL layer 113R, the EL layer 113G, and the EL layer 113B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (a host material, an assist material, and the like) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar material and a TADF material.

Either a low molecular compound or a high molecular compound can be used for the light-emitting element, and an inorganic compound may also be included. Each layer included in the light-emitting element can be formed by an evaporation method (including a vacuum evaporation method), a transfer method, a printing method, an inkjet method, a coating method, or the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes into the other when voltage is applied between the pair of electrodes. A tandem structure enables a light-emitting element to emit light at high luminance. Furthermore, a tandem structure allows the amount of current needed for obtaining the same luminance to be reduced as compared to the case of using a single structure; thus, the reliability can be increased. A tandem structure may be referred to as a stack structure.

In the case of using a light-emitting element having a tandem structure in FIG. 13 and the like, the EL layer 113R preferably has a structure including a plurality of light-emitting units that emit red light, the EL layer 113G preferably has a structure including a plurality of light-emitting units that emit green light, and the EL layer 113B preferably has a structure including a plurality of light-emitting units that emit blue light.

A protective layer 131 is provided over the light-emitting element 130R, the light-emitting element 130G, and the light-emitting element 130B. The protective layer 131 and the substrate 152 are bonded to each other with an adhesive layer 142. The substrate 152 is provided with a light-blocking layer 117. A solid sealing structure or a hollow sealing structure can be employed to seal the light-emitting elements, for example. In FIG. 13, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting elements. Alternatively, the space may be filled with a resin different from that of the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is also preferable that the protective layer 131 be provided to extend to the end portion of the display apparatus 50A. Meanwhile, a connection portion 204 has a portion not provided with the protective layer 131 so that the FPC 172 and a conductive layer 167 are electrically connected to each other.

By providing the protective layer 131 over the light-emitting element 130R, the light-emitting element 130G, and the light-emitting element 130B, the reliability of the light-emitting elements can be increased.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit degradation of the light-emitting elements by preventing oxidation of the common electrode 115 and inhibiting entry of impurities (e.g., water and oxygen) into the light-emitting elements, for example; thus, the reliability of the display apparatus can be improved.

For the protective layer 131, an inorganic insulating film such as an oxide insulating film, a nitride insulating film, an oxynitride insulating film, or a nitride oxide insulating film can be used, for example. Specific examples of these inorganic insulating films are as described above. In particular, the protective layer 131 preferably includes a nitride insulating film or a nitride oxide insulating film, and further preferably includes a nitride insulating film.

An inorganic film containing ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 204 is provided in a region of the substrate 151 that does not overlap with the substrate 152. In the connection portion 204, the wiring 165 is electrically connected to the FPC 172 through a conductive layer 166, the conductive layer 167, and a connection layer 242. An example is illustrated in which the wiring 165 has a single-layer structure of a conductive layer obtained by processing the same conductive film as the conductive layer 112a. An example is illustrated in which the conductive layer 166 has a single-layer structure of a conductive layer obtained by processing the same conductive film as the conductive layer 112b. An example is illustrated in which the conductive layer 167 has a single-layer structure of a conductive layer obtained by processing the same conductive film as the pixel electrode 111R, the pixel electrode 111G, and the pixel electrode 111B. On the top surface of the connection portion 204, the conductive layer 167 is exposed. Thus, the connection portion 204 and the FPC 172 can be electrically connected to each other through the connection layer 242.

The display apparatus 50A has a top-emission structure. Light emitted from the light-emitting element is emitted toward the substrate 152 side. For the substrate 152, a material having a high visible-light-transmitting property is preferably used. The pixel electrode 111R, the pixel electrode 111G, and the pixel electrode 111B contain a material that reflects visible light, and the counter electrode (the common electrode 115) contains a material that transmits visible light.

The light-blocking layer 117 is preferably provided on the surface of the substrate 152 on the substrate 151 side. The light-blocking layer 117 can be provided between adjacent light-emitting elements, in the connection portion 140, and in the circuit portion 164, for example.

A coloring layer such as a color filter may be provided on the surface of the substrate 152 on the substrate 151 side or over the protective layer 131. When the color filter is provided to overlap with the light-emitting element, the color purity of light emitted from the pixel can be increased.

Moreover, a variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer side of the substrate 152. For example, a glass layer or a silica layer (SiOₓ layer) is preferably provided as the surface protective layer to inhibit the surface contamination and the generation of a scratch. For the surface protective layer, DLC (diamond-like carbon), aluminum oxide (AlOₓ), a polyester-based material, a polycarbonate-based material, or the like may be used. For the surface protective layer, a material having a high visible light transmittance is preferably used. For the surface protective layer, a material with high hardness is preferably used.

For each of the substrate 151 and the substrate 152, glass, quartz, ceramic, sapphire, a resin, a metal, an alloy, a semiconductor, or the like can be used. For the substrate on the side from which light from the light-emitting element is extracted, a material that transmits the light is used. When a flexible material is used for the substrate 151 and the substrate 152, the display apparatus can have increased flexibility and a flexible display can be obtained. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for at least one of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence). Examples of a film having high optical isotropy include a triacetyl cellulose (TAC, also referred to as cellulose triacetate) film, a cycloolefin polymer (COP) film, a cycloolefin copolymer (COC) film, and an acrylic film.

For the adhesive layer 142, any of a variety of curable adhesives, e.g., a reactive curable adhesive, a thermosetting curable adhesive, an anaerobic adhesive, or a photocurable adhesive such as an ultraviolet curable adhesive, can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

For the connection layer 242, an anisotropic conductive film (ACF), an anisotropic conductive paste (ACP), or the like can be used.

### [Display Apparatus 50B]

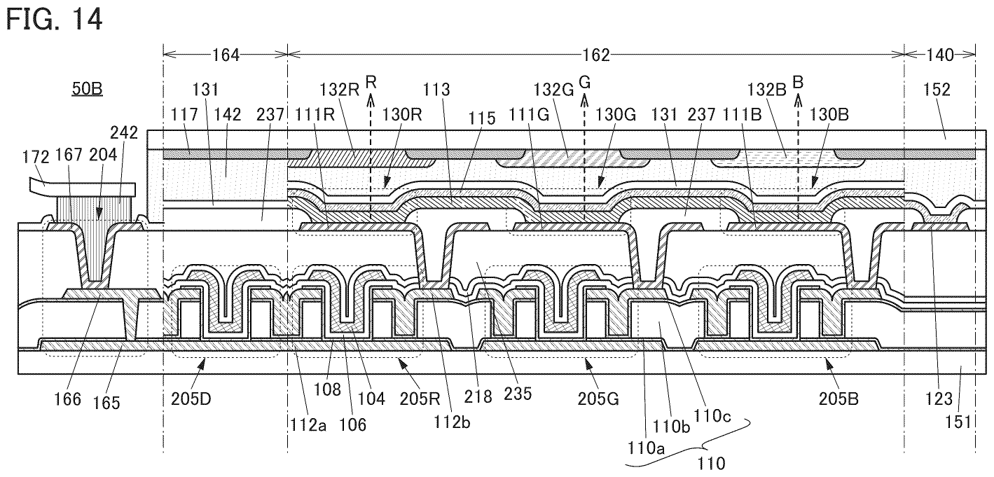

A display apparatus 50B illustrated in FIG. 14 is different from the display apparatus 50A mainly in that the subpixels of different colors include respective coloring layers (color filters or the like) and the light-emitting elements that include a common EL layer 113. Note that in the following description of display apparatuses, the description of portions similar to those of the above-described display apparatus may be omitted.

The display apparatus 50B illustrated in FIG. 14 includes, between the substrate 151 and the substrate 152, the transistor 205D, the transistor 205R, the transistor 205G, the transistor 205B, the light-emitting element 130R, the light-emitting element 130G, the light-emitting element 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display apparatus 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display apparatus 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display apparatus 50B through the coloring layer 132B.

The EL layer 113 and the common electrode 115 are shared between the light-emitting element 130R, the light-emitting element 130G, and the light-emitting element 130B. The number of fabrication steps can be smaller in the case where the EL layer 113 is shared between the subpixels of different colors than in the case where the subpixels of different colors include respective EL layers.

The light-emitting element 130R, the light-emitting element 130G, and the light-emitting element 130B illustrated in FIG. 14 emit white light, for example. When white light emitted from the light-emitting element 130R, white light emitted from the light-emitting element 130G, and white light emitted from the light-emitting element 130B pass through the coloring layer 132R, the coloring layer 132G, and the coloring layer 132B, respectively, light of desired colors can be obtained.

The light-emitting element that emits white light preferably includes two or more light-emitting layers. When two light-emitting layers are used to obtain white light, the two light-emitting layers are selected such that emission colors of the light-emitting layers are complementary colors. For example, when the emission color of the first light-emitting layer and the emission color of the second light-emitting layer are complementary colors, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer containing a light-emitting substance that emits blue light and a light-emitting layer containing a light-emitting substance that emits visible light having a longer wavelength than blue light. The EL layer 113 preferably includes a light-emitting layer that emits yellow light (Y) and a light-emitting layer that emits blue light, for example. Alternatively, the EL layer 113 preferably includes alight-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellowish green, or green light, and a light-emitting unit that emits blue light are stacked in this order; and a three-unit tandem structure in which a light-emitting unit that emits blue light, a light-emitting unit that emits yellow, yellowish green, or green light and red light, and a light-emitting unit that emits blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Alternatively, the light-emitting element 130R, the light-emitting element 130G, and the light-emitting element 130B illustrated in FIG. 14 emit blue light, for example. In that case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or 130G is converted into light with a longer wavelength, whereby red or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted without being converted by the color conversion layer. When light transmitted through the color conversion layer is extracted through the coloring layer, light other than light of the desired color can be absorbed by the coloring layer, and color purity of light exhibited by a subpixel can be improved.

### [Display Apparatus 50C]

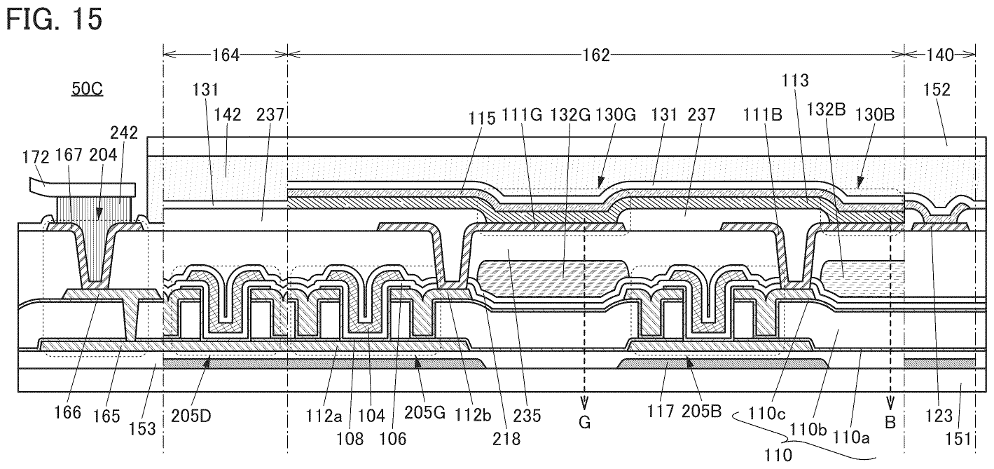

A display apparatus 50C illustrated in FIG. 15 is different from the display apparatus 50B mainly in being a bottom-emission display apparatus.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 15 illustrates an example in which the light-blocking layer 117 is provided over the substrate 151, the insulating layer 153 is provided over the light-blocking layer 117, and the transistor 205D, the transistor 205R (not illustrated), the transistor 205G, the transistor 205B, and the like are provided over the insulating layer 153. In addition, the coloring layer 132R (not illustrated), the coloring layer 132G, and the coloring layer 132B are provided over the insulating layer 218, and the insulating layer 235 is provided over the coloring layer 132R, the coloring layer 132G, and the coloring layer 132B.

The light-emitting element 130R (not illustrated) overlapping with the coloring layer 132R includes the pixel electrode 111R (not illustrated), the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrode 111R, the pixel electrode 111G, and the pixel electrode 111B. A material that reflects visible light is preferably used for the common electrode 115. In the bottom-emission display apparatus, a metal or the like having low resistance can be used for the common electrode 115; thus, a voltage drop due to the resistance of the common electrode 115 can be inhibited and the display quality can be high.

The transistor of one embodiment of the present invention can be miniaturized and the area occupied by the transistor in the substrate surface can be reduced, so that the aperture ratio of the pixel can be increased or the pixel size can be reduced in the display apparatus having a bottom-emission structure.

### [Display Apparatus 50D]

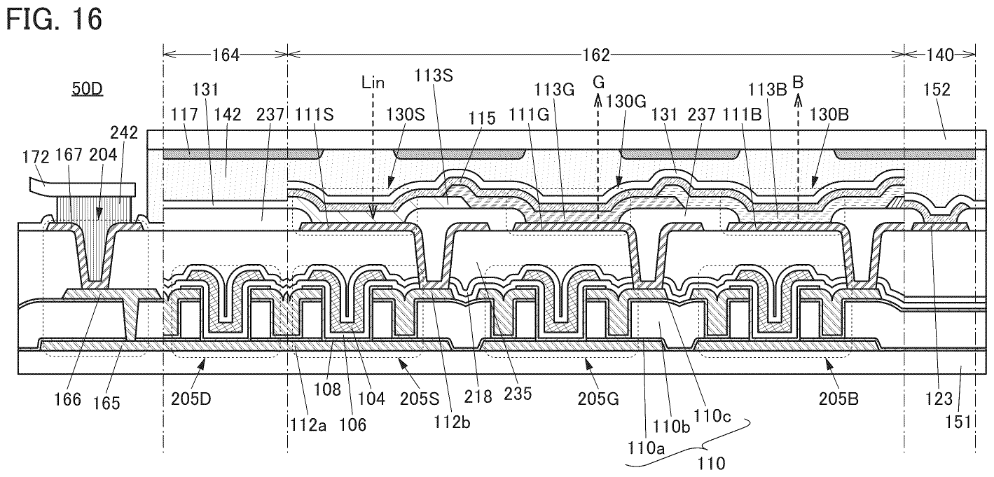

A display apparatus 50D illustrated in FIG. 16 is different from the display apparatus 50A mainly in including a light-receiving element 130S.

The display apparatus 50D includes light-emitting elements and a light-receiving element in a pixel. In the display apparatus 50D, it is preferable to use organic EL elements as the light-emitting elements and an organic photodiode as the light-receiving element. The organic EL elements and the organic photodiode can be formed over the same substrate. Thus, the organic photodiode can be incorporated in a display apparatus using the organic EL elements.

The display apparatus 50D can detect the touch or approach of an object while displaying an image because the pixel includes the light-emitting elements and the light-receiving element and thus has a light-receiving function. Accordingly, the display portion 162 has one or both of an image capturing function and a sensing function in addition to an image displaying function. For example, all the subpixels included in the display apparatus 50D can display an image; alternatively, some of the subpixels can emit light as a light source, some of the rest of the subpixels can detect light, and the other subpixels can display an image.

Accordingly, a light-receiving portion and a light source do not need to be provided separately from the display apparatus 50D; hence, the number of components of an electronic device can be reduced. For example, a biometric authentication device provided in the electronic device, a capacitive touch panel for scroll operation, or the like is not necessarily provided separately. Thus, with the use of the display apparatus 50D, the electronic device can be provided at lower manufacturing costs.

When the light-receiving element is used as an image sensor, the display apparatus 50D can capture an image using the light-receiving element. For example, image capturing for personal authentication with the use of a fingerprint, a palm print, the iris, the shape of a blood vessel (including the shape of a vein and the shape of an artery), a face, or the like is possible by using the image sensor.

Moreover, the light-receiving element can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display apparatus and the object come in direct contact with each other. Furthermore, the contactless sensor can detect the object even when the object is not in contact with the display apparatus.

The light-receiving element 130S includes a pixel electrode 111S over the insulating layer 235, a functional layer 113S over the pixel electrode 111S, and the common electrode 115 over the functional layer 113S. Light Lin enters the functional layer 113S from the outside of the display apparatus 50D.

The pixel electrode 111S is electrically connected to the conductive layer 112b included in a transistor 205S through an opening provided in the insulating layer 106, the insulating layer 218, and the insulating layer 235.

The end portion of the pixel electrode 111S is covered with the insulating layer 237.

The common electrode 115 is one continuous film shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example in which an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer containing any of a substance having a high hole-transport property, a substance having a high electron-transport property, a substance having a bipolar property (a substance having a high electron-transport property and a high hole-transport property), and the like. Without limitation to the above, a layer containing a substance having a high hole-injection property, a hole-blocking material, a substance having a high electron-injection property, an electron-blocking material, or the like may be further included. Layers other than the active layer included in the light-receiving element can be formed using a material that can be used for the light-emitting element, for example.

Either a low molecular compound or a high molecular compound can be used for the light-receiving element, and an inorganic compound may also be included. Each layer included in the light-receiving element can be formed by a method such as an evaporation method (including a vacuum evaporation method), a transfer method, a printing method, an inkjet method, or a coating method.

### [Display Apparatus 50E]

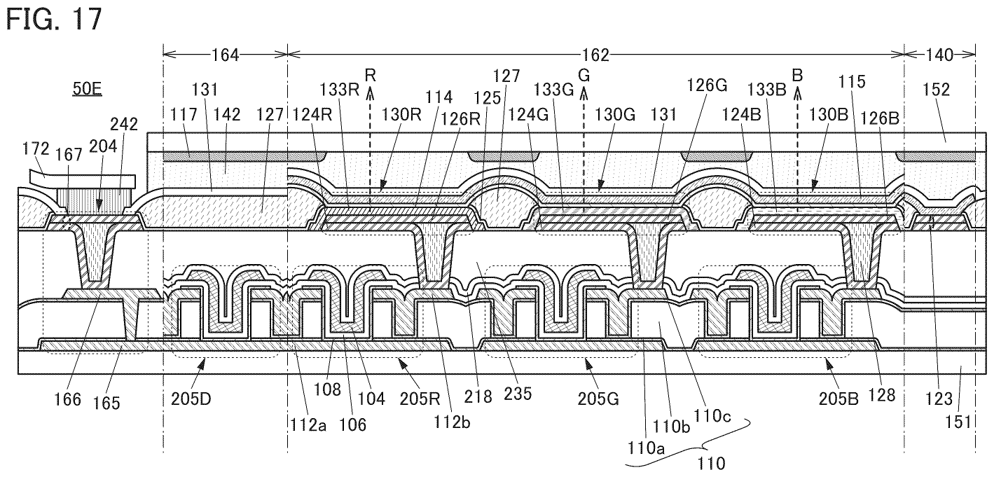

A display apparatus 50E illustrated in FIG. 17 is an example of a display apparatus having the MML structure. In other words, the display apparatus 50E includes a light-emitting element that is formed without using a fine metal mask. The stacked-layer structure from the substrate 151 to the insulating layer 235 and the stacked-layer structure from the protective layer 131 to the substrate 152 are similar to those in the display apparatus 50A; therefore, description thereof is omitted.

In FIG. 17, the light-emitting element 130R, the light-emitting element 130G, and the light-emitting element 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 17 emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 17 emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 17 emits blue light (B). The layer 133B includes alight-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. Note that in this specification and the like, the layer 133R, the layer 133G, and the layer 133B are sometimes referred to as island-shaped EL layers, EL layers formed in an island shape, or the like, in which case the common layer 114 is not included.

The layer 133R, the layer 133G, and the layer 133B are separated from one another. When the EL layer is provided to have an island shape for each light-emitting element, leakage current between adjacent light-emitting elements can be inhibited. This can prevent crosstalk due to unintended light emission, so that a display apparatus with extremely high contrast can be obtained.

Although FIG. 17 illustrates the layer 133R, the layer 133G, and the layer 133B that have the same thickness, the present invention is not limited thereto. The layer 133R, the layer 133G, and the layer 133B may have different thicknesses.

The conductive layer 124R is electrically connected to the conductive layer 112b included in the transistor 205R through an opening provided in the insulating layer 106, the insulating layer 218, and the insulating layer 235. Similarly, the conductive layer 124G is electrically connected to the conductive layer 112b included in the transistor 205G, and the conductive layer 124B is electrically connected to the conductive layer 112b included in the transistor 205B.

The conductive layer 124R, the conductive layer 124G, and the conductive layer 124B are formed to cover the openings provided in the insulating layer 235. A layer 128 is embedded in each of the depressed portions of the conductive layer 124R, the conductive layer 124G, and the conductive layer 124B.

The layer 128 has a planarization function for the depressed portions of the conductive layer 124R, the conductive layer 124G, and the conductive layer 124B. The conductive layer 126R, the conductive layer 126G, and the conductive layer 126B electrically connected to the conductive layer 124R, the conductive layer 124G, and the conductive layer 124B, respectively, are provided over the conductive layer 124R, the conductive layer 124G, the conductive layer 124B, and the layer 128. Thus, regions overlapping with the depressed portions of the conductive layer 124R, the conductive layer 124G, and the conductive layer 124B can also be used as the light-emitting regions, increasing the aperture ratio of the pixels. A conductive layer functioning as a reflective electrode is preferably used as each of the conductive layer 124R, the conductive layer 126R, the conductive layer 124G, the conductive layer 126G, the conductive layer 124B, and the conductive layer 126B.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 17 illustrates an example in which the top surface of the layer 128 includes a flat portion, the shape of the layer 128 is not particularly limited. The top surface of the layer 128 can include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

The end portion of the conductive layer 126R may be aligned with the end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be improved.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, the top surface and the side surface of the conductive layer 126G are covered with the layer 133G, and the top surface and the side surface of the conductive layer 126B are covered with the layer 133B. Accordingly, regions provided with the conductive layer 126R, the conductive layer 126G, and the conductive layer 126B can be entirely used as the light-emitting regions of the light-emitting element 130R, the light-emitting element 130G, and the light-emitting element 130B, thereby increasing the aperture ratio of the pixels.

The side surface and part of the top surface of each of the layer 133R, the layer 133G, and the layer 133B are covered with an insulating layer 125 and an insulating layer 127. The common layer 114 is provided over the layer 133R, the layer 133G, the layer 133B, and the insulating layer 125 and the insulating layer 127, and the common electrode 115 is provided over the common layer 114. The common layer 114 and the common electrode 115 are each one continuous film shared by the plurality of light-emitting elements.

In FIG. 17, the insulating layer 237 illustrated in FIG. 13 and the like is not provided between the conductive layer 126R and the layer 133R. That is, the display apparatus 50E is not provided with an insulating layer (also referred to as a partition wall, a bank, a spacer, or the like) that is in contact with the pixel electrode and covers an upper end portion of the pixel electrode. Thus, the distance between adjacent light-emitting elements can be significantly shortened. Accordingly, the display apparatus can have a high resolution or a high definition. In addition, a mask for forming the insulating layer is not needed, which leads to a reduction in manufacturing cost of the display apparatus.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include the light-emitting layer and a carrier-blocking layer (a hole-blocking layer or an electron-blocking layer) over the light-emitting layer. Alternatively, the layer 133R, the layer 133G, and the layer 133B each preferably include the light-emitting layer, a carrier-blocking layer over the light-emitting layer, and a carrier-transport layer over the carrier-blocking layer. Since the surfaces of the layer 133R, the layer 133G, and the layer 133B are exposed in the fabrication process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting elements can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting element 130R, the light-emitting element 130G, and the light-emitting element 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and parts of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes, the layer 133R, the layer 133G, and the layer 133B, leading to inhibition of a short circuit of the light-emitting elements. Thus, the reliability of the light-emitting elements can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting elements can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers; hence, extreme unevenness of the formation surface of the layers (e.g., the carrier-injection layer and the common electrode) provided over the island-shaped layers can be reduced, and the formation surface can be made flatter. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display apparatus of one embodiment of the present invention, the step can be eliminated with the insulating layer 125 and the insulating layer 127, and the coverage with the common layer 114 and the common electrode 115 can be improved. Thus, connection defects caused due to step disconnection of the common layer 114 and the common electrode 115 can be inhibited. In addition, an increase in electric resistance, which is caused by local thinning of the common electrode 115 due to the step, can be inhibited.

The top surface of the insulating layer 127 preferably has a shape with high flatness. The top surface of the insulating layer 127 may include at least one of a flat surface, a convex surface, and a concave surface. For example, the top surface of the insulating layer 127 preferably has a smooth convex shape with high flatness.

The insulating layer 125 can be an insulating layer including an inorganic material. As the insulating layer 125, an inorganic insulating film such as an oxide insulating film, a nitride insulating film, an oxynitride insulating film, or a nitride oxide insulating film can be used, for example. Specific examples of these inorganic insulating films are as described above. The insulating layer 125 may have a single-layer structure or a stacked-layer structure. Aluminum oxide is particularly preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a targeted substance (also referred to as having low permeability). Alternatively, a barrier property refers to a function of capturing or fixing (also referred to as gettering) a targeted substance.

When the insulating layer 125 has a function of a barrier insulating layer or a gettering function, entry of impurities (typically, at least one of water and oxygen) that would diffuse into the light-emitting elements from the outside can be inhibited. With this structure, a highly reliable light-emitting element and a highly reliable display apparatus can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, preferably has both of them.

The insulating layer 127 provided over the insulating layer 125 has a planarization function for the extreme unevenness of the insulating layer 125, which is formed between adjacent light-emitting elements. In other words, the insulating layer 127 has an effect of improving the flatness of the formation surface of the common electrode 115.

As the insulating layer 127, an insulating layer containing an organic material can be suitably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. For the insulating layer 127, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. A photoresist may be used as the photosensitive organic resin. As the photosensitive organic resin, either a positive-type material or a negative-type material may be used.

For the insulating layer 127, a material absorbing visible light may be used. When the insulating layer 127 absorbs light emitted from the light-emitting element, light leakage (stray light) from the light-emitting element to the adjacent light-emitting element through the insulating layer 127 can be inhibited. Thus, the display quality of the display apparatus can be improved. Since no polarizing plate is required to improve the display quality of the display apparatus, the weight and thickness of the display apparatus can be reduced.

Examples of the material absorbing visible light include a material containing a pigment of black or the like, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

### [Display Apparatus 50F]

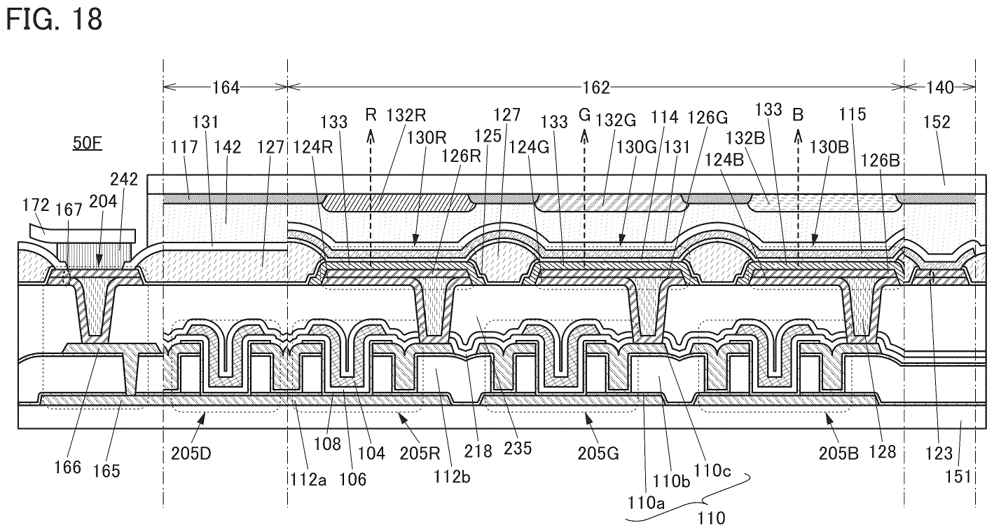

A display apparatus 50F illustrated in FIG. 18 is different from the display apparatus 50E mainly in that the subpixels of different colors include respective coloring layers (color filters or the like) and respective layers 133 in the light-emitting elements.

The display apparatus 50F illustrated in FIG. 18 includes, between the substrate 151 and the substrate 152, the transistor 205D, the transistor 205R, the transistor 205G, the transistor 205B, the light-emitting element 130R, the light-emitting element 130G, the light-emitting element 130B, the coloring layer 132R transmitting red light, the coloring layer 132G transmitting green light, the coloring layer 132B transmitting blue light, and the like.

Light emitted from the light-emitting element 130R is extracted as red light to the outside of the display apparatus 50F through the coloring layer 132R. Similarly, light emitted from the light-emitting element 130G is extracted as green light to the outside of the display apparatus 50F through the coloring layer 132G. Light emitted from the light-emitting element 130B is extracted as blue light to the outside of the display apparatus 50F through the coloring layer 132B.

The light-emitting element 130R, the light-emitting element 130G, and the light-emitting element 130B each include the layer 133. The three layers 133 are formed using the same process and the same material. The three layers 133 are isolated from one another. When the EL layer is provided to have an island shape for each light-emitting element, leakage current between adjacent light-emitting elements can be inhibited. This can prevent crosstalk due to unintended light emission, so that a display apparatus with extremely high contrast can be obtained.

The light-emitting element 130R, the light-emitting element 130G, and the light-emitting element 130B illustrated in FIG. 18 emit white light, for example. When white light emitted from the light-emitting element 130R, white light emitted from the light-emitting element 130G, and white light emitted from the light-emitting element 130B pass through the coloring layer 132R, the coloring layer 132G, and the coloring layer 132B, respectively, light of desired colors can be obtained.

Alternatively, the light-emitting element 130R, the light-emitting element 130G, and the light-emitting element 130B illustrated in FIG. 18 emit blue light, for example. In that case, the layer 133 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the desired color can be absorbed by the coloring layer, and color purity of light exhibited by a subpixel can be improved.

### [Display Apparatus 50G]

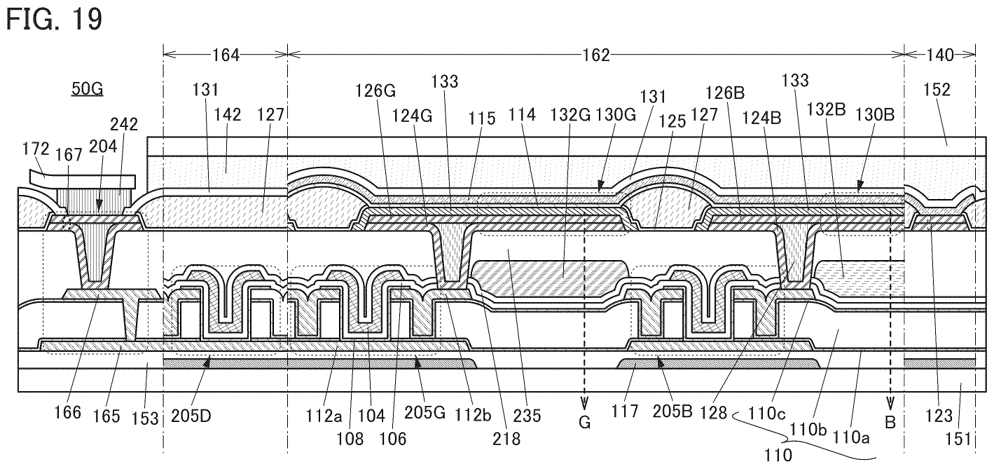

A display apparatus 50G illustrated in FIG. 19 is different from the display apparatus 50F mainly in being a bottom-emission display apparatus.

Light emitted from the light-emitting element is emitted toward the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 19 illustrates an example in which the light-blocking layer 117 is provided over the substrate 151, the insulating layer 153 is provided over the light-blocking layer 117, and the transistor 205D, the transistor 205R (not illustrated), the transistor 205G, the transistor 205B, and the like are provided over the insulating layer 153. In addition, the coloring layer 132R (not illustrated), the coloring layer 132G, and the coloring layer 132B are provided over the insulating layer 218, and the insulating layer 235 is provided over the coloring layer 132R, the coloring layer 132G, and the coloring layer 132B.

The light-emitting element 130R (not illustrated) overlapping with the coloring layer 132R includes the conductive layer 124R (not illustrated), the conductive layer 126R (not illustrated), the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a high visible-light-transmitting property is used for each of the conductive layer 124R, the conductive layer 124G, the conductive layer 124B, the conductive layer 126R, the conductive layer 126G, and the conductive layer 126B. A material that reflects visible light is preferably used for the common electrode 115. In the bottom-emission display apparatus, a metal or the like having low resistance can be used for the common electrode 115; thus, a voltage drop due to the resistance of the common electrode 115 can be inhibited and the display quality can be high.

The transistor of one embodiment of the present invention can be miniaturized and the area occupied by the transistor in the substrate surface can be reduced, so that the aperture ratio of the pixel can be increased or the pixel size can be reduced in the display apparatus having a bottom-emission structure.

### [Example of Method for Fabricating Display Apparatus]

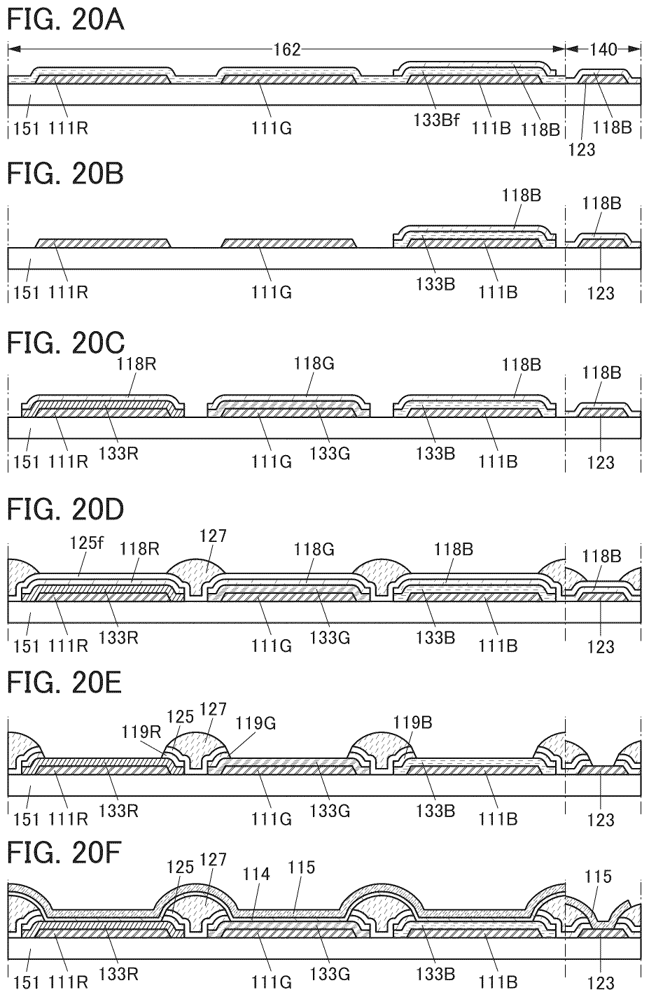

A method for fabricating a display apparatus having the MML structure will be described below with reference to FIG. 20A to FIG. 20F. Here, steps of fabricating light-emitting elements without using a fine metal mask will be described in detail. FIG. 20A to FIG. 20F show cross-sectional views of three light-emitting elements included in the display portion 162 and the connection portion 140 in the steps.

For fabrication of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

In the method described below for fabricating the display apparatus, the island-shaped layer (the layer including the light-emitting layer) is formed not by using a fine metal mask but by forming a light-emitting layer on the entire surface and processing the light-emitting layer by a photolithography method. Accordingly, a high-resolution display apparatus or a display apparatus with a high aperture ratio, which has been difficult to achieve so far, can be obtained. Moreover, light-emitting layers can be formed separately for the respective colors, enabling the display apparatus to perform extremely clear display with high contrast and high display quality. Furthermore, providing a sacrificial layer over the light-emitting layer can reduce damage to the light-emitting layer in the fabrication process of the display apparatus, resulting in an increase in the reliability of the light-emitting element.

For example, in the case where the display apparatus includes three kinds of a light-emitting element that emits blue light, a light-emitting element that emits green light, and a light-emitting element that emits red light, three kinds of island-shaped light-emitting layers can be formed by forming a light-emitting layer and performing processing three times by photolithography.

First, the pixel electrode 111R, the pixel electrode 111G, the pixel electrode 111B, and the conductive layer 123 are formed over the substrate 151 provided with the transistor 205R, the transistor 205G, the transistor 205B, and the like (each of which is not illustrated) (FIG. 20(A)).

A conductive film to be the pixel electrodes can be formed by a sputtering method or a vacuum evaporation method, for example. A resist mask is formed over the conductive film by a photolithography process, and then the conductive film is processed, whereby the pixel electrode 111R, the pixel electrode 111G, the pixel electrode 111B, and the conductive layer 123 can be formed. The conductive film can be processed by one or both of a wet etching method and a dry etching method.

Next, a film 133Bf to be the layer 133B later is formed over the pixel electrode 111R, the pixel electrode 111G, and the pixel electrode 111B (FIG. 20(A)). The film 133Bf (to be the layer 133B later) includes a light-emitting layer that emits blue light.

This embodiment describes an example in which an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding step. In that case, the driving voltage of the light-emitting element of the color formed second or later might be high.

In view of this, in fabrication of the display apparatus of one embodiment of the present invention, it is preferable that an island-shaped EL layer of a light-emitting element that emits light with the shortest wavelength (e.g., the blue-light-emitting element) be formed first. For example, it is preferable that the island-shaped EL layers be formed in the order of blue, green, and red or in the order of blue, red, and green.

This enables the blue-light-emitting element to keep a good state of the interface between the pixel electrode and the EL layer and to be inhibited from having an increased driving voltage. In addition, the blue-light-emitting element can have a longer lifetime and higher reliability. Note that the red-light-emitting element and the green-light-emitting element have a smaller influence of an increase in driving voltage or the like than the blue-light-emitting element. Accordingly, adopting the above formation order results in a lower driving voltage and higher reliability of the whole display apparatus.

Note that the formation order of the island-shaped EL layers is not limited to the above; for example, the island-shaped EL layers may be formed in the order of red, green, and blue.

As illustrated in FIG. 20A, the film 133Bf is not formed over the conductive layer 123. The film 133Bf can be formed only in a desired region using an area mask, for example. Employing a film formation step using an area mask and a processing step using a resist mask enables a light-emitting element to be fabricated by a relatively easy process.

The upper temperature limit of a compound contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the fabrication process of the display apparatus can be increased. Therefore, the range of choices of the materials and the fabrication method of the display apparatus can be widened, thereby improving the yield and the reliability.

Examples of the upper temperature limit include the glass transition point, the softening point, the melting point, the thermal decomposition temperature, and the 5% weight loss temperature, and the lowest temperature among them is preferable.

The film 133Bf can be formed by an evaporation method, specifically a vacuum evaporation method, for example. The film 133Bf may be formed by a method such as a transfer method, a printing method, an inkjet method, or a coating method.

Next, a sacrificial layer 118B is formed over the film 133Bf and the conductive layer 123 (FIG. 20A). A resist mask is formed over a film to be the sacrificial layer 118B by a photolithography process, and then the film is processed, whereby the sacrificial layer 118B can be formed.

Providing the sacrificial layer 118B over the film 133Bf can reduce damage to the film 133Bf in the fabrication process of the display apparatus, resulting in an increase in the reliability of the light-emitting element.

The sacrificial layer 118B is preferably provided to cover the end portions of the pixel electrode 111R, the pixel electrode 111G, and the pixel electrode 111B. Accordingly, the end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B might be damaged in a step after the formation of the layer 133B, and thus is preferably positioned outward from the end portion of the pixel electrode 111B. That is, the end portion of the layer 133B is preferably not used as the light-emitting region. This can inhibit a variation in the characteristics of the light-emitting elements and can improve the reliability.

When the layer 133B covers the top surface and the side surface of the pixel electrode 111B, the steps after the formation of the layer 133B can be performed in a state where the pixel electrode 111B is not exposed. When the end portion of the pixel electrode 111B is exposed, corrosion might occur in the etching step or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the fabrication process of the display apparatus.

As the sacrificial layer 118B, a film that is highly resistant to the process conditions for the film 133Bf, specifically a film having high etching selectivity with respect to the film 133Bf, is used.

The sacrificial layer 118B is formed at a temperature lower than the upper temperature limit of each compound contained in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The upper temperature limit of the compound contained in the film 133Bf is preferably high, in which case the film formation temperature of the sacrificial layer 118B can be high. For example, the substrate temperature in the formation of the sacrificial layer 118B can be higher than or equal to 100° C., higher than or equal to 120° C., or higher than or equal to 140° C. An inorganic insulating film formed at a higher film formation temperature can be denser and have a higher barrier property. Therefore, forming the sacrificial layer at such a temperature can further reduce damage to the film 133Bf and improve the reliability of the light-emitting element.

Note that the same applies to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the above-described wet film formation method may be used for the formation.

The sacrificial layer 118B (or a layer provided in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

In the case of employing a wet etching method, damage to the film 133Bf in processing of the sacrificial layer 118B can be reduced as compared to the case of employing a dry etching method. In the case of employing a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of employing a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

For the sacrificial layer 118B, a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon can be used.

In place of gallium described above, the element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with excellent compatibility with the semiconductor manufacturing process. Alternatively, an oxide or a nitride of the semiconductor material can be used. Alternatively, a non-metallic material such as carbon or a compound thereof can be used. Alternatively, a metal such as titanium, tantalum, tungsten, chromium, or aluminum, or an alloy containing one or more of these metals can be used. Alternatively, an oxide containing the above-described metal, such as titanium oxide or chromium oxide, or a nitride such as titanium nitride, chromium nitride, or tantalum nitride can be used.

As the sacrificial layer 118B, any of a variety of inorganic insulating films that can be used as the protective layer 131 can be used. In particular, an oxide insulating film is preferable because its adhesion to the film 133Bf is higher than that of a nitride insulating film. For example, an inorganic insulating material such as aluminum oxide, hafnium oxide, or silicon oxide can be used for the sacrificial layer 118B. As the sacrificial layer 118B, an aluminum oxide film can be formed by an ALD method, for example. An ALD method is preferably used, in which case damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used as both the sacrificial layer 118B and the insulating layer 125 that is to be formed later. For example, an aluminum oxide film formed by an ALD method can be used as both the sacrificial layer 118B and the insulating layer 125. Here, for the sacrificial layer 118B and the insulating layer 125, the same film formation condition may be used or different film formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, the sacrificial layer 118B is a layer a large part or the whole of which is to be removed in a later step, and thus is preferably easy to process. Therefore, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

For the sacrificial layer 118B, an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer may be used.

For example, a stacked-layer structure of an organic film (e.g., a PVA film) formed by an evaporation method or the above wet film formation method and an inorganic film (e.g., a silicon nitride film) formed by a sputtering method can be employed for the sacrificial layer 118B.

Note that in the display apparatus of one embodiment of the present invention, part of the sacrificial film remains as the sacrificial layer in some cases.

Then, the film 133Bf is processed using the sacrificial layer 118B as a hard mask, so that the layer 133B is formed (FIG. 20B).

Accordingly, as illustrated in FIG. 20B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. In particular, an anisotropic dry etching method is preferably employed. Alternatively, a wet etching method may be employed.

After that, steps similar to the formation step of the film 133Bf, the formation step of the sacrificial layer 118B, and the formation step of the layer 133B are repeated twice under the condition where at least light-emitting materials are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 20C). Specifically, the layer 133R is formed to include a light-emitting layer that emits red light and the layer 133G is formed to include a light-emitting layer that emits green light. A material that can be used for the sacrificial layer 118B can be used for the sacrificial layer 118R and the sacrificial layer 118G. The sacrificial layer 118R and the sacrificial layer 118G may be formed using the same material or different materials.

Note that it is preferable that the side surfaces of the layer 133B, the layer 133G, and the layer 133R be perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 m, less than or equal to 5 m, less than or equal to 3 m, less than or equal to 2 m, or less than or equal to 1 m. Here, the distance can be determined by, for example, the distance between facing end portions of two adjacent layers among the layer 133B, the layer 133G, and the layer 133R. When the distance between the island-shaped EL layers is shortened in this manner, a display apparatus with a high resolution and a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 20D).

As the insulating film 125f, an insulating film is preferably formed to have a thickness larger than or equal to 3 nm, larger than or equal to 5 nm, or larger than or equal to 10 nm and smaller than or equal to 200 nm, smaller than or equal to 150 nm, smaller than or equal to 100 nm, or smaller than or equal to 50 nm.

The insulating film 125f is preferably formed by an ALD method, for example. An ALD method is preferably used, in which case damage to the EL layer during film formation can be reduced and a film with good coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation speed than an ALD method. In that case, a highly reliable display apparatus can be fabricated with high productivity.

For example, an insulating film to be the insulating layer 127 is preferably formed by the above-described wet film formation method (e.g., spin coating) using a photosensitive resin composite containing an acrylic resin. After the film formation, heat treatment (also referred to as pre-baking) is preferably performed to eliminate a solvent contained in the insulating film. Next, part of the insulating film is exposed to light by irradiation with visible light or ultraviolet rays. Next, the region of the insulating film exposed to light is removed by development. Then, heat treatment (also referred to as post-baking) is performed. Accordingly, the insulating layer 127 illustrated in FIG. 20D can be formed. Note that the shape of the insulating layer 127 is not limited to the shape illustrated in FIG. 20D. For example, the top surface of the insulating layer 127 can include one or more of a convex surface, a concave surface, and a flat surface. The insulating layer 127 may cover the side surface of the end portion of at least one of the sacrificial layer 118B, the sacrificial layer 118G, and the sacrificial layer 118R.

Next, as illustrated in FIG. 20E, etching treatment is performed using the insulating layer 127 as a mask to remove parts of the insulating film 125f, the sacrificial layer 118B, the sacrificial layer 118G, and the sacrificial layer 118R. Consequently, the openings are formed in the insulating film 125f, the sacrificial layer 118B, the sacrificial layer 118G, and the sacrificial layer 118R; thus, the insulating layer 125 is formed and the top surfaces of the layer 133B, the layer 133G, the layer 133R, and the conductive layer 123 are exposed. Note that parts of the sacrificial layer 118B, the sacrificial layer 118G, and the sacrificial layer 118R may remain in positions overlapping with the insulating layer 127 and the insulating layer 125 (a sacrificial layer 119B, a sacrificial layer 119G, and a sacrificial layer 119R).

A dry etching method or a wet etching method can be used for the etching treatment. Note that the insulating film 125f is preferably formed using a material similar to those for the sacrificial layer 118B, the sacrificial layer 118G, and the sacrificial layer 118R, in which case etching treatment can be performed collectively.

As described above, by providing the insulating layer 127, the insulating layer 125, the sacrificial layer 118B, the sacrificial layer 118G, and the sacrificial layer 118R, a connection defect due to a disconnection portion and an increase in electric resistance due to a locally thinned portion can be inhibited from occurring in the common electrode 115 between the light-emitting elements. Thus, the display apparatus of one embodiment of the present invention can have improved display quality.

Next, the common layer 114 and the common electrode 115 are formed in this order over the insulating layer 127, the layer 133B, the layer 133G, and the layer 133R (FIG. 20F).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

As described above, in the method for fabricating the display apparatus of one embodiment of the present invention, the island-shaped layer 133B, the island-shaped layer 133G, and the island-shaped layer 133R are formed not by using a fine metal mask but by forming a film on the entire surface and processing the film; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the layer 133B, the layer 133G, and the layer 133R can be inhibited from being in contact with each other in the adjacent subpixels. As a result, generation of leakage current between the subpixels can be inhibited. This can prevent crosstalk due to unintended light emission, so that a display apparatus with extremely high contrast can be obtained.

Providing the insulating layer 127 having a tapered end portion between adjacent island-shaped EL layers can inhibit step disconnection and prevent a locally thinned portion to be formed in the common electrode 115 at the time of forming the common electrode 115. Thus, a connection defect due to a disconnection portion and an increase in electric resistance due to a locally thinned portion can be inhibited from occurring in the common layer 114 and the common electrode 115. Hence, the display apparatus of one embodiment of the present invention achieves both a high resolution and a high display quality.

This embodiment can be combined with the other embodiments as appropriate.

### Embodiment 3

In this embodiment, a circuit that can be employed in the display apparatus including the transistor of one embodiment of the present invention will be described.

### <Structure Example of Pixel Circuit>

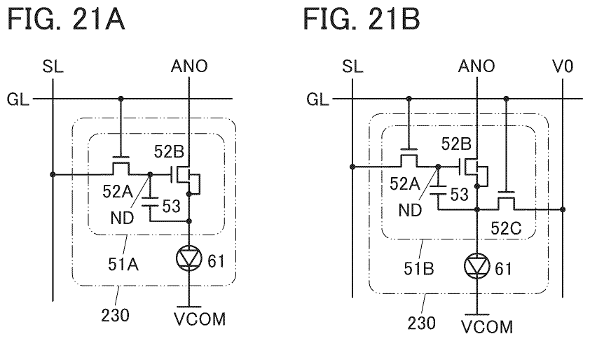

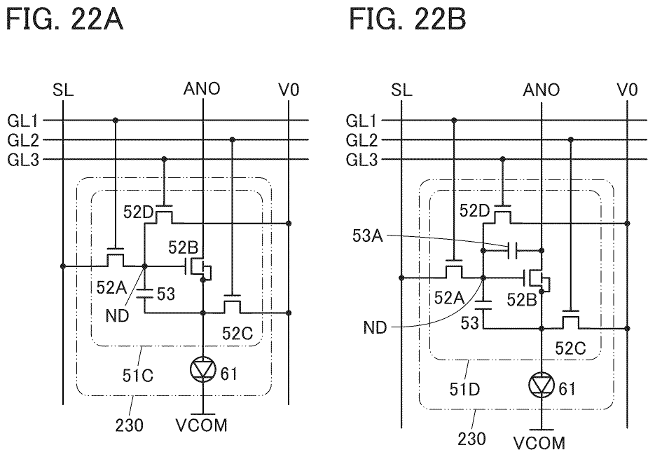

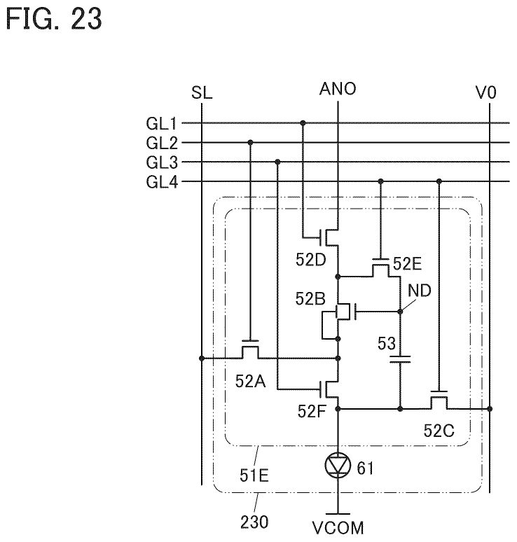

FIG. 21A, FIG. 21B, FIG. 22A, FIG. 22B, and FIG. 23 illustrate structure examples of a pixel 230. For example, the pixel 230 corresponds to the pixel 210 illustrated in FIG. 12 in the above embodiment. The pixel 230 includes a pixel circuit 51 (a pixel circuit 51A, a pixel circuit 51B, a pixel circuit 51C, a pixel circuit 51D, or a pixel circuit 51E), and a light-emitting element 61.

The light-emitting element described in this embodiment and the like refers to a self-luminous display element such as an organic EL element (OLED). Note that the light-emitting element electrically connected to the pixel circuit can be a self-luminous light-emitting element such as an LED, a micro LED, a QLED, or a semiconductor laser.

The pixel circuit 51A illustrated in FIG. 21A is a 2Tr1C-type pixel circuit including a transistor 52A, a transistor 52B, and a capacitor 53.

One of a source and a drain of the transistor 52A is electrically connected to a wiring SL, and a gate of the transistor 52A is electrically connected to a wiring GL. The other of the source and the drain of the transistor 52A is electrically connected to a gate of the transistor 52B and one terminal of the capacitor 53. One of a source and a drain of the transistor 52B is electrically connected to a wiring ANO. The other of the source and the drain of the transistor 52B is electrically connected to the other terminal of the capacitor 53 and an anode of the light-emitting element 61. A cathode of the light-emitting element 61 is electrically connected to a wiring VCOM. A region where the other of the source and the drain of the transistor 52A, the gate of the transistor 52B, and the one terminal of the capacitor 53 are electrically connected to one another functions as a node ND.

The wiring GL is a wiring for supplying a potential for putting the transistor 52A included in the pixel 230 that performs display in an on state. The wiring SL is a wiring for supplying a potential for supplying an image signal to the transistor 52A. The wiring VCOM is a wiring for supplying a potential for supplying current to the light-emitting element 61. The transistor 52A has a function of controlling electrical continuity between the wiring SL and the gate of the transistor 52B in accordance with the potential of the wiring GL. For example, VDD is supplied to the wiring ANO, and VSS is supplied to the wiring VCOM.

When the transistor 52A is put in an on state, an image signal is supplied from the wiring SL to the node ND. After that, when the transistor 52A is put in an off state, the image signal is held in the node ND. In order to surely hold the image signal supplied to the node ND, a transistor with a low off-state current is preferably used as the transistor 52A. For example, an OS transistor is preferably used as the transistor 52A.

The transistor 52B has a function of controlling the amount of current flowing through the light-emitting element 61. The capacitor 53 has a function of holding a gate potential of the transistor 52B. The intensity of light emitted from the light-emitting element 61 is controlled in accordance with an image signal supplied to the gate of the transistor 52B (the node ND).

In the pixel circuit 51A illustrated in FIG. 21A, the transistor 52B includes a second gate (also referred to as a back gate). The second gate of the transistor 52B is electrically connected to the other of the source and the drain of the transistor 52B.

The transistor 100 or the like described in the above embodiment can be used as the transistor 52B, for example. Using the transistor 100 or the like as the transistor 52B can increase the number of gray levels expressed by the display portion included in the display apparatus. Furthermore, the emission luminance of the display apparatus can be stable. Thus, the reliability of the display apparatus can be increased. In addition, the display quality of the display apparatus can be increased.

The pixel circuit 51B illustrated in FIG. 21B is a 3Tr1C-type pixel circuit including the transistor 52A, the transistor 52B, a transistor 52C, and the capacitor 53. The pixel circuit 51B illustrated in FIG. 21B has a structure in which the transistor 52C is added to the pixel circuit 51A illustrated in FIG. 21A.

One of a source and a drain of the transistor 52C is electrically connected to the other of the source and the drain of the transistor 52B. The other of the source and the drain of the transistor 52C is electrically connected to a wiring V0. A reference potential is supplied to the wiring V0, for example.

The transistor 52C has a function of controlling electrical continuity between the wiring V0 and the other of the source and the drain of the transistor 52B in accordance with the potential of the wiring GL. The wiring V0 is a wiring for supplying a reference potential. In the case where an n-channel transistor is used as the transistor 52B, a variation in the gate-source voltage of the transistor 52B can be reduced by the reference potential of the wiring V0 supplied through the transistor 52C.

A current value that can be used for setting of pixel parameters can be obtained using the wiring V0. Specifically, the wiring V0 can function as a monitor line for outputting current flowing through the transistor 52B or current flowing through the light-emitting element 61 to the outside. Current output to the wiring V0 can be converted into voltage by a source follower circuit or the like and can be output to the outside. For another example, the current can be converted into a digital signal by an A-D converter or the like and can be output to the outside.

In the pixel circuit 51B illustrated in FIG. 21B, the transistor 52B includes a second gate. The second gate of the transistor 52B is electrically connected to the other of the source and the drain of the transistor 52B.

The transistor 100 or the like described in the above embodiment can be used as the transistor 52B, for example.

The pixel circuit 51C illustrated in FIG. 22A has a structure in which a transistor 52D is added to the pixel circuit 51B illustrated in FIG. 21B. The pixel circuit 51C illustrated in FIG. 22A is a 4Tr1C-type pixel circuit including the transistor 52A, the transistor 52B, the transistor 52C, the transistor 52D, and the capacitor 53.

One of a source and a drain of the transistor 52D is electrically connected to the node ND, and the other of the source and the drain is electrically connected to the wiring V0.

A wiring GL1, a wiring GL2, and a wiring GL3 are electrically connected to the pixel circuit 51C. The wiring GL1 is electrically connected to the gate of the transistor 52A, the wiring GL2 is electrically connected to the gate of the transistor 52C, and the wiring GL3 is electrically connected to a gate of the transistor 52D. Note that in this embodiment and the like, the wiring GL1, the wiring GL2, and the wiring GL3 are sometimes collectively referred to as the wiring GL. Thus, the wiring GL may be one wiring or a plurality of wirings.

When the transistor 52C and the transistor 52D are turned on at the same time, the source and the gate of the transistor 52B have the same potential, so that the transistor 52B can be turned off. Thus, current flowing to the light-emitting element 61 can be blocked forcibly. Such a pixel circuit is suitable for the case of using a display method in which a display period and an off period are alternately provided.

The pixel circuit 51D illustrated in FIG. 22B is an example of the case where a capacitor 53A is added to the pixel circuit 51C. The capacitor 53A functions as a storage capacitor. The pixel circuit 51C illustrated in FIG. 22A is a 4Tr1C-type pixel circuit. The pixel circuit 51D illustrated in FIG. 22B is a 4Tr2C-type pixel circuit.

The transistor 52B includes a second gate in each of the pixel circuit 51C illustrated in FIG. 22A and the pixel circuit 51D illustrated in FIG. 22B. The second gate of the transistor 52B is electrically connected to the other of the source and the drain of the transistor 52B. The transistor 100 and the like described in the above embodiment can be used as the transistor 52B, for example.

The pixel circuit 51E illustrated in FIG. 23 is a 6Tr1C-type pixel circuit including the transistor 52A, the transistor 52B, the transistor 52C, the transistor 52D, a transistor 52E, a transistor 52F, and the capacitor 53. The transistor 52B has a second gate.

One of the source and the drain of the transistor 52A is electrically connected to the wiring SL, and the gate of the transistor 52A is electrically connected to the wiring GL2. One of the source and the drain of the transistor 52D is electrically connected to the wiring ANO, and the gate of the transistor 52D is electrically connected to the wiring GL1. The other of the source and the drain of the transistor 52D is electrically connected to one of the source and the drain of the transistor 52B. The other of the source and the drain of the transistor 52B is electrically connected to the other of the source and the drain of the transistor 52A and one of a source and a drain of the transistor 52F. A gate of the transistor 52F is electrically connected to the wiring GL3.

One of a source and a drain of the transistor 52E is electrically connected to the other of the source and the drain of the transistor 52D and the one of the source and the drain of the transistor 52B. The other of the source and the drain of the transistor 52E is electrically connected to the gate of the transistor 52B and one terminal of the capacitor 53. The other terminal of the capacitor 53 is electrically connected to the other of the source and the drain of the transistor 52F, the anode of the light-emitting element 61, and one of the source and the drain of the transistor 52C. A gate of the transistor 52E and the gate of the transistor 52C are electrically connected to a wiring GL4. The other of the source and the drain of the transistor 52C is electrically connected to the wiring V0. A region where the other of the source and the drain of the transistor 52E, the gate of the transistor 52B, and the one terminal of the capacitor 53 are electrically connected to one another functions as the node ND.

In FIG. 23, the transistor 52B includes a second gate. The second gate of the transistor 52B is electrically connected to the other of the source and the drain of the transistor 52B.

For example, the transistor 100 or the like described in the above embodiment can be used as the transistor 52B. Alternatively, the transistor 100 or the like can be used as the transistor 52D, the transistor 52F, and the like in some cases.

With the use of the transistors of one embodiment of the present invention for a pixel circuit of a display apparatus, the area occupied by the pixel circuit can be reduced. Thus, the resolution of the display apparatus can be improved. For example, a display apparatus with a resolution higher than or equal to 1000 ppi, preferably higher than or equal to 2000 ppi, further preferably higher than or equal to 3000 ppi, still further preferably higher than or equal to 4000 ppi, yet further preferably higher than or equal to 5000 ppi, yet still further preferably higher than or equal to 6000 ppi, and lower than or equal to 10000 ppi, lower than or equal to 9000 ppi, or lower than or equal to 8000 ppi can be achieved.

The reduction in the area occupied by the pixel circuit can increase the number of pixels of the display apparatus (can increase the definition). For example, a display apparatus with an extremely high definition of HD (number of pixels: 1280×720), FHD (number of pixels: 1920×1080), WQHD (number of pixels: 2560×1440), WQXGA (number of pixels: 2560×1600), 4K2K (number of pixels: 3840×2160), or 8K4K (number of pixels: 7680×4320) can be achieved.

Accordingly, the use of the transistors of one embodiment of the present invention for a pixel circuit of the display apparatus can increase the display quality of the display apparatus. A bottom-emission display apparatus using an EL element can have a high aperture ratio of a pixel. A pixel with a high aperture ratio can have a lower current density than a pixel with a low aperture ratio when the pixel with a high aperture ratio and the pixel with a low aperture ratio emit light with the same luminance. Thus, the reliability of the display apparatus can be improved.

### <Structure Example of Sequential Circuit>

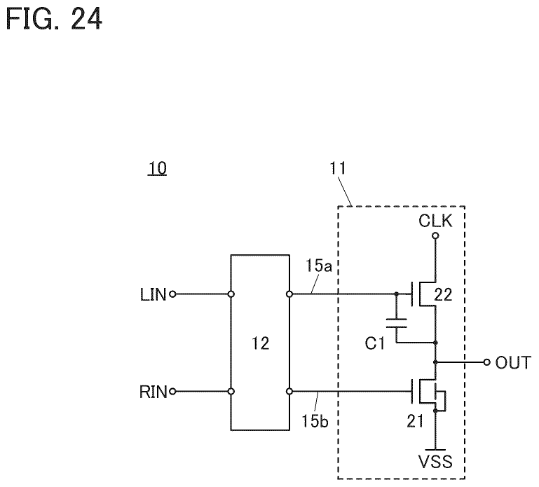

FIG. 24 illustrates a structure example of a sequential circuit 10. The sequential circuit 10 includes a circuit 11 and a circuit 12. The circuit 11 and the circuit 12 are electrically connected to each other through a wiring 15a and a wiring 15b. For example, the sequential circuit can be used as part of a driver circuit of a display apparatus. In particular, the sequential circuit 10 can be suitably used as part of a scan line driver circuit (also referred to as a gate driver circuit) of the display apparatus.

The circuit 12 has a function of outputting a first signal to the wiring 15a and outputting a second signal to the wiring 15b in accordance with the potential of a signal LIN and the potential of a signal RIN. Here, the second signal is a signal obtained by inverting the first signal. That is, in the case where the first signal and the second signal are each a signal having two kinds of potentials, a high potential and a low potential, the circuit 12 outputs a low potential to the wiring 15b when outputting a high potential to the wiring 15a, and the circuit 12 outputs a high potential to the wiring 15b when outputting a low potential to the wiring 15a.

The circuit 11 includes a transistor 21, a transistor 22, and a capacitor C1. The transistor 21 and the transistor 22 are n-channel transistors. For a semiconductor where a channel is formed in each of the transistor 21 and the transistor 22, a metal oxide (hereinafter also referred to as an oxide semiconductor) exhibiting semiconductor characteristics can be suitably used. Note that the semiconductor is not limited to an oxide semiconductor; a semiconductor such as silicon (single crystal silicon, polycrystalline silicon, or amorphous silicon) or germanium or a compound semiconductor may be used.

The transistor of one embodiment of the present invention can be suitably used as each of the transistor 21 and the transistor 22. For example, the transistor 100 or the like described in the above embodiment can be suitably used as the transistor 21.

The transistor 21 includes a pair of gates (hereinafter referred to as a first gate and a second gate). In the transistor 21, the first gate is electrically connected to the wiring 15b, the second gate is electrically connected to one of a source and a drain of the transistor 21 and a wiring supplied with a potential VSS (also referred to as a first potential), and the other of the source and the drain is electrically connected to one of a source and a drain of the transistor 22. In the transistor 22, a gate is electrically connected to the wiring 15a, and the other of the source and the drain is electrically connected to a wiring supplied with a signal CLK. The capacitor C1 has a pair of electrodes, one of which is electrically connected to the one of the source and the drain of the transistor 22 and the other of the source and the drain of the transistor 21, and the other of which is electrically connected to the gate of the transistor 22 and the wiring 15a. The other of the source and the drain of the transistor 21, the one of the source and the drain of the transistor 22, and the one electrode of the capacitor C1 are electrically connected to an output terminal OUT. Note that the output terminal OUT is a portion supplied with an output potential from the circuit 11, and may be part of a wiring or part of an electrode.

The other of the source and the drain of the transistor 22 is supplied with a second potential and a third potential alternately as the signal CLK. The second potential can be a potential (e.g., a potential VDD) higher than the potential VSS. The third potential can be a potential lower than the second potential. As the third potential, the potential VSS can be suitably used. Note that the other of the source and the drain of the transistor 22 may be supplied with the potential VDD instead of the signal CLK.

When the wiring 15a and the wiring 15b are supplied with a high potential and a low potential, respectively, the transistor 22 is turned on and the transistor 21 is turned off. At this time, electrical continuity is established between the output terminal OUT and the wiring supplied with the signal CLK.

In the circuit 11, the output terminal OUT and the gate of the transistor 22 are electrically connected to each other through the capacitor C1; thus, an increase in the potential of the output terminal OUT is accompanied by an increase in the potential of the gate of the transistor 22 owing to a bootstrap effect. Here, in the case of the absence of the capacitor C1, using the same potential (assumed to be the potential VDD) as the second potential of the signal CLK and a high potential applied to the wiring 15a would cause the potential of the output terminal OUT to decrease from the potential VDD by the threshold voltage of the transistor 22. By contrast, in the presence of the capacitor C1, the potential of the gate of the transistor 22 increases to a potential almost twice as high as the potential VDD (specifically, a potential almost twice as high as the difference between the potential VDD and the potential VSS, or a potential almost twice as high as the difference between the potential VDD and the third potential), so that the potential VDD can be output to the output terminal OUT without being affected by the threshold voltage of the transistor 22. Accordingly, the sequential circuit 10 with high output performance can be obtained without increasing the varieties of power supply potentials.

Conversely, when the wiring 15a and the wiring 15b are supplied with a low potential and a high potential, respectively, the transistor 22 is turned off and the transistor 21 is turned on. At this time, electrical continuity is established between the output terminal OUT and the wiring supplied with the potential VSS, and the potential VSS is output to the output terminal OUT.

Here, the sequential circuit 10 can be used as a driver circuit of a display apparatus. In particular, the sequential circuit can be suitably used as a scan line driver circuit. At this time, in the case where a scanning line connected to a plurality of pixels of the display apparatus is connected to the output terminal OUT, the duty ratio of an output signal output from the sequential circuit 10 to the output terminal OUT is much lower than that of the signal CLK or the like. In this case, the period for which the transistor 21 is on is much longer than the period for which the transistor 21 is off. That is, the period for which the first gate of the transistor 21 is supplied with a high potential is much longer than the period for which the first gate of the transistor 21 is supplied with a low potential, resulting in inducing degradation of transistor characteristics. However, as described above, since the transistor of one embodiment of the present invention has high reliability, the use of the transistor of one embodiment of the present invention for the transistor 21 can inhibit degradation of transistor characteristics in a state where a high potential is supplied to the first gate.

The use of the transistor of one embodiment of the present invention for the transistor 21 suitably prevents the threshold voltage from having a negative value, which enables the transistor 21 to easily have normally-off characteristics. In the case of the transistor 21 having normally-on characteristics, a leakage current occurs between the source and the drain when the voltage between the second gate of the transistor 21 and the source thereof is 0 V, preventing the potential of the output terminal OUT from being maintained. Therefore, to put the transistor 21 in an off state, the second gate of the transistor 21 needs to be supplied with a potential lower than the potential VSS, which necessitates a plurality of power supplies. However, as described above, since the transistor of one embodiment of the present invention has a structure in which the second gate and the source are electrically connected to each other (one conductive layer is shared), the use of the transistor of one embodiment of the present invention as the transistor 21 can achieve the sequential circuit 10 with high output performance without increasing the number of kinds of power supply potentials.

With the use of the transistor of one embodiment of the present invention as the transistor 21, the saturation in the I_{d}-V_{d} characteristics of the transistor 21 can be improved. This facilitates designing of the circuit 11 and enables the circuit 11 to operate stably.

The structure described in this embodiment can be used in an appropriate combination with any of the structures described in the other embodiments.

### Embodiment 4

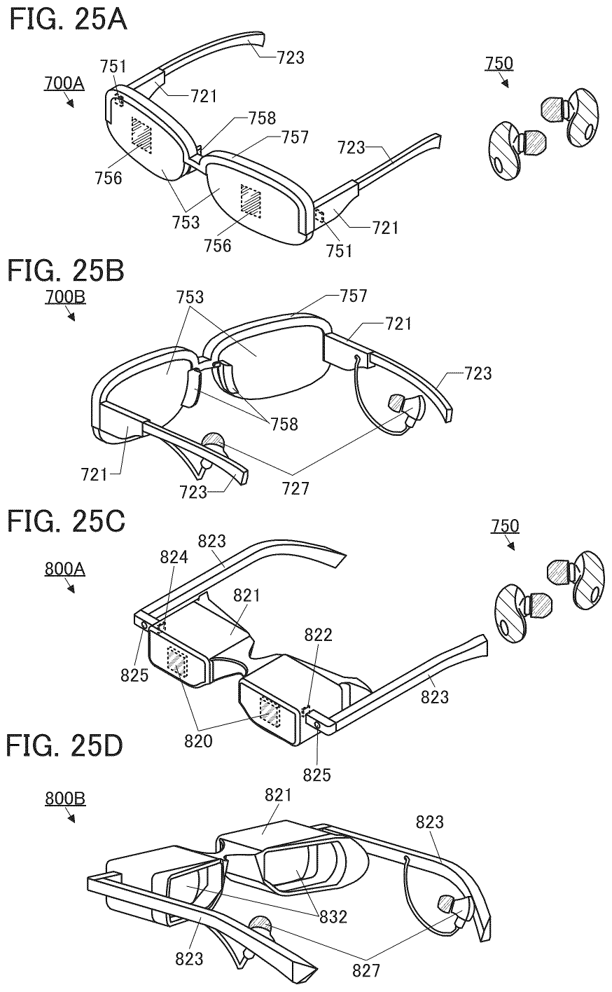

In this embodiment, electronic devices of one embodiment of the present invention will be described with reference to FIG. 25A to FIG. 27G.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for display portions of a variety of electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display apparatus of one embodiment of the present invention can have high resolution, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of such a display apparatus having one or both of a high definition and a high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 25A to FIG. 25D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 25A and an electronic device 700B illustrated in FIG. 25B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with an extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 25C and an electronic device 800B illustrated in FIG. 25D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with an extremely high resolution. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be mounted on the user's head with the wearing portions 823. FIG. 25C or the like illustrates an example in which the wearing portions 823 have a shape like a temple (also referred to as a joint) of glasses; however, one embodiment of the present invention is not limited thereto. The wearing portions 823 can have any shape with which the user can wear the electronic device, for example, a shape of a helmet or a band.

The image capturing portion 825 has a function of obtaining information on the external environment. Data obtained by the image capturing portion 825 can be output to the display portions 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object is provided. That is, the image capturing portion 825 is one embodiment of the sensing portion. As the sensing portion, an image sensor or a distance image sensor such as LIDAR (Light Detection And Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portions 820, the housing 821, and the wearing portions 823. Thus, without additionally requiring an audio device such as headphones, earphones, or a speaker, the user can enjoy videos and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 25A has a function of transmitting information to the earphones 750 with the wireless communication function. For another example, the electronic device 800A illustrated in FIG. 25C has a function of transmitting information to the earphones 750 with the wireless communication function.

The electronic device may include earphone portions. The electronic device 700B illustrated in FIG. 25B includes earphone portions 727. For example, the earphone portions 727 and the control portion can be connected to each other by wire. Part of a wiring that connects the earphone portions 727 and the control portion may be positioned inside the housing 721 or the wearing portions 723.

Similarly, the electronic device 800B illustrated in FIG. 25D includes earphone portions 827. For example, the earphone portions 827 and the control portion 824 can be connected to each other by wire. Part of a wiring that connects the earphone portions 827 and the control portion 824 may be positioned inside the housing 821 or the wearing portions 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, the electronic device of one embodiment of the present invention can be suitably applied to both the glasses-type device (e.g., the electronic device 700A and the electronic device 700B) and the goggles-type device (e.g., the electronic device 800A and the electronic device 800B).

The electronic device of one embodiment of the present invention can transmit information to earphones by wire or wirelessly.

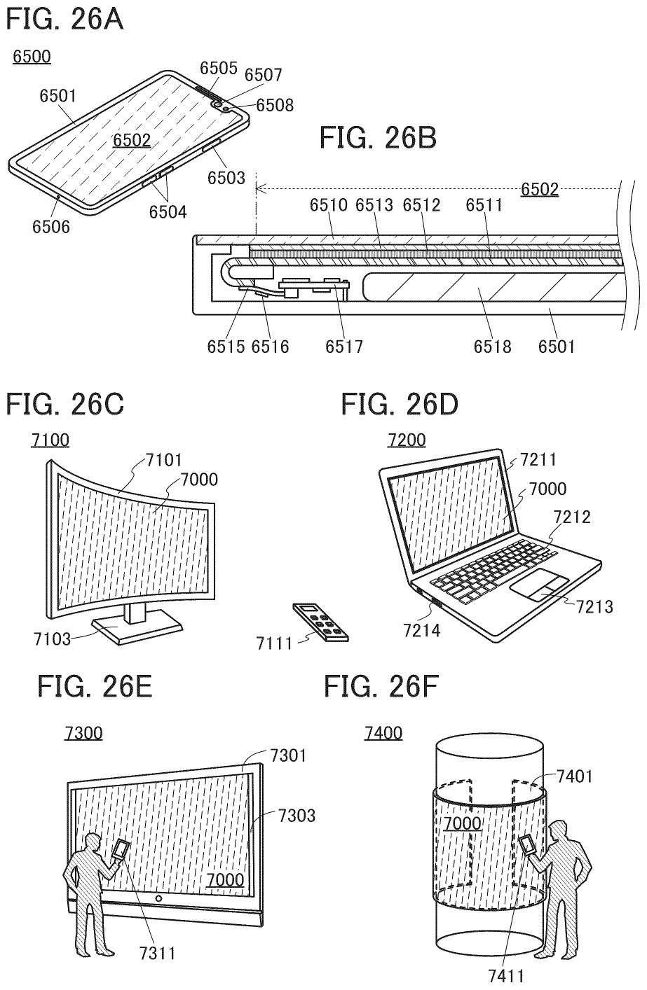

An electronic device 6500 illustrated in FIG. 26A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 26B is a schematic cross-sectional view including the end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display apparatus of one embodiment of the present invention can be used as the display panel 6511. Thus, an extremely lightweight electronic device can be obtained. Since the display panel 6511 is extremely thin, the battery 6518 with high capacity can be mounted while an increase in thickness of the electronic device is suppressed. Moreover, part of the display panel 6511 is folded back such that a connection portion with the FPC 6515 is provided on the back side of the display portion 6502, whereby an electronic device with a narrow bezel can be obtained.

FIG. 26C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

The operation of the television device 7100 illustrated in FIG. 26C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 26D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 26E and FIG. 26F illustrate examples of digital signage.

Digital signage 7300 illustrated in FIG. 26E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 26F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 26E and FIG. 26F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 26E and FIG. 26F, it is preferable that the digital signage 7300 or the digital signage 7400 be capable of working with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

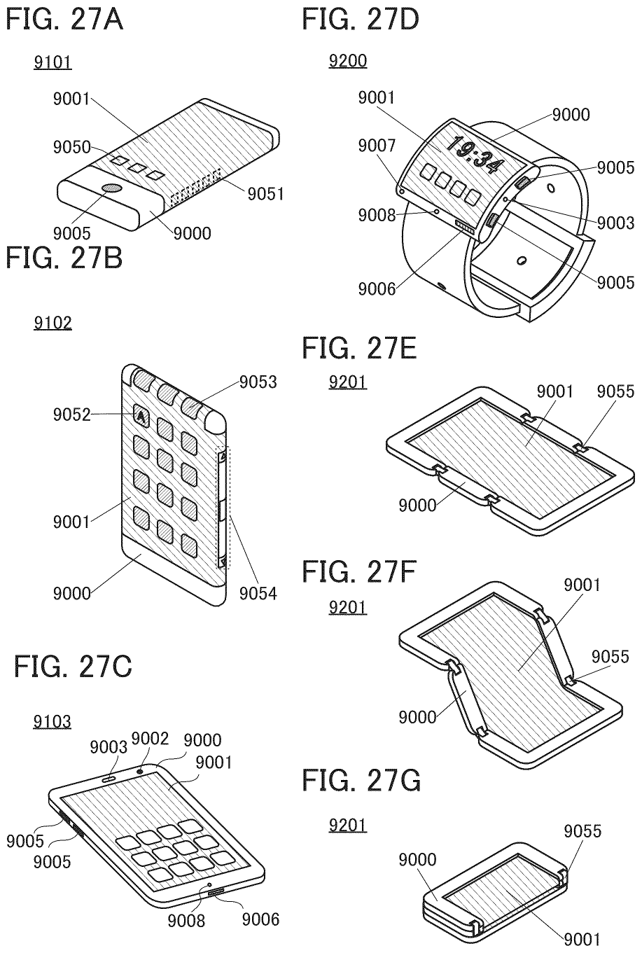

Electronic devices illustrated in FIG. 27A to FIG. 27G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays), a microphone 9008, and the like.

The display apparatus of one embodiment of the present invention can be used for the display portion 9001 in FIG. 27A to FIG. 27G.

The electronic devices illustrated in FIG. 27A to FIG. 27G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a recording medium (an external recording medium or a recording medium incorporated in the camera), a function of displaying the taken image on the display portion, or the like.

The electronic devices illustrated in FIG. 27A to FIG. 27G will be described in detail below.

FIG. 27A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display characters and image information on its plurality of surfaces. FIG. 27A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 27B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 27C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 27D is a perspective view illustrating a watch-type portable information terminal 9200. The portable information terminal 9200 can be used as a Smartwatch (registered trademark), for example. The display surface of the display portion 9001 is curved, and display can be performed along the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 27E to FIG. 27G are perspective views illustrating a foldable portable information terminal 9201. FIG. 27E is a perspective view of an opened state of the portable information terminal 9201, FIG. 27G is a perspective view of a folded state thereof, and FIG. 27F is a perspective view of a state in the middle of change from one of FIG. 27E and FIG. 27G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

10: sequential circuit
11B: subpixel
11G: subpixel
11R: subpixel
11: circuit
12: circuit
15a: wiring
15b: wiring
21: transistor
22: transistor
50A: display apparatus
50B: display apparatus
50C: display apparatus
50D: display apparatus
50E: display apparatus
50F: display apparatus
50G: display apparatus
51A: pixel circuit
51B: pixel circuit
51C: pixel circuit
51D: pixel circuit
51E: pixel circuit
51: pixel circuit
52A: transistor
52B: transistor
52C: transistor
52D: transistor
52E: transistor
52F: transistor
53A: capacitor
53: capacitor
61: light-emitting element
100A: transistor
100B: transistor
100C: transistor
100D: transistor
100E: transistor
100F: transistor
100G: transistor
100H: transistor
100I: transistor
100J: transistor
100K: transistor
100: transistor
102: substrate
103: insulating layer
104f: conductive film
104: conductive layer
106: insulating layer
108f: metal oxide film
108: semiconductor layer
110a: insulating layer
110b: insulating layer
110c: insulating layer
110: insulating layer
111B: pixel electrode
111G: pixel electrode
111R: pixel electrode
111S: pixel electrode
112a: conductive layer
112b: conductive layer
112bf conductive film
112c: conductive layer
113B: EL layer
113G: EL layer
113R: EL layer
113S: functional layer
113: EL layer
114: common layer
115: common electrode
117: light-blocking layer
118B: sacrificial layer
118G: sacrificial layer
118R: sacrificial layer
119B: sacrificial layer
119G: sacrificial layer
119R: sacrificial layer
123: conductive layer
124B: conductive layer
124G: conductive layer
124R: conductive layer
125f insulating film
125: insulating layer
126B: conductive layer
126G: conductive layer
126R: conductive layer
127: insulating layer
128: layer
130B: light-emitting element
130G: light-emitting element
130R: light-emitting element
130S: light-receiving element
131: protective layer
132B: coloring layer
132G: coloring layer
132R: coloring layer
133B: layer
133Bf: film
133G: layer
133R: layer
133: layer
140: connection portion
141: opening
142: adhesive layer
143: depressed portion
144: region
145: opening
151: substrate
152: substrate
153: insulating layer
162: display portion
164: circuit portion
165: wiring
166: conductive layer
167: conductive layer
172: FPC
173: IC
204: connection portion
205B: transistor
205D: transistor
205G: transistor
205R: transistor
205S: transistor
210: pixel
218: insulating layer
230: pixel
235: insulating layer
237: insulating layer
242: connection layer
700A: electronic device
700B: electronic device
721: housing
723: wearing portion
727: earphone portion
750: earphone
751: display panel
753: optical member
756: display region
757: frame
758: nose pad
800A: electronic device
800B: electronic device
820: display portion
821: housing
822: communication portion
823: wearing portion
824: control portion
825: image capturing portion
827: earphone portion
832: lens
6500: electronic device
6501: housing
6502: display portion
6503: power button
6504: button
6505: speaker
6506: microphone
6507: camera
6508: light source
6510: protection member
6511: display panel
6512: optical member
6513: touch sensor panel
6515: FPC
6516: IC
6517: printed circuit board
6518: battery
7000: display portion
7100: television device
7101: housing
7103: stand
7111: remote control
7200: laptop personal computer
7211: housing
7212: keyboard
7213: pointing device
7214: external connection port
7300: digital signage
7301: housing
7303: speaker
7311: information terminal
7400: digital signage
7401: pillar
7411: information terminal
9000: housing
9001: display portion
9002: camera
9003: speaker
9005: operation key
9006: connection terminal
9007: sensor
9008: microphone
9050: icon
9051: information
9052: information
9053: information
9054: information
9055: hinge
9101: portable information terminal
9102: portable information terminal
9103: tablet terminal
9200: portable information terminal
9201: portable information terminal

1. A transistor comprising:
a first conductive layer;
a second conductive layer;
a third conductive layer;
a first insulating layer over the first conductive layer;
a second insulating layer below the third conductive layer; and
a semiconductor layer comprising a region facing the second conductive layer with the first insulating layer therebetween,
wherein the first insulating layer comprises an opening reaching the first conductive layer and a depressed portion surrounding the opening,
wherein the second conductive layer covers an inner wall of the depressed portion,
wherein the semiconductor layer is provided in contact with an inner wall and a bottom surface of the opening,
wherein the second insulating layer is provided in contact with a top surface of the semiconductor layer, and
wherein the third conductive layer covers the inner wall of the opening and comprises a region facing the semiconductor layer with the second insulating layer therebetween.

2. The transistor according to claim 1,
wherein the semiconductor layer comprises an oxide semiconductor.

3. The transistor according to claim 1,
wherein the first insulating layer has a stacked-layer structure of a third insulating layer, a fourth insulating layer over the third insulating layer, and a fifth insulating layer over the fourth insulating layer, and
wherein the third insulating layer and the fifth insulating layer each comprise a region having a film density higher than a film density of the fourth insulating layer.

4. The transistor according to claim 1,
wherein, in a cross-sectional view, a width of the opening is wider on the second conductive layer side than on the first conductive layer side, and
wherein, in the cross-sectional view, a width of the depressed portion is wider on the second conductive layer side than on the first conductive layer side.

5. The transistor according to claim 1,
wherein, in a cross-sectional view, a width of the opening is wider on the second conductive layer side than on the first conductive layer side, and
wherein, in the cross-sectional view, a width of the depressed portion is narrower on the second conductive layer side than on the first conductive layer side.

6. The transistor according to claim 1,
wherein, in a cross-sectional view, when a length of a side surface of the first insulating layer in contact with the semiconductor layer is L1 and a length of a region of the second conductive layer that faces the semiconductor layer with the first insulating layer therebetween is L2, L2 is greater than or equal to 0.5 times and less than or equal to 1.0 times L1.

7. A transistor comprising:
a first conductive layer;
a second conductive layer;
a third conductive layer;
a first insulating layer over the first conductive layer;
a second insulating layer under the third conductive layer; and
a semiconductor layer,
wherein the first insulating layer comprises a first opening reaching the first conductive layer and a depressed portion surrounding the first opening,
wherein the semiconductor layer is in contact with an inner wall and a bottom surface of the first opening and a top surface of the first insulating layer,
wherein the second conductive layer covers an inner wall of the depressed portion and comprises a first region over and in contact with the semiconductor layer and a second region facing the semiconductor layer with the first insulating layer therebetween,
wherein the second insulating layer is in contact with a top surface of the semiconductor layer, and
wherein the third conductive layer covers the inner wall of the first opening and comprises a region facing the semiconductor layer with the second insulating layer therebetween.

8. The transistor according to claim 7,
wherein the semiconductor layer comprises an oxide semiconductor.

9. The transistor according to claim 7,
wherein the first insulating layer has a stacked-layer structure of a third insulating layer, a fourth insulating layer over the third insulating layer, and a fifth insulating layer over the fourth insulating layer, and
wherein the third insulating layer and the fifth insulating layer each comprise a region having a film density higher than a film density of the fourth insulating layer.

10. The transistor according to claim 7,
wherein, in a cross-sectional view, a width of the first opening is wider on the second conductive layer side than on the first conductive layer side, and
wherein, in the cross-sectional view, a width of the depressed portion is wider on the second conductive layer side than on the first conductive layer side.

11. The transistor according to claim 7,
wherein, in a cross-sectional view, a width of the first opening is wider on the second conductive layer side than on the first conductive layer side, and
wherein, in the cross-sectional view, a width of the depressed portion is narrower on the second conductive layer side than on the first conductive layer side.

12. The transistor according to claim 7,
wherein, in a cross-sectional view, when a length of a side surface of the first insulating layer in contact with the semiconductor layer is L1 and a length of the region of the second conductive layer that faces the semiconductor layer with the first insulating layer therebetween is L2, L2 is greater than or equal to 0.5 times and less than or equal to 1.0 times L1.

13. A method for fabricating a transistor, comprising the steps of:
forming a first conductive layer;
forming a first insulating layer over the first conductive layer;
processing the first insulating layer to form a depressed portion in the first insulating layer;
forming a second insulating layer to cover a top surface of the first insulating layer;
forming a second conductive laver over the second insulating layer;
forming an opening reaching the first conductive layer in a region surrounded by the depressed portion;
forming a metal oxide film to cover a top surface of the second conductive layer, an inner wall of the opening, and a bottom surface of the opening;
processing the metal oxide film to form a semiconductor layer that comprises a region overlapping with the inner wall of the opening;
forming a third insulating layer to cover the semiconductor layer and the top surface of the second conductive layer; and
forming a third conductive layer over the third insulating layer that comprises a region overlapping with the opening.

14. The method for fabricating a transistor according to claim 13,
wherein a treatment for supplying oxygen to the first insulating layer is performed.

15. The method for fabricating a transistor according to claim 13,
wherein the metal oxide film is formed using a sputtering method.

16. The method for fabricating a transistor according to claim 13,
wherein the metal oxide film is formed using an ALD method.
